(19) United States
(12) Patent Application Publication
(10) Pub. No.: US 2024/0282634 A1
(43) Pub. Date: Aug. 22, 2024

(54) MANUFACTURING METHOD FOR SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/652,969

(22) Filed: May 2, 2024

Related U.S. Application Data
(63) Continuation of application No. PCT/JP2022/040503, filed on Oct. 28, 2022.

(30) Foreign Application Priority Data
Nov. 5, 2021 (JP) 2021-181322

(51) Int. Cl. H01L 21/78; H01L 21/56; H01L 23/00

(52) U.S. Cl. CPC H01L 21/78; H01L 21/56; H01L 24/27; H01L 2224/27462

(57) ABSTRACT

A manufacturing method for a semiconductor device includes a step of preparing a wafer source that has a first main surface on one side and a second main surface on the other side, a step of forming a main surface electrode on the first main surface, a step of forming a terminal electrode on the main surface electrode, a step of forming a sealing insulator that covers a periphery of the terminal electrode on the first main surface such as to expose a part of the terminal electrode, and a step of cutting the wafer source in a horizontal direction along the first main surface from an intermediate portion of a thickness range of the wafer source, and separating the wafer source into a sealed wafer on the sealing insulator side and an unsealed wafer on the second surface side.

### CROSS-REFERENCE TO RELATED APPLICATIONS

The present application is a bypass continuation of International Patent Application No. PCT/JP2022/040503, filed on Oct. 28, 2022, which claims the benefit of priority to Japanese Patent Application No. 2021-181322 filed on Nov. 5, 2021, and the entire contents of each application are hereby incorporated herein by reference.

### BACKGROUND

### 1. Field of the Disclosure

The present disclosure relates to a manufacturing method for a semiconductor device.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is an enlarged plan view showing a principal part of an inner portion of a chip.

FIG. 4 is a cross sectional view taken along IV-IV line shown in FIG. 3.

FIG. 5 is an enlarged cross sectional view showing a peripheral edge portion of the chip.

FIG. 6 is a plan view showing layout examples of a gate electrode and a source electrode.

FIG. 7 is a plan view showing a layout example of an upper insulating film.

FIG. 8 is a perspective view showing a wafer source and a supporting substrate that are to be used in first, second and third manufacturing method examples for the semiconductor device shown in FIG. 1.

FIG. 9 is a flowchart showing the first manufacturing method example for the semiconductor device shown in FIG. 1.

FIGS. 10A to 10I are cross sectional views showing the first manufacturing method example for the semiconductor device shown in FIG. 9.

FIG. 11 is a flowchart showing forming steps of a device structure shown in FIG. 9.

FIGS. 12A to 12M are cross sectional views showing an example of the forming step of the device structure shown in FIG. 11.

FIGS. 13A to 13J are cross sectional views showing a step after a step of forming a main surface electrode in the example of the forming step of the device structure shown in FIG. 11.

FIG. 14 is a flowchart showing the second manufacturing method example for the semiconductor device shown in FIG. 1.

FIG. 15 is a flowchart showing the third manufacturing method example for the semiconductor device shown in FIG. 1.

FIG. 16 is a perspective view showing a wafer source, first supporting substrate and a second supporting substrate that are to be used in fourth and fifth manufacturing method examples for the semiconductor device shown in FIG. 1.

FIG. 17 is a flowchart showing the fourth manufacturing method example for the semiconductor device shown in FIG. 1.

FIGS. 18A to 18K are cross sectional views showing the fourth manufacturing method example for the semiconductor device shown in FIG. 17.

FIG. 19 is a cross sectional view showing the fifth manufacturing method example for the semiconductor device shown in FIG. 1.

FIG. 20 is a plan view showing a semiconductor device according to a second embodiment.

FIG. 21 is a plan view showing a semiconductor device according to a third embodiment.

FIG. 22 is a cross sectional view taken along XXII-XXII line shown in FIG. 21.

FIG. 23 is a circuit diagram showing an electrical configuration of the semiconductor device shown in FIG. 21.

FIG. 24 is a plan view showing a semiconductor device according to a fourth embodiment.

FIG. 25 is a cross sectional view taken along XXV-XXV line shown in FIG. 24.

FIG. 26 is a plan view showing a semiconductor device according to a fifth embodiment.

FIG. 27 is a plan view showing a semiconductor device according to a sixth embodiment.

FIG. 28 is a plan view showing a semiconductor device according to a seventh embodiment.

FIG. 29 is a plan view showing a semiconductor device according to a eighth embodiment.

FIG. 30 is a cross sectional view taken along XXX-XXX line shown in FIG. 29.

FIG. 31 is a cross sectional view showing a modified example of the chip to be applied to each of the embodiments.

FIG. 32 is a cross sectional view showing a modified example of a sealing insulator to be applied to each of the embodiments.

FIG. 33 is a plan view showing a package to which any one of the semiconductor devices according to the first to seventh embodiments is to be incorporated.

FIG. 34 is a plan view showing a package to which any one of the semiconductor device according to the eighth embodiment is to be incorporated.

FIG. 35 is a perspective view showing a package to which any one of the semiconductor devices according to the first to seventh embodiments and the semiconductor device according to the eighth embodiment are to be incorporated.

FIG. 36 is an exploded perspective view of the package shown in FIG. 35.

FIG. 37 is a cross sectional view taken along XXXVII-XXXVII line shown in FIG. 35.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

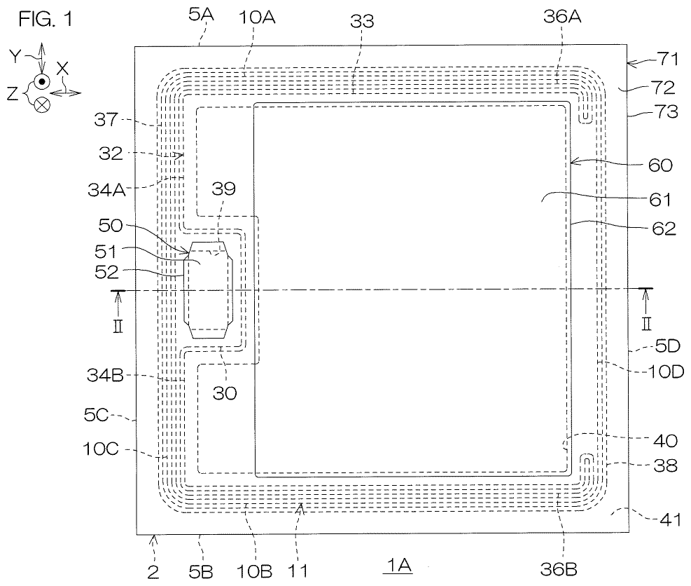

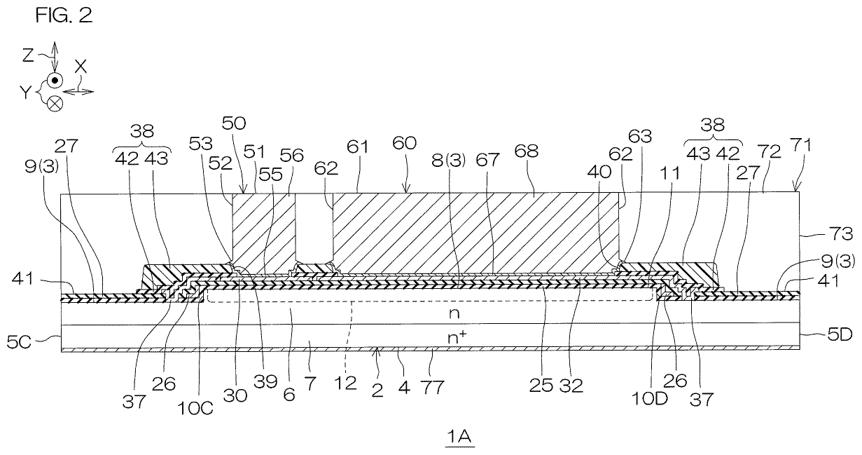

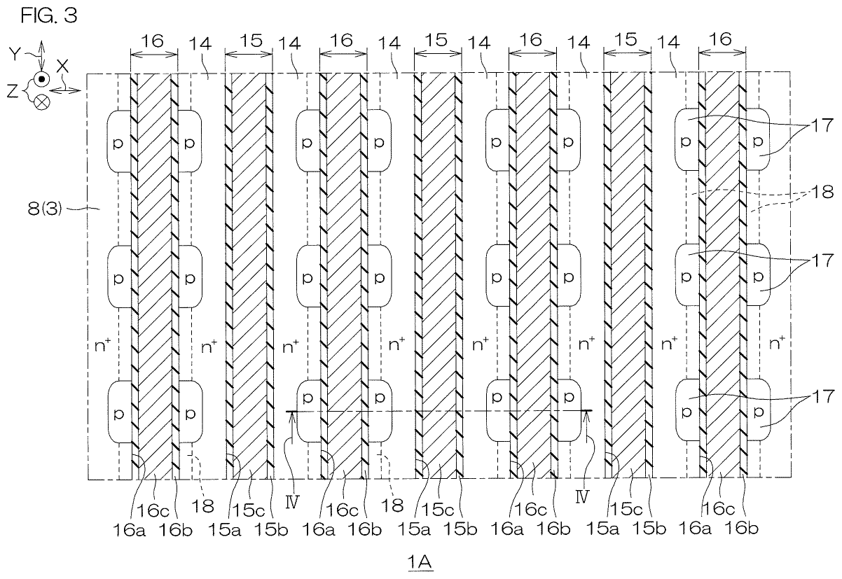

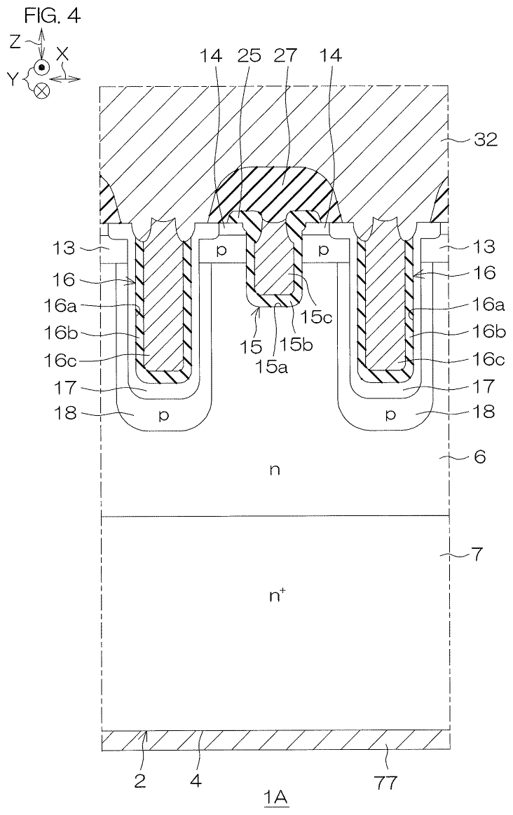

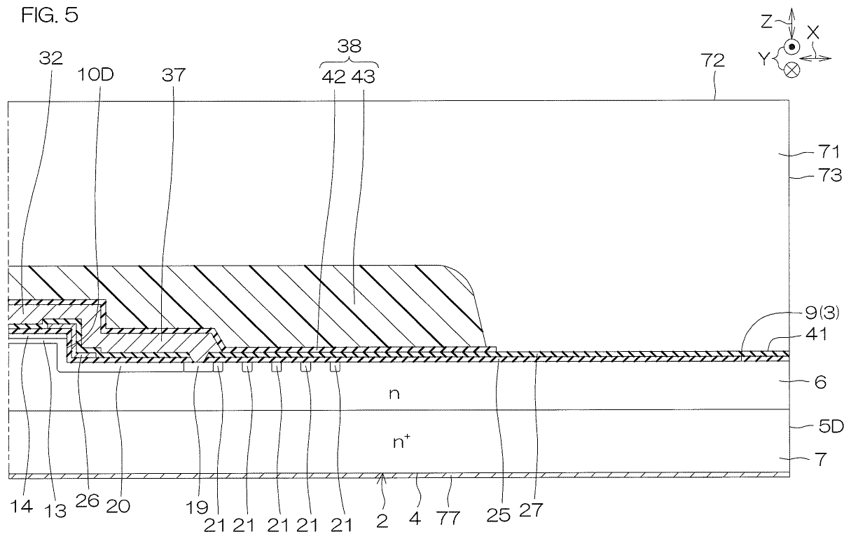

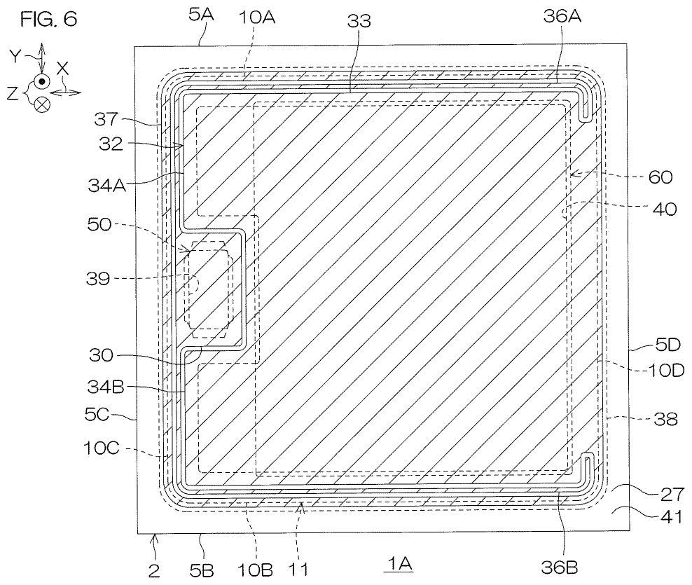

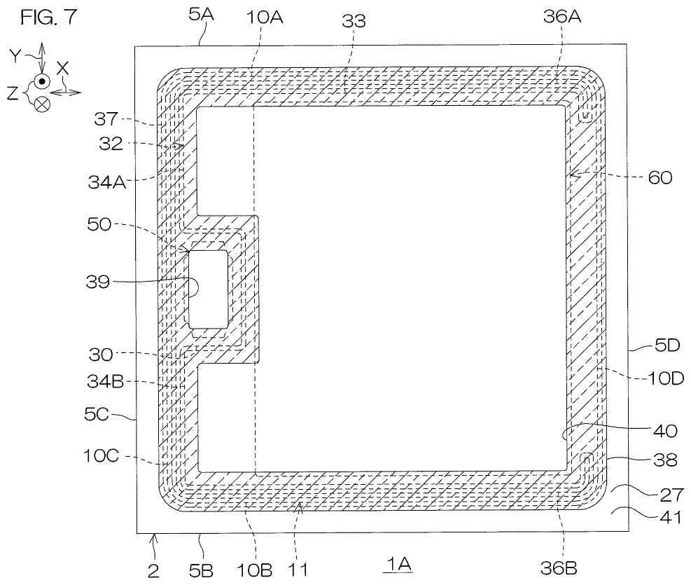

FIG. 1 is a plan view of a semiconductor device 1A according to a first embodiment. FIG. 2 is a cross sectional view taken along II-II line shown in FIG. 1. FIG. 3 is an enlarged plan view showing a principal part of an inner portion of a chip 2. FIG. 4 is a cross sectional view taken along IV-IV line shown in FIG. 3. FIG. 5 is an enlarged cross sectional view showing a peripheral edge portion of the chip 2. FIG. 6 is a plan view showing layout examples of a gate electrode 30 and a source electrode 32. FIG. 7 is a plan view showing a layout example of an upper insulating film 38.

With reference to FIG. 1 to FIG. 7, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11-20] direction) of the SiC monocrystal. The off angle may exceed 0° and be not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm, in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2, the MISFET structure 12 is shown simplified by a dashed line. Hereinafter, with reference to FIG. 3 and FIG. 4, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 5, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate electrode 30 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 may include at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably include the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably includes the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 on the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The semiconductor device 1A includes a gate terminal electrode 50 that is arranged on the gate electrode 30. The gate terminal electrode 50 is erected in a columnar shape on a portion of the gate electrode 30 that is exposed from the gate opening 39. The gate terminal electrode 50 has an area less than the area of the gate electrode 30 in plan view and is arranged on the inner portion of the gate electrode 30 at an interval from the peripheral edge of the gate electrode 30.

The gate terminal electrode 50 has a gate terminal surface 51 and a gate terminal side wall 52. The gate terminal surface 51 flatly extends along the first main surface 3. The gate terminal surface 51 may consist of a ground surface with grinding marks. The gate terminal side wall 52 is located on the upper insulating film 38 (specifically, the organic insulating film 43), in this embodiment.

That is, the gate terminal electrode 50 has a portion in contact with the inorganic insulating film 42 and the organic insulating film 43. The gate terminal side wall 52 extends substantially vertically to the normal direction Z. Here, “substantially vertically” includes a mode that extends in the laminate direction while being curved (meandering). The gate terminal side wall 52 includes a portion that faces the gate electrode 30 with the upper insulating film 38 interposed therebetween. The gate terminal side wall 52 preferably consists of a smooth surface without a grinding mark.

The gate terminal electrode 50 has a first protrusion portion 53 that outwardly protrudes at a lower end portion of the gate terminal side wall 52. The first protrusion portion 53 is formed at a region on the upper insulating film 38 (the organic insulating film 43) side than an intermediate portion of the gate terminal side wall 52. The first protrusion portion 53 extends along an outer surface of the upper insulating film 38, and is formed in a tapered shape in which a thickness gradually decreases toward the tip portion from the gate terminal side wall 52 in cross sectional view. The first protrusion portion 53 therefore has a sharp-shaped tip portion with an acute angle. As a matter of course, the gate terminal electrode 50 without the first protrusion portion 53 may be formed.

The gate terminal electrode 50 preferably has a thickness exceeding the thickness of the gate electrode 30. The thickness of the gate terminal electrode 50 is defined by a distance between the gate electrode 30 and the gate terminal surface 51. The thickness of the gate terminal electrode 50 particularly preferably exceeds the thickness of the upper insulating film 38. The thickness of the gate terminal electrode 50 exceeds the thickness of the chip 2, in this embodiment. As a matter of course, the thickness of the gate terminal electrode 50 may be less than the thickness of the chip 2. The thickness of the gate terminal electrode 50 may be not less than 10 μm and not more than 300 μm. The thickness of the gate terminal electrode 50 is preferably not less than 30 μm. The thickness of the gate terminal electrode 50 is particularly preferably not less than 80 μm and not more than 200 μm.

A planar area of the gate terminal electrode 50 is to be adjusted in accordance with the planar area of the first main surface 3. The planar area of the gate terminal electrode 50 is defined by a planar area of the gate terminal surface 51. The planar area of the gate terminal electrode 50 is preferably not more than 25% of the first main surface 3. The planar area of the gate terminal electrode 50 may be not more than 10% of the first main surface 3.

When the first main surface 3 has the planar area of not less than 1 mm square, the planar area of the gate terminal electrode 50 may be not less than 0.4 mm square. The gate terminal electrode 50 may be formed in a polygonal shape (for example, rectangular shape) having a planar area of not less than 0.4 mm×0.7 mm. The gate terminal electrode 50 is formed in a polygonal shape (quadrangle shape with four corners cut out in a rectangular shape) having four sides parallel to the first to fourth side surfaces 5A to 5D in plan view, in this embodiment. As a matter of course, the gate terminal electrode 50 may be formed in a quadrangle shape, a polygonal shape other than the quadrangle shape, a circular shape, or an elliptical shape in plan view.

The gate terminal electrode 50 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape inside the gate opening 39 and is drawn out onto the upper insulating film 38 in a film shape. The first gate conductor film 55 forms a part of the first protrusion portion 53. The first gate conductor film 55 does not necessarily have to be formed and may be omitted.

The second gate conductor film 56 forms a body of the gate terminal electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 particularly preferably exceeds the thickness of the upper insulating film 38. The thickness of the second gate conductor film 56 exceeds the thickness of the chip 2, in this embodiment.

The second gate conductor film 56 covers the gate electrode 30 with the first gate conductor film 55 interposed therebetween inside the gate opening 39, and is drawn out onto the upper insulating film 38 with the first gate conductor film 55 interposed therebetween. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a source terminal electrode 60 that is arranged on the source electrode 32. The source terminal electrode 60 is erected in a columnar shape on a portion of the source electrode 32 that is exposed from the source opening 40. The source terminal electrode 60 may have an area less than the area of the source electrode 32 in plan view, and may be arranged on an inner portion of the source electrode 32 at an interval from the peripheral edge of the source electrode 32.

The source terminal electrode 60 is arranged on the body electrode portion 33 of the source electrode 32, and is not arranged on the drawer electrode portions 34A, 34B of the source electrode 32, in this embodiment. A facing area between the gate terminal electrode 50 and the source terminal electrode 60 is thereby reduced. Such a structure is effective in reducing a risk of short-circuit between the gate terminal electrode 50 and the source terminal electrode 60, in a case in which conductive adhesives such as solders and metal pastes are to be adhered to the gate terminal electrode 50 and the source terminal electrode 60. As a matter of course, conductive bonding members such as conductor plates and conducting wires (for example, bonding wires) may be connected to the gate terminal electrode 50 and the source terminal electrode 60. In this case, a risk of short-circuit between the conductive bonding member on the gate terminal electrode 50 side and the conductive bonding member on the source terminal electrode 60 side can be reduced.

The source terminal electrode 60 has a source terminal surface 61 and a source terminal side wall 62. The source terminal surface 61 flatly extends along the first main surface 3. The source terminal surface 61 may consist of a ground surface with grinding marks. The source terminal side wall 62 is located on the upper insulating film 38 (specifically, the organic insulating film 43), in this embodiment.

That is, the source terminal electrode 60 has a portion in contact with the inorganic insulating film 42 and the organic insulating film 43. The source terminal side wall 62 extends substantially vertically to the normal direction Z. Here, “substantially vertically” includes a mode that extends in the laminate direction while being curved (meandering). The source terminal side wall 62 includes a portion that faces the source electrode 32 with the upper insulating film 38 interposed therebetween. The source terminal side wall 62 preferably consists of a smooth surface without a grinding mark.

The source terminal electrode 60 has a second protrusion portion 63 that outwardly protrudes at a lower end portion of the source terminal side wall 62. The second protrusion portion 63 is formed at a region on the upper insulating film 38 (the organic insulating film 43) side than an intermediate portion of the source terminal side wall 62. The second protrusion portion 63 extends along the outer surface of the upper insulating film 38, and is formed in a tapered shape in which a thickness gradually decreases toward the tip portion from the source terminal side wall 62 in cross sectional view. The second protrusion portion 63 therefore has a sharp-shaped tip portion with an acute angle. As a matter of course, the source terminal electrode 60 without the second protrusion portion 63 may be formed.

The source terminal electrode 60 preferably has a thickness exceeding the thickness of the source electrode 32. The thickness of the source terminal electrode 60 is defined by a distance between the source electrode 32 and the source terminal surface 61. The thickness of the source terminal electrode 60 particularly preferably exceeds the thickness of the upper insulating film 38. The thickness of the source terminal electrode 60 exceeds the thickness of the chip 2, in this embodiment.

As a matter of course, the thickness of the source terminal electrode 60 may be less than the thickness of the chip 2. The thickness of the source terminal electrode 60 may be not less than 10 μm and not more than 300 μm. The thickness of the source terminal electrode 60 is preferably not less than 30 μm. The thickness of the source terminal electrode 60 is particularly preferably not less than 80 μm and not more than 200 μm. The thickness of the source terminal electrode 60 is substantially equal to the thickness of the gate terminal electrode 50.

A planar area of the source terminal electrode 60 is to be adjusted in accordance with the planar area of the first main surface 3. The planar area of the source terminal electrode 60 is defined by a planar area of the source terminal surface 61. The planar area of the source terminal electrode 60 preferably exceeds the planar area of the gate terminal electrode 50. The planar area of the source terminal electrode 60 is preferably not less than 50% of the first main surface 3. The planar area of the source terminal electrode 60 is particularly preferably not less than 75% of the first main surface 3.

In a case in which the first main surface 3 has a planar area of not less than 1 mm square, the planar area of the source terminal electrode 60 is preferably not less than 0.8 mm square. In this case, the planar area of each of the source terminal electrode 60 is particularly preferably not less than 1 mm square. The source terminal electrode 60 may be formed in a polygonal shape having a planar area of not less than 1 mm×1.4 mm. The source terminal electrode 60 is formed in a quadrangle shape having four sides parallel to the first to fourth side surfaces 5A to 5D in plan view, in this embodiment. As a matter of course, the source terminal electrode 60 may be formed in a polygonal shape other than the quadrangle shape, a circular shape, or an elliptical shape in plan view.

The source terminal electrode 60 has a laminated structure that includes a first source conductor film 67 and a second source conductor film 68 laminated in that order from the source electrode 32 side, in this embodiment. The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material as that of the first gate conductor film 55.

The first source conductor film 67 has a thickness less than the thickness of the source electrode 32. The first source conductor film 67 covers the source electrode 32 in a film shape inside the source opening 40 and is drawn out onto the upper insulating film 38 in a film shape. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source terminal electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material as that of the second gate conductor film 56.

The second source conductor film 68 preferably has a thickness exceeding the thickness of the source electrode 32. The thickness of the second source conductor film 68 particularly preferably exceeds the thickness of the upper insulating film 38. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the source electrode 32 with the first source conductor film 67 interposed therebetween inside the source opening 40, and is drawn out onto the upper insulating film 38 with the first source conductor film 67 interposed therebetween. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The semiconductor device 1A includes a sealing insulator 71 that covers the first main surface 3. The sealing insulator 71 covers a periphery of the gate terminal electrode 50 and a periphery of the source terminal electrode 60 such as to expose a part of the gate terminal electrode 50 and a part of the source terminal electrode 60 on the first main surface 3. Specifically, the sealing insulator 71 covers the active surface 8, the outer surface 9 and the first to fourth connecting surfaces 10A to 10D such as to expose the gate terminal electrode 50 and the source terminal electrode 60.

The sealing insulator 71 exposes the gate terminal surface 51 and the source terminal surface 61 and covers the gate terminal side wall 52 and the source terminal side wall 62. The sealing insulator 71 covers the first protrusion portion 53 of the gate terminal electrode 50 and faces the upper insulating film 38 with the first protrusion portion 53 interposed therebetween, in this embodiment. The sealing insulator 71 suppresses a dropout of the gate terminal electrode 50. Also, the sealing insulator 71 covers the second protrusion portion 63 of the source terminal electrode 60 and faces the upper insulating film 38 with the second protrusion portion 63 interposed therebetween, in this embodiment. The sealing insulator 71 suppresses a dropout of the source terminal electrode 60.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 51 and the source terminal surface 61. The insulating main surface 72 may consist of a ground surface with grinding marks. In this case, the insulating main surface 72 preferably forms a single ground surface with the gate terminal surface 51 and the source terminal surface 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 880 and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 50 and the thickness of the source terminal electrode 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include the plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32 and not more than the thickness of the upper insulating film 38. The particle sizes of the medium size fillers may be not less than 1 μm and not more than 20 μm.

The large size fillers may have a thickness exceeding the thickness of the upper insulating film 38. The plurality of fillers may include at least one large size filler exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The sealing insulator 71 may include a plurality of filler fragments each having a broken particle shape in a surface layer portion of the insulating main surface 72 and in a surface layer portion of the insulating side wall 73. The plurality of filler fragments may each be formed by any one of a part of the small size fillers, a part of the medium size fillers and a part of the large size fillers.

The plurality of filler fragments positioned on the insulating main surface 72 side each has a broken portion that is formed along the insulating main surface 72 such as to be oriented to the insulating main surface 72. The plurality of filler fragments positioned on the insulating side wall 73 side each has a broken portion that is formed along the insulating side wall 73 such as to be oriented to the insulating side wall 73. The broken portions of the plurality of filler fragments may be exposed from the insulating main surface 72 and the insulating side wall 73, or may be partially or wholly covered with the matrix resin. The plurality of filler fragments do not affect the structures on the chip 2 side, since the plurality of filler fragments are located in the surface layer portions of the insulating main surface 72 and the insulating side wall 73.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 60 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the gate electrode 30 (the source electrode 32: main surface electrode), the gate terminal electrode 50 (the source terminal electrode 60) and the sealing insulator 71. The chip 2 has the first main surface 3. The gate electrode 30 (the source electrode 32) is arranged on the first main surface 3. The gate terminal electrode 50 (the source terminal electrode 60) is arranged on the gate electrode 30 (the source electrode 32). The sealing insulator 71 covers the periphery of the gate terminal electrode 50 (the source terminal electrode 60) on the first main surface 3 such as to expose the gate terminal electrode 50 (the source terminal electrode 60).

According to this structure, an object to be sealed can be protected from an external force and a humidity (moisture) by the sealing insulator 71. That is, the object to be sealed can be protected from a damage (including peeling) due to the external force and deterioration (including corrosion) due to the humidity. It is therefore possible to suppress shape defects and fluctuations in electrical characteristics. As a result, it is possible to provide the semiconductor device 1A capable of improving reliability.

The semiconductor device 1A preferably includes the upper insulating film 38 that partially covers the gate electrode 30 (the source electrode 32). According to this structure, an object to be covered can be protected from the external force and the humidity with the upper insulating film 38. That is, according to this structure, the object to be sealed can be protected by both of the upper insulating film 38 and the sealing insulator 71.

In such a structure, the sealing insulator 71 preferably has the portion directly covering the upper insulating film 38. The sealing insulator 71 preferably has the portion covering the gate electrode 30 (the source electrode 32) across the upper insulating film 38 interposed therebetween. The gate terminal electrode 50 (the source terminal electrode 60) preferably has the portion that directly covers the upper insulating film 38. The upper insulating film 38 preferably includes any one of or both of the inorganic insulating film 42 and the organic insulating film 43. The organic insulating film 43 preferably consists of the photosensitive resin film.

The upper insulating film 38 is preferably thicker than the gate electrode 30 (the source electrode 32). The upper insulating film 38 is preferably thinner than the chip 2. The sealing insulator 71 is preferably thicker than the gate electrode 30 (the source electrode 32). The sealing insulator 71 is preferably thicker than the upper insulating film 38. The sealing insulator 71 is particularly preferably thicker than the chip 2.

The sealing insulator 71 preferably includes the thermosetting resin (matrix resin). The sealing insulator 71 preferably includes the plurality of fillers that are added into the thermosetting resin. According to this structure, a mechanical strength can be adjusted by the plurality of fillers. The sealing insulator 71 preferably includes the flexible particles (flexible agent) that are added into the thermosetting resin. According to this structure, an elastic modulus of the sealing insulator 71 can be adjusted by the flexible particles.

The sealing insulator 71 preferably exposes the gate terminal surface 51 (the source terminal surface 61) of the gate terminal electrode 50 (the source terminal electrode 60) and preferably covers the gate terminal side wall 52 (the source terminal side wall 62). That is, the sealing insulator 71 preferably protects the gate terminal electrode 50 (the source terminal electrode 60) from the gate terminal side wall 52 (the source terminal side wall 62).

In this case, the sealing insulator 71 preferably has the insulating main surface 72 that forms the single flat surface with the gate terminal surface 51 (the source terminal surface 61). The sealing insulator 71 preferably has the insulating side wall 73 that forms the single flat surface with the first to fourth side surfaces 5A to 5D (side surface) of the chip 2. According to this structure, the object to be sealed that is positioned on the first main surface 3 side can be appropriately protected with the sealing insulator 71.

Those above structures are effective when the gate terminal electrode 50 (the source terminal electrode 60) having a relatively large planar area and/or a relatively large thickness is applied to the chip 2 having a relatively large planar area and/or a relatively small thickness. The gate terminal electrode 50 (the source terminal electrode 60) having the relatively large planar area and/or the relatively large thickness is also effective in absorbing a heat generated on the chip 2 side and dissipating the heat to the outside.

For example, the gate terminal electrode 50 (the source terminal electrode 60) is preferably thicker than the gate electrode 30 (the source electrode 32). The gate terminal electrode 50 (the source terminal electrode 60) is preferably thicker than the upper insulating film 38. The gate terminal electrode 50 (the source terminal electrode 60) is particularly preferably thicker than the chip 2. For example, the gate terminal electrode 50 may cover the region of not more than 25% of the first main surface 3 in plan view, and the source terminal electrode 60 may cover the region of not less than 50% of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

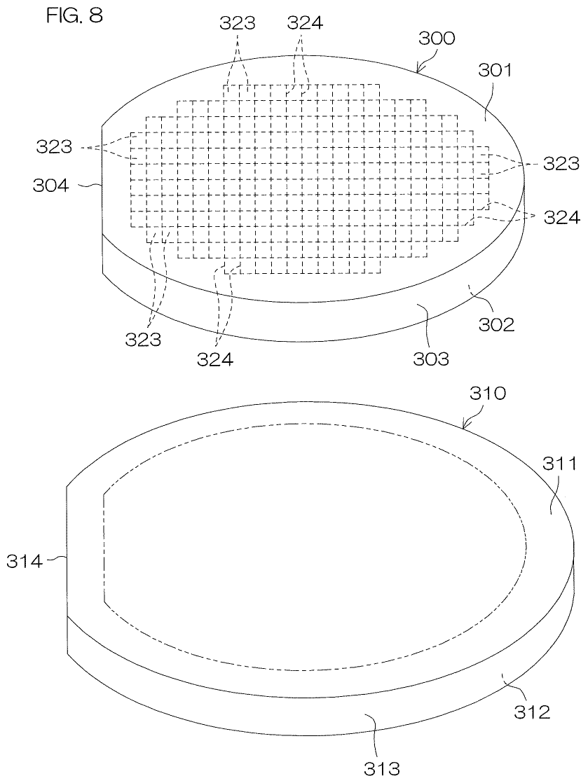

FIG. 8 is a perspective view showing a wafer source 300 and a supporting substrate 310 that are to be used in first, second and third manufacturing method examples for the semiconductor device 1A shown in FIG. 1. The wafer source 300 is to be a base of the chip 2 (specifically, the second semiconductor region 7). The wafer source 300 is a crystal plate cut out in a disc shape or a circular columnar shape from an ingot (in this embodiment, an SiC monocrystalline mass) consisting of a semiconductor monocrystal by a slicing method. The wafer source 300 is a wafer supply source from which at least one (preferably, a plurality) of wafers are cut out until the wafer source 300 becomes inseparable. The wafer source 300 may consist of a general wafer for device forming cut out from the ingot.

The wafer source 300 has a first main surface 301 on one side, a second main surface 302 on the other side, and a side surface 303 that connects the first main surface 301 and the second main surface 302. The first main surface 301 and the second main surface 302 are arranged along c-planes of the SiC monocrystal. Preferably, the first main surface 301 is arranged along a silicon surface and the second main surface 302 is arranged along a carbon surface.

As with the first main surface 3 and the second main surface 4 of the chip 2, the first main surface 301 and the second main surface 302 may have an off angle inclined at a predetermined angle in a predetermined off direction with respect to the c-planes. The off direction is preferably the a-axis direction of the SiC monocrystal. The off angle may exceed 0° and be not more than 10°. The off angle is preferably not more than 5°. The off angle is particularly preferably not less than 2° and not more than 4.5°. An off direction and an off angle of the supporting substrate 310 are preferably substantially equal to the off direction and the off angle of the wafer source 300.

The first main surface 301 may consist of a ground surface, a cleaved surface, a polished surface, or a mirror surface. The second main surface 302 may consist of a ground surface, a cleaved surface, a polished surface, or a mirror surface. A surface state of the second main surface 302 does not necessarily have to be the same as a surface state of the first main surface 301. A peripheral edge of the first main surface 301 is square and unchamfered. That is, the first main surface 301 is formed substantially at a right angle to the side surface 303. A peripheral edge of the second main surface 302 is angular and unchamfered. That is, the second main surface 302 is formed substantially at a right angle to the side surface 303.

The wafer source 300 has a first mark 304 that indicates a crystal orientation of the SiC monocrystal at the side surface 303. The first mark 304 includes an orientation flat that is notched rectilinearly in plan view in this embodiment. The orientation flat extends in the second direction Y in this embodiment.

As a matter of course, the orientation flat does not necessarily have to extend in the second direction Y and may extend in the first direction X. Also, the first mark 304 may include an orientation flat extending in the first direction X and an orientation flat extending in the second direction Y. Also, in place of or in addition to the orientation flat, the first mark 304 may have an orientation notch that is notched toward a central portion of the wafer source 300. The orientation notch may be a notched portion that is notched in a polygonal shape such as a triangular shape or a quadrilateral shape, etc., in plan view.

The wafer source 300 may have a diameter of not less than 25 mm and not more than 300 mm (that is, not less than 1 inch and not more than 12 inches. The diameter of the wafer source 300 is defined by a length of a chord passing through a center of the wafer source 300 outside the first mark 304. The wafer source 300 may have a thickness of not less than 0.1 mm and not more than 50 mm. The thickness of the wafer source 300 is typically not less than 20 mm. In a case in which a wafer for device forming that cut out from an ingot is used as the wafer source 300, the thickness of the wafer source 300 may be not less than 0.3 mm and not more than 15 mm (preferably not more than 10 mm).

The supporting substrate 310 is a plate shaped member that supports the wafer source 300 from the second main surface 302 side. The supporting substrate 310 may be formed in a disc shape or a circular columnar shape. As long as it can support the wafer source 300 from the second main surface 302 side, a material of the supporting substrate 310 is arbitrary. The supporting substrate 310 may consist of an inorganic plate, an organic plate, a metal plate, a crystal plate, or an amorphous plate (glass plate). Preferably, the supporting substrate 310 consists of a light transmitting plate or a transparent plate and is arranged such as to suppress attenuation of laser light. A melting point of the supporting substrate 310 is preferably not less than a melting point of the wafer source 300. A ratio of a thermal expansion coefficient of the supporting substrate 310 with respect to a thermal expansion coefficient of the wafer source 300 is preferably not less than 0.5 and not more than 1.5.

The supporting substrate 310 particularly preferably consists of the same material as the wafer source 300 (that is, SiC). In this case, the supporting substrate 310 may consist of an SiC monocrystal or an SiC polycrystal. Further in this case, the supporting substrate 310 preferably consists of a hexagonal SiC monocrystal. The supporting substrate 310, like the wafer source 300, consists of a 4H-SiC monocrystal in this embodiment. As a matter of course, the supporting substrate 310 may consist of another polytype other than the 4H-SiC monocrystal. The supporting substrate 310 consists of a crystal plate (that is, a wafer) cut out from an ingot (SiC monocrystalline mass) by a slicing method in this embodiment.

An impurity concentration of the supporting substrate 310 is set independently of the wafer source 300. The impurity concentration of the supporting substrate 310 preferably differs from an impurity concentration of the wafer source 300. The impurity concentration of the supporting substrate 310 is preferably less than the impurity concentration of the wafer source 300. The supporting substrate 310 is particularly preferably undoped. In this case, absorption (attenuation) of laser light due to the supporting substrate 310 is suppressed.

The supporting substrate 310 may include vanadium as an impurity. If the supporting substrate 310 includes an n-type impurity or a p-type impurity, the impurity concentration of the supporting substrate 310 is preferably not more than 1×10¹⁸ cm⁻³. It is noted that laser light having a wavelength of not more than 390 μm has a tendency to be absorbed (attenuated) by an SiC monocrystal regardless of whether or not it is doped with an impurity.

The supporting substrate 310 has a first plate surface 311 on one side (the wafer source 300 side), a second plate surface 312 on the other side, and a plate side surface 313 that connects the first plate surface 311 and the second plate surface 312. The first plate surface 311 may consist of a ground surface, a cleaved surface, a polished surface, or a mirror surface. The second plate surface 312 may consist of a ground surface, a cleaved surface, a polished surface, or a mirror surface. A surface state of the second plate surface 312 does not necessarily have to be the same as a surface state of the first plate surface 311.

The first plate surface 311 and the second plate surface 312 are preferably arranged along c-planes of the SiC monocrystal. In this case, preferably, the first plate surface 311 is arranged along a silicon surface and the second plate surface 312 is arranged along a carbon surface. As with the first main surface 301 and the second main surface 302 of the wafer source 300, the first plate surface 311 and the second plate surface 312 may have an off angle inclined at a predetermined angle in a predetermined off direction with respect to the c-planes.

The off direction is preferably the a-axis direction of the SiC monocrystal. The off angle may exceed 0° and be not more than 10°. The off angle is preferably not more than 5°. The off angle is particularly preferably not less than 2° and not more than 4.5°. The off direction and an off angle of the supporting substrate 310 are preferably substantially equal to the off direction and the off angle of the wafer source 300. The off direction and an off angle of the supporting substrate 310 are preferably substantially equal to the off direction and the off angle of the wafer source 300.

A peripheral edge of the first plate surface 311 has a chamfered portion that is inclined obliquely. The chamfered portion of the first plate surface 311 may be a round chamfered portion or a 45 degree chamfered portion. A peripheral edge of the second plate surface 312 has a chamfered portion that is inclined obliquely. The chamfered portion of the second plate surface 312 may be a round chamfered portion or a 45 degree chamfered portion. One or both of the peripheral edge of the first plate surface 311 and the peripheral edge of the second plate surface 312 may lack a chamfered portion and be square. However, from a standpoint of handling, both the peripheral edge of the first plate surface 311 and the peripheral edge of the second plate surface 312 preferably have chamfered portions. The term “handling” according to this Description includes not only transfer work accompanying a manufacturing process of the semiconductor device 1A but also includes distribution to markets.

The supporting substrate 310 has a second mark 314 that indicates a crystal orientation at the plate side surface 313. The second mark 314 is also a mark that indirectly indicates the crystal orientation of the wafer source 300. The second mark 314 includes an orientation flat that is notched rectilinearly in plan view in this embodiment. The orientation flat extends in the second direction Y in this embodiment. As a matter of course, the orientation flat does not necessarily have to extend in the second direction Y and may extend in the first direction X.

Also, the second mark 314 may include an orientation flat extending in the first direction X and an orientation flat extending in the second direction Y. Also, in place of or in addition to the orientation flat, the second mark 314 may have an orientation notch that is notched toward the central portion of the wafer source 300. The orientation notch may be a notched portion that is notched in a polygonal shape such as a triangular shape or a quadrilateral shape, etc., in plan view.

A diameter and a thickness of the supporting substrate 310 are arbitrary. The diameter of the supporting substrate 310 is defined by a length of a chord passing through a center of the supporting substrate 310 outside the second mark 314. In view of the handling of the wafer source 300, the supporting substrate 310 preferably has a diameter not less than the diameter of the wafer source 300 and a thickness not less than the thickness of the wafer source 300. An interval between the peripheral edge of the wafer source 300 and the peripheral edge of the supporting substrate 310 when the central portion of the wafer source 300 and a central portion of the supporting substrate 310 are overlapped is preferably not less than 0 mm and not more than 10 mm.

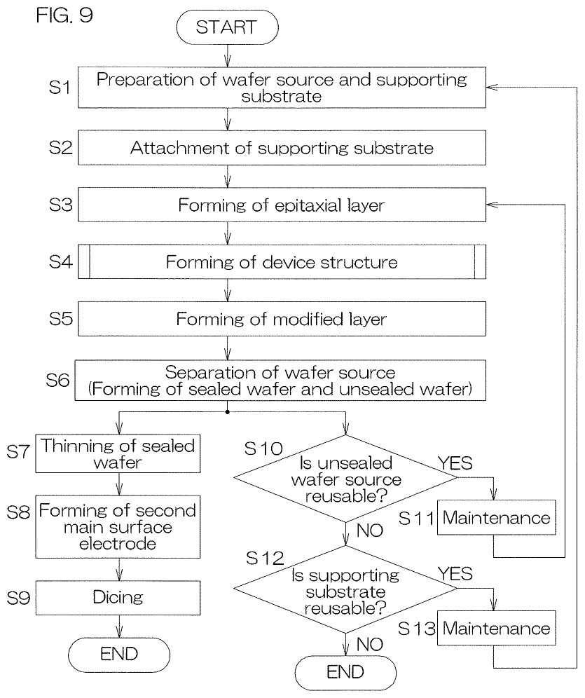

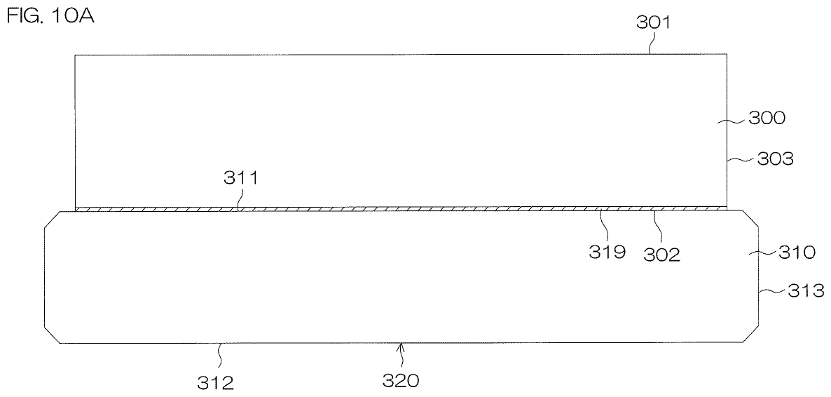

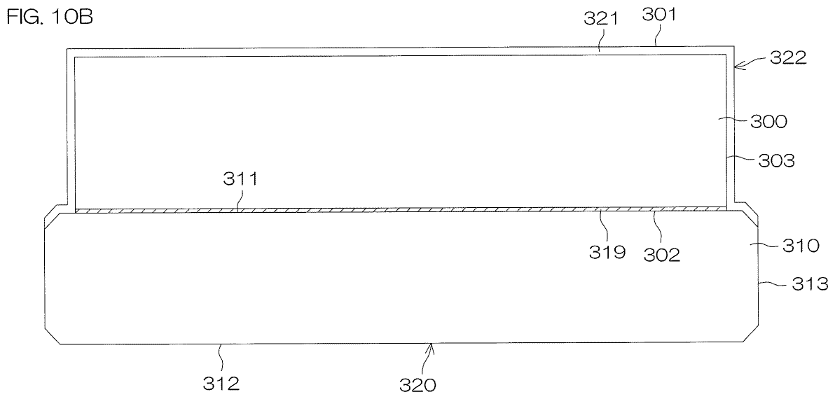

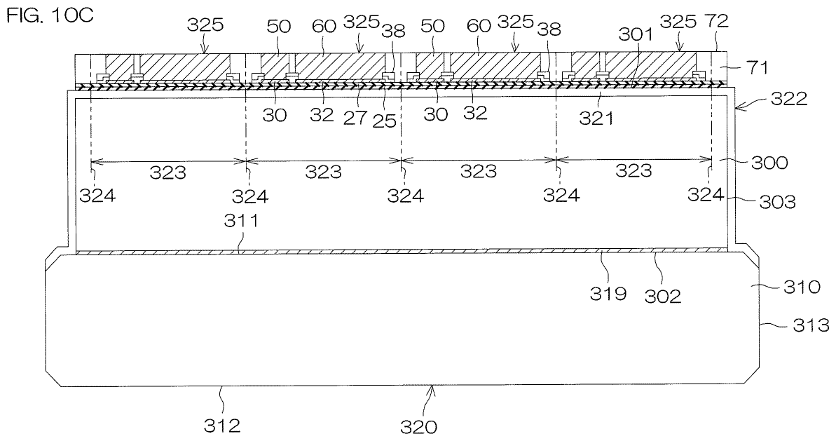

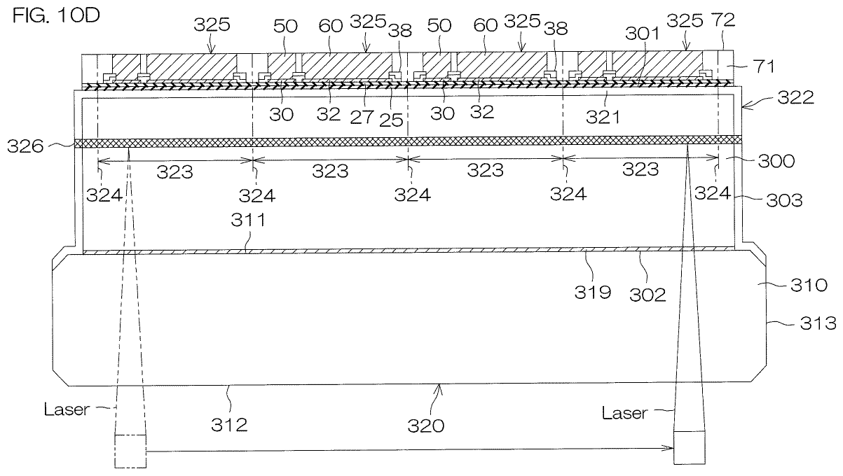

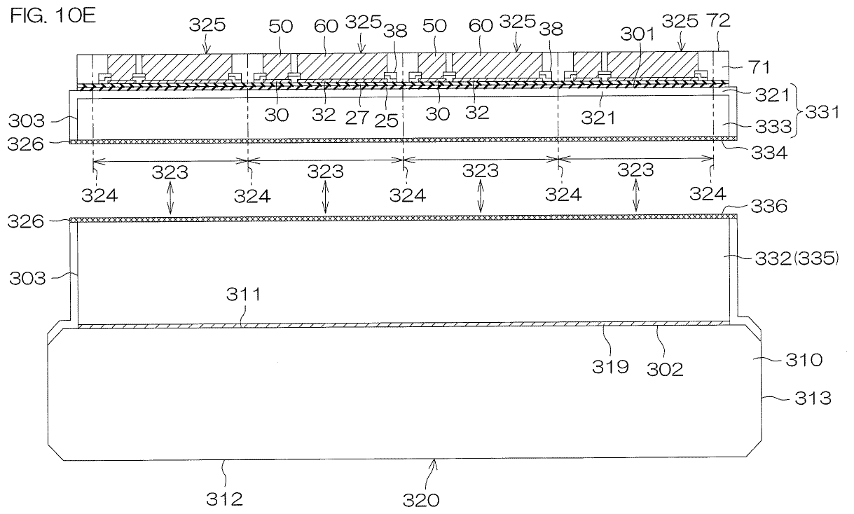

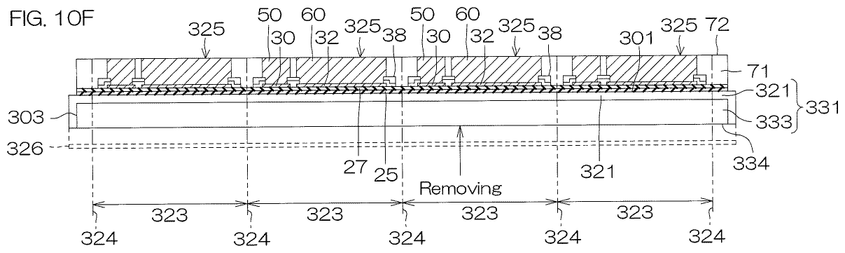

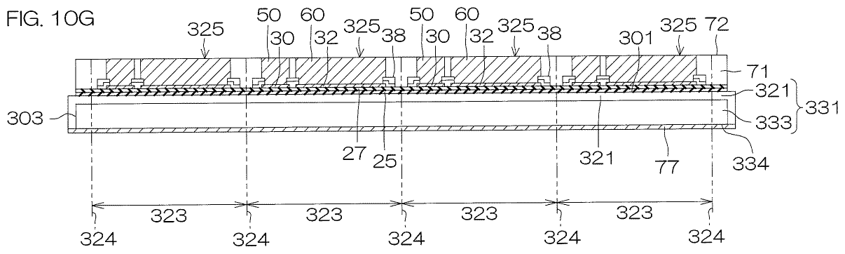

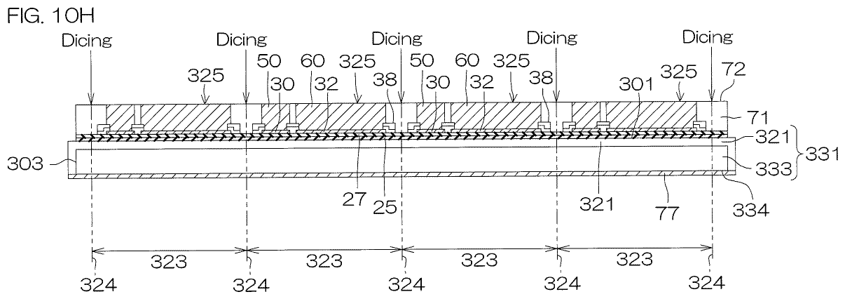

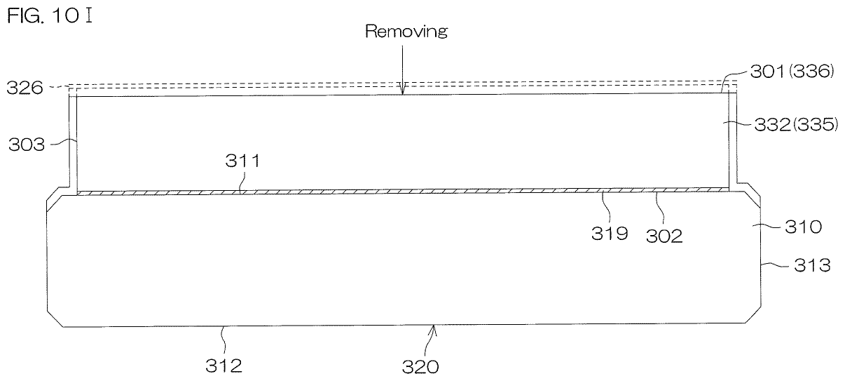

FIG. 9 is a flowchart showing the first manufacturing method example for the semiconductor device 1A shown in FIG. 1. FIG. 10A to FIG. 10I are cross sectional views showing the first manufacturing method example for the semiconductor device 1A shown in FIG. 9. In FIG. 10A to FIG. 10I, the wafer source 300 and the supporting substrate 310 are shown in simplified manner.

With reference to FIG. 10A, the wafer source 300 and the supporting substrate 310 are prepared (step S1 of FIG. 9). Next, the supporting substrate 310 is attached to the wafer source 300 (step S2 of FIG. 9). In this step, the first plate surface 311 (silicon surface) of the supporting substrate 310 is attached to the second main surface 302 (carbon surface) of the wafer source 300.

The supporting substrate 310 is attached to the wafer source 300 such that the second mark 314 extends parallel to the first mark 304 at a position adjacent to the first mark 304 (see FIG. 8). In a case in which both the first mark 304 and the second mark 314 include orientation notches, the supporting substrate 310 is attached to the wafer source 300 such that the notch directions are matched. The crystal orientation of the wafer source 300 is determined by one or both of the first mark 304 and the second mark 314.

The first plate surface 311 of the supporting substrate 310 may be directly bonded to the second main surface 302 of the wafer source 300 by a room temperature bonding method that is an example of a direct bonding method. In the room temperature bonding method, an activating step and a bonding step are performed. In the activating step, for example, atoms or ions are irradiated onto the second main surface 302 of the wafer source 300 and the first plate surface 311 of the supporting substrate 310 inside a high vacuum and dangling bonds are formed on each of the second main surface 302 and the first plate surface 311.

In the bonding step, the activated second main surface 302 and the activated first plate surface 311 are bonded. An amorphous bonding layer 319 composed of a portion of the wafer source 300 and a portion of the supporting substrate 310 is formed between the second main surface 302 and the first plate surface 311 after bonding. That is, the supporting substrate 310 is bonded to the wafer source 300 via the amorphous bonding layer 319. The direct bonding method may include a heat treatment step and a pressurizing step for increasing a bonding strength of the supporting substrate 310 with respect to the wafer source 300.

The amorphous bonding layer 319 has a different optical absorption coefficient from the wafer source 300. Specifically, the amorphous bonding layer 319 has an optical absorption coefficient that is greater than the optical absorption coefficient of the wafer source 300. Further, the optical absorption coefficient of the amorphous bonding layer 319 is greater than the optical absorption coefficient of the supporting substrate 310. A thickness of the amorphous bonding layer 319 may exceed 0 μm and be not more than 5 μm. The thickness of the amorphous bonding layer 319 is preferably not more than 1 μm. The wafer source 300 forms a wafer attachment structure 320 together with the supporting substrate 310 and the amorphous bonding layer 319. That is, the wafer source 300 is handled integrally with the supporting substrate 310.

In this step, the supporting substrate 310 is bonded to the wafer source 300 by the direct bonding method. However, as long as the wafer source 300 can be supported by the supporting substrate 310, a bonding method of the supporting substrate 310 to the wafer source 300 is arbitrary. For example, the supporting substrate 310 may be bonded to the wafer source 300 by a double-sided tape or an adhesive, etc. In this case, an adhesive layer consisting of the double-sided tape or the adhesive, etc., is formed between the wafer source 300 and the supporting substrate 310.

Next, with reference to FIG. 10B, an epitaxial layer 321 is grown from the first main surface 301 by an epitaxial growth method (step S3 of FIG. 9). The epitaxial layer 321 becomes a base of the chip 2 (specifically, the first semiconductor region 6). The epitaxial layer 321 has a thickness less than the thickness of the wafer source 300. The thickness of the epitaxial layer 321 is preferably not less than 3 μm and not more than 30 μm. The thickness of the epitaxial layer 321 is particularly preferably not less than 5 μm and not more than 25 μm.

The epitaxial layer 321 is also formed on the side surface 303 of the wafer source 300 and the first plate surface 311 of the supporting substrate 310 in this embodiment. The epitaxial layer 321 may cover the amorphous bonding layer 319 at a lower end side of the side surface 303 of the wafer source 300. Through this step, an epi-wafer source 322 is formed on the first plate surface 311. The epi-wafer source 322 has a laminated structure that includes the wafer source 300 and the epitaxial layer 321 and has the first main surface 301 formed by the epitaxial layer 321. A step of grinding the first main surface 301 may be performed before the forming step of the epitaxial layer 321. That is, the epitaxial layer 321 may be grown from the first main surface 301 after the grinding step.

Next, with reference to FIG. 10C, a plurality of device regions 323 and a plurality of scheduled cutting lines 324 are set on the first main surface 301 of the epi-wafer source 322 (also see broken line portion of FIG. 8) and a device structure 325 is formed in each of the plurality of device regions 323 (step S4 of FIG. 9). The plurality of device regions 323 are each a region corresponding to the semiconductor device 1A. The plurality of device regions 323 are each set in a quadrangle shape in plan view. The plurality of device regions 323 are arrayed in a matrix along the first direction X and the second direction Y in plan view in this embodiment.

The plurality of scheduled cutting lines 324 are lines (regions extending in band shapes) that define locations that are to be the first to fourth side surfaces 5A to 5D of the chips 2. The plurality of scheduled cutting lines 324 are set in a lattice that extends along the first direction X and the second direction Y such as to demarcate the plurality of device regions 323. The plurality of scheduled cutting lines 324 may, for example, be defined by alignment marks, etc., provided at an interior and/or an exterior of the epi-wafer source 322.

The plurality of device structures 325 each include a structure corresponding to the semiconductor device 1A. In the forming step of the device structures 325, the mesa portion 11, the MISFET structure 12, the main surface insulating film 25, the side wall structure 26, the interlayer insulating film 27, the gate electrode 30, the source electrode 32, the plurality of gate wirings 36A and 36B, the source wiring 37, the upper insulating film 38, the gate terminal electrode 50, the source terminal electrode 60, and the sealing insulator 71 are formed in each of the plurality of device regions 323. The descriptions of the specific features of the respective structures formed in the forming step of the device structures 325 are as have been provided above. Also, a specific description of the forming step of the device structures 325 shall be provided below.

Next, with reference to FIG. 10D, a modified layer 326 that is oriented along a horizontal direction parallel to the first main surface 301 is formed at an intermediate portion of a thickness range of the epi-wafer source 322 (step S5 of FIG. 9). Specifically, the modified layer 326 is formed at an intermediate portion of a thickness range of the wafer source 300 in a portion of the epi-wafer source 322 consisting of the wafer source 300. More specifically, the modified layer 326 is formed in an interior of the wafer source 300 at an interval from the epitaxial layer 321.

In this step, a light converging portion is set at the intermediate portion of the thickness range of the wafer source 300 and a laser light is irradiated from a laser light irradiating apparatus toward the wafer source 300 via the supporting substrate 310. Thereby, the laser light is prevented from being shielded by the gate terminal electrode 50, the source terminal electrode 60, and the sealing insulator 71. An irradiation position of the laser light with respect to the wafer source 300 is moved along the horizontal direction. The laser light is preferably irradiated in pulses into the interior of the wafer source 300. The modified layer 326 in which a portion of the crystal structure of the wafer source 300 (SiC monocrystal) is modified to be of a different property is thereby formed.

That is, the modified layer 326 is a laser processing mark formed by the irradiation of the laser light. The modified layer 326 consists of a layer with which density, refractive index, mechanical strength (crystal strength), or other physical characteristic has been modified to differ in property from the wafer source 300 and having a more fragile physical property than the wafer source 300. The modified layer 326 may include at least one layer among an amorphous layer, a melted and rehardened layer, a defect layer, a dielectric breakdown layer, or a refractive index changed layer.

The amorphous layer is a layer in which a portion of the wafer source 300 has been made amorphous. The melted and rehardened layer is a layer in which a portion of the wafer source 300 has been melted and thereafter rehardened. The defect layer is a layer that includes holes, cracks, etc., formed in the wafer source 300. The dielectric breakdown layer is a layer in which a portion of the wafer source 300 has undergone dielectric breakdown. The refractive index changed layer is a layer in which a portion of the wafer source 300 has changed to be of a different refractive index.

A formation location of the modified layer 326 is set in accordance with a thickness of a wafer to be acquired from the epi-wafer source 322. A distance between the first main surface 301 and the modified layer 326 is preferably set to a value less than a distance between the second main surface 302 and the modified layer 326. As a matter of course, the distance between the first main surface 301 and the modified layer 326 may be set to a value exceeding the distance between the second main surface 302 and the modified layer 326.

The distance between the first main surface 301 and the modified layer 326 is preferably set to a value less than the thickness of the sealing insulator 71. In this case, a wafer having a thickness less than the thickness of the sealing insulator 71 is acquired from the epi-wafer source 322. Further in this case, a distance between the epitaxial layer 321 and the modified layer 326 is preferably set to a value less than the thickness of the epitaxial layer 321.

As a matter of course, the distance between the first main surface 301 and the modified layer 326 may be set to a value exceeding the thickness of the sealing insulator 71. In this case, a wafer having a thickness exceeding the thickness of the sealing insulator 71 is acquired from the epi-wafer source 322. Further in this case, the distance between the epitaxial layer 321 and the modified layer 326 is preferably set to a value exceeding the thickness of the epitaxial layer 321.

The distance between the first main surface 301 and the modified layer 326 may be not less than 10 μm and not more than 300 μm. The distance between the first main surface 301 and the modified layer 326 may be not more than 100 μm. The distance between the second main surface 302 and the modified layer 326 may be not more than 50 μm. The distance between the second main surface 302 and the modified layer 326 may be not more than 40 μm.

Next, with reference to FIG. 10E, the epi-wafer source 322 is cut along the horizontal direction from the intermediate portion of the thickness range with the modified layer 326 as a starting point (step S6 of FIG. 9). In this step, an external force is applied to the modified layer 326 in a state in which the epi-wafer source 322 is supported (sandwiched) by the sealing insulator 71 and the supporting substrate 310 and the wafer source 300 is cleaved in the horizontal direction with the modified layer 326 as the starting point.

The external force applied to the wafer source 300 may be an ultrasonic wave. The separating step of the wafer source 300 is performed without a supporting member, which supports the epi-wafer source 322, being attached to the sealing insulator 71 side. However, it is not prohibited for a jig for positioning the epi-wafer source 322, a jig for suppressing positional deviation of the epi-wafer source 322, etc., to be in contact with the epi-wafer source 322, the sealing insulator 71, etc.

The epi-wafer source 322 is thereby separated into a sealed wafer 331 on the sealing insulator 71 side and an unsealed wafer 332 on the supporting substrate 310 side. The sealed wafer 331 is handled independently of the unsealed wafer 332 and the unsealed wafer 332 is handled independently of the sealed wafer 331.

The sealed wafer 331 has a laminated structure that includes a first wafer portion 333 consisting of a portion of the wafer source 300 and the epitaxial layer 321 laminated on the first wafer portion 333. The sealed wafer 331 has a first cut surface 334 that is formed by the first wafer portion 333. The first cut surface 334 is arranged along a carbon surface of the SiC monocrystal. The sealed wafer 331 is cut out in a state of being supported by the sealing insulator 71 and therefore, deformation (for example, warping that accompanies thinning) of the sealed wafer 331 is suppressed by the sealing insulator 71. The sealed wafer 331 can thereby be formed appropriately.

It is therefore preferable for the distance between the first main surface 301 and the modified layer 326 to be set to a value less than the thickness of the sealing insulator 71 and the sealed wafer 331 that is thinner than the sealing insulator 71 to be cut out. In this case, the distance between the epitaxial layer 321 and the modified layer 326 may be set to a value exceeding the thickness of the epitaxial layer 321 and the sealed wafer 331 having the first wafer portion 333 that is thicker than the epitaxial layer 321 may be cut out. Also, the distance between the epitaxial layer 321 and the modified layer 326 may be set to a value less than the thickness of the epitaxial layer 321 and the sealed wafer 331 having the epitaxial layer 321 that is thicker than the first wafer portion 333 may be cut out.

As a matter of course, the sealed wafer 331 that is thicker than the sealing insulator 71 may be cut out. In this case, the sealed wafer 331 may have the first wafer portion 333 that is thicker than the epitaxial layer 321. Also, the sealed wafer 331 may have the epitaxial layer 321 that is thicker than the first wafer portion 333.

The unsealed wafer 332 has a single layer structure that includes a second wafer portion 335 consisting of a portion of the wafer source 300 and is supported by the supporting substrate 310 via the amorphous bonding layer 319. The unsealed wafer 332 has a second cut surface 336 formed by the second wafer portion 335. The second cut surface 336 is arranged along a silicon surface of the SiC monocrystal. The unsealed wafer 332 is cut out in a state of being supported by the supporting substrate 310 and therefore, deformation (for example, warping that accompanies thinning) of the unsealed wafer 332 is suppressed by the supporting substrate 310.

The unsealed wafer 332 can thereby be formed appropriately. In this step, the unsealed wafer 332 that is thicker than the sealed wafer 331 is cut out. A thickness of the unsealed wafer 332 may exceed that of the sealing insulator 71. Further, the thickness of the unsealed wafer 332 may exceed a total thickness of the sealed wafer 331 and the sealing insulator 71.

With reference to FIG. 10F, at the sealed wafer 331 side supported by the sealing insulator 71, a thinning step of the sealed wafer 331 is performed (step S7 of FIG. 9). This step includes a step of removing at least a portion of the first wafer portion 333 from the first cut surface 334 side in a state of being supported by the sealing insulator 71. Also, this step includes a step of removing a remaining portion of the modified layer 326 adhered to the first cut surface 334. This step includes at least one among a grinding step performed on the first cut surface 334 and an etching step performed on the first cut surface 334. The grinding step may include at least one among a mechanical polishing method and a chemical mechanical polishing method. The etching step may include at least one among a dry etching step and a wet etching step.

The sealed wafer 331 is thinned until the sealed wafer 331 is of a desired thickness. In a case in which the sealed wafer 331 that is thinner than the sealing insulator 71 is cut out, the thinning step of the sealed wafer 331 includes a step of thinning the sealed wafer 331 further. On the other hand, in a case in which the sealed wafer 331 that is thicker than the sealing insulator 71 is cut out, the thinning step of the sealed wafer 331 preferably includes a step of thinning the sealed wafer 331 until the sealed wafer 331 becomes less in thickness than the sealing insulator 71. In a case in which the first wafer portion 333 is thinner than the epitaxial layer 321 in these steps, the first wafer portion 333 is thinned further. On the other hand, in a case in which the first wafer portion 333 is thicker than the epitaxial layer 321, the first wafer portion 333 is preferably thinned until the first wafer portion 333 becomes less in thickness than the epitaxial layer 321.

Next, with reference to FIG. 10G, the drain electrode 77 (second main surface electrode) covering the first cut surface 334 of the sealed wafer 331 is formed (step S8 of FIG. 9). The drain electrode 77 may be formed by a sputtering method and/or a vapor deposition method.

Thereafter, with reference to FIG. 10H, the sealed wafer 331 and the sealing insulator 71 are cut along the scheduled cutting lines 324 (step S9 of FIG. 9). The sealed wafer 331 and the sealing insulator 71 may be cut by a dicing blade (not shown). A plurality of the semiconductor devices 1A are manufactured from the wafer source 300 (sealed wafer 331) through steps including the above.

On the other hand, with reference to FIG. 10I, at the unsealed wafer 332 (second wafer portion 335) side supported by the supporting substrate 310, it is determined whether or not the unsealed wafer 332 is reusable as the new wafer source 300 (step S10 of FIG. 9). In a case in which the unsealed wafer 332 has a thickness and a state of levels enabling acquisition of another sealed wafer 331, it may be determined that the unsealed wafer 332 is reusable.

In a case in which the unsealed wafer 332 is reusable (step S10 of FIG. 9: YES), a maintenance step of the unsealed wafer 332 (second wafer portion 335) is performed (step S11 of FIG. 9). The maintenance step of the unsealed wafer 332 includes a step of repairing the unsealed wafer 332 to a state enabling use as the new wafer source 300. This step may include a step of removing a remaining portion of the modified layer 326 adhered to the second cut surface 336 of the unsealed wafer 332.

The removing step of the modified layer 326 includes at least one among a grinding step performed on the modified layer 326 and an etching step performed on the modified layer 326. The grinding step may include at least one among a mechanical polishing method and a chemical mechanical polishing method. The etching step may include at least one among a dry etching step and a wet etching step. The removing step of the modified layer 326 may include at least one among a grinding step performed on the unsealed wafer 332 (second cut surface 336) and an etching step performed on the unsealed wafer 332.

Through this step, the second cut surface 336 of the unsealed wafer 332 is smoothened and the unsealed wafer 332 is reused as the new wafer source 300. Thereafter, steps S1 to S6 of FIG. 9 are performed successively (see also FIG. 10A to FIG. 10E). In a case in which the unsealed wafer 332 is to be reused as the last wafer source 300, the last wafer source 300 may be separated as a sealed wafer 331 from the supporting substrate 310. In this case, the modified layer 326 is formed in an interior or a vicinity of the amorphous bonding layer 319 and the last wafer source 300 is separated from the supporting substrate 310 by cleaving of the modified layer 326.

On the other hand, in a case in which the unsealed wafer 332 is unreusable (step S10 of FIG. 9: NO), the manufacturing process using a single wafer source 300 ends and it is determined whether or not the supporting substrate 310 is reusable (step S12 of FIG. 9). In a case in which the supporting substrate 310 has a thickness and a state of levels enabling supporting of another wafer source 300, it may be determined that the supporting substrate 310 is reusable. In a case in which the supporting substrate 310 is unreusable (step S12 of FIG. 9: NO), the manufacturing process using the supporting substrate 310 ends.

In a case in which the supporting substrate 310 is reusable (step S12 of FIG. 9: YES), a maintenance step of the supporting substrate 310 is performed (step S13 of FIG. 9). The maintenance step of the supporting substrate 310 includes a step of repairing the supporting substrate 310 to a state enabling use as the new supporting substrate 310. This step includes a step of removing the amorphous bonding layer 319 and the unsealed wafer 332 from the supporting substrate 310.

The removing step of the unsealed wafer 332 (amorphous bonding layer 319) includes at least one among a grinding step performed on the unsealed wafer 332 and an etching step performed on the unsealed wafer 332. The grinding step may include at least one among a mechanical polishing method and a chemical mechanical polishing method. The etching step may include at least one among a dry etching step and a wet etching step.

The removing step of the unsealed wafer 332 may include at least one among a grinding step performed on the supporting substrate 310 (first plate surface 311) and an etching step performed on the supporting substrate 310. Thereby, the first plate surface 311 of the supporting substrate 310 is smoothened and the supporting substrate 310 is reused. Thereafter, steps S1 to S6 of FIG. 9 are performed successively (see also FIG. 10A to FIG. 10E).

In FIG. 9, the semiconductor devices 1A are manufactured in the manufacturing process of the first time performed on the wafer source 300 and the reusing step of the wafer source 300. However, arbitrary semiconductor devices (for example, semiconductor devices 1B to 1H according to other embodiments) differing from the semiconductor devices 1A may be manufactured in the manufacturing process of the first time and the semiconductor devices 1A may be manufactured in the reusing step. As a matter of course, the semiconductor devices 1A may be manufactured in the manufacturing process of the first time and arbitrary semiconductor devices differing from the semiconductor devices 1A may be manufactured in the reusing step. Also, the semiconductor devices 1A may be manufactured using at least one unsealed wafer 332 acquired from the reusing step and arbitrary semiconductor devices differing from the semiconductor devices 1A may be manufactured using the remaining unsealed wafers 332.

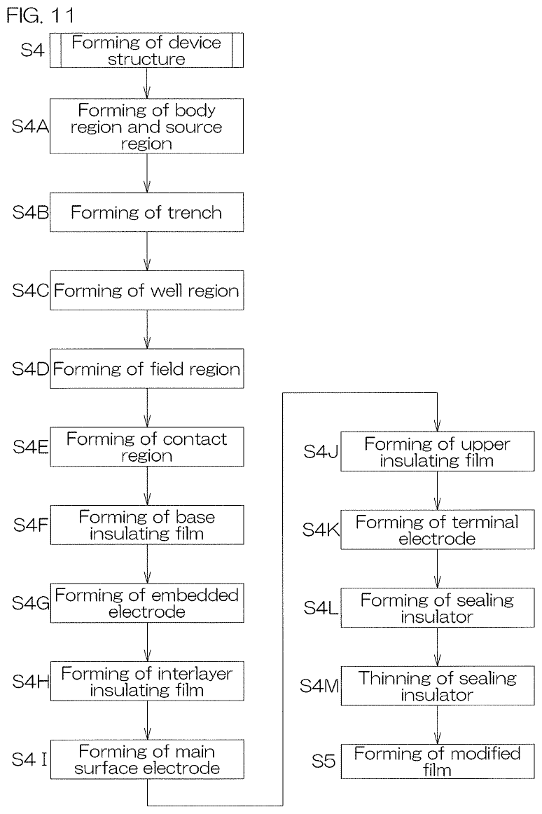

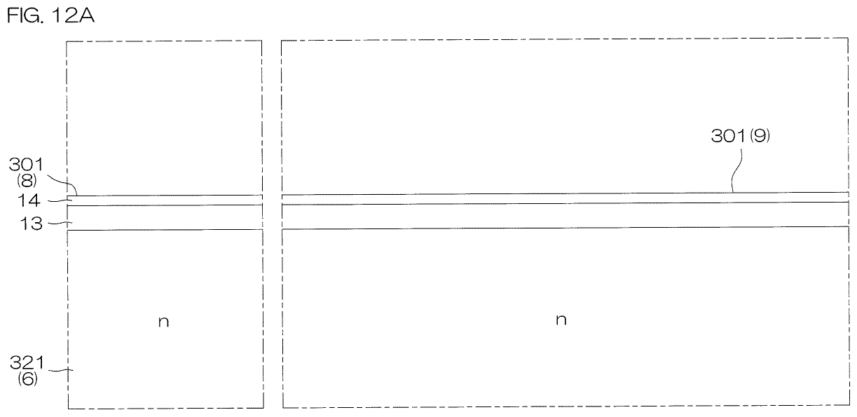

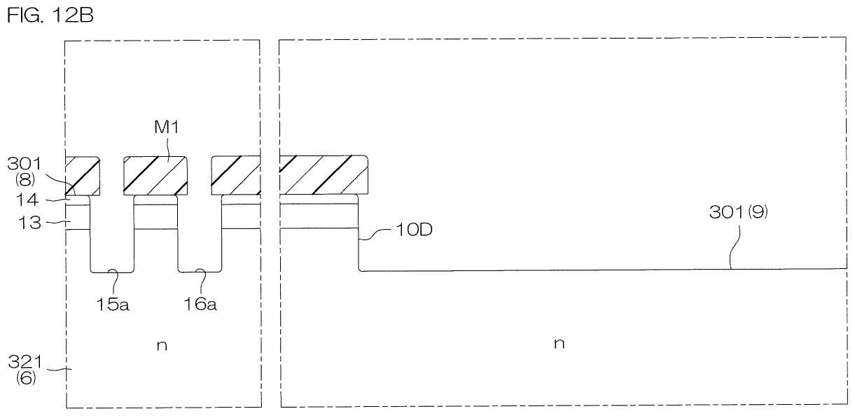

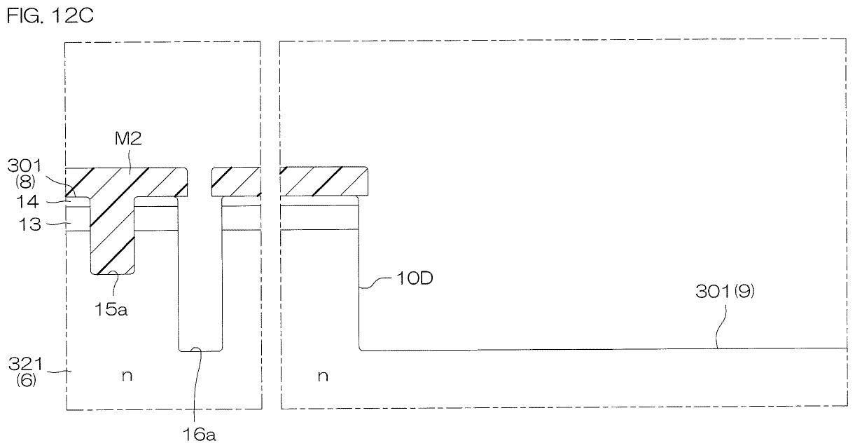

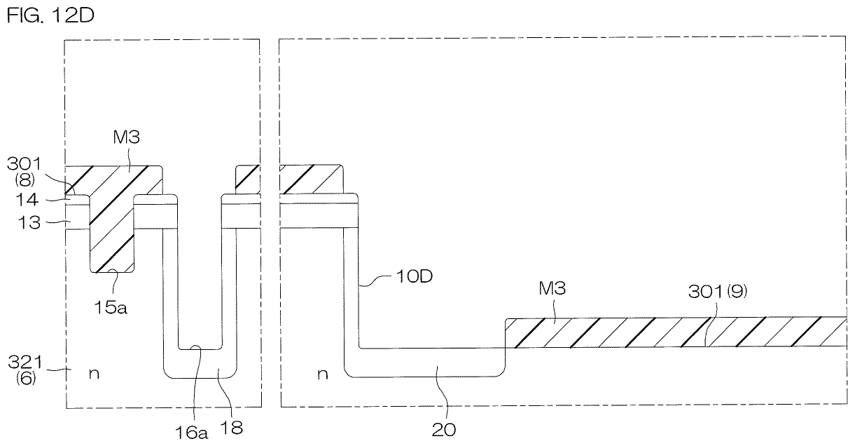

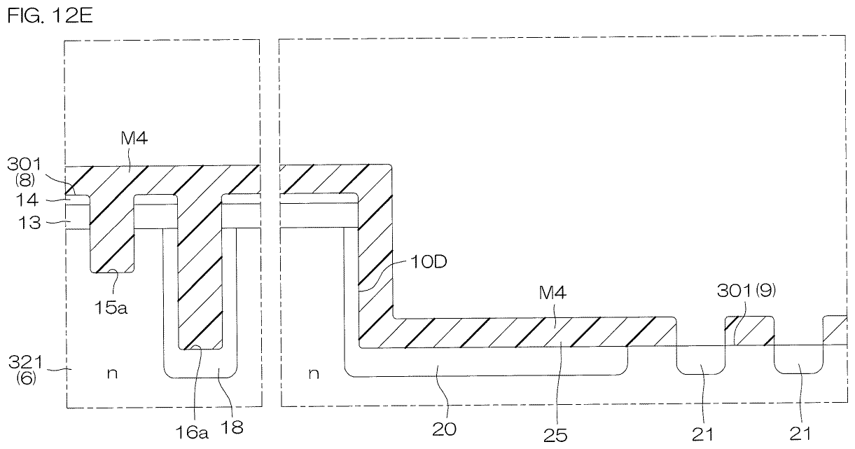

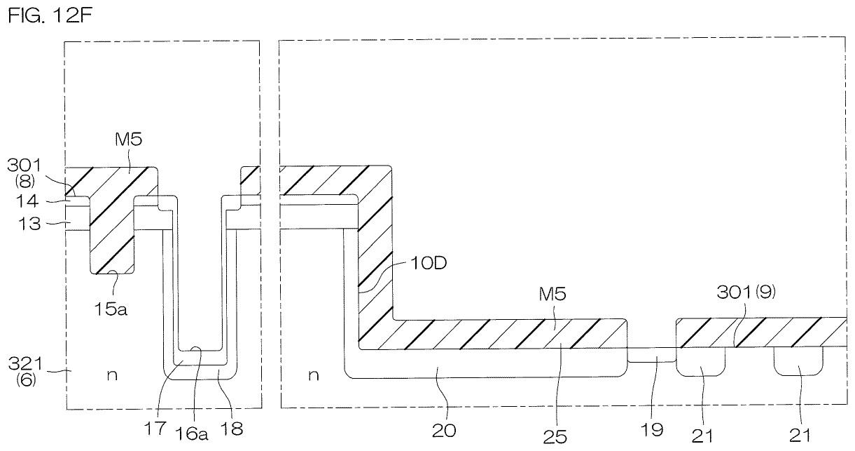

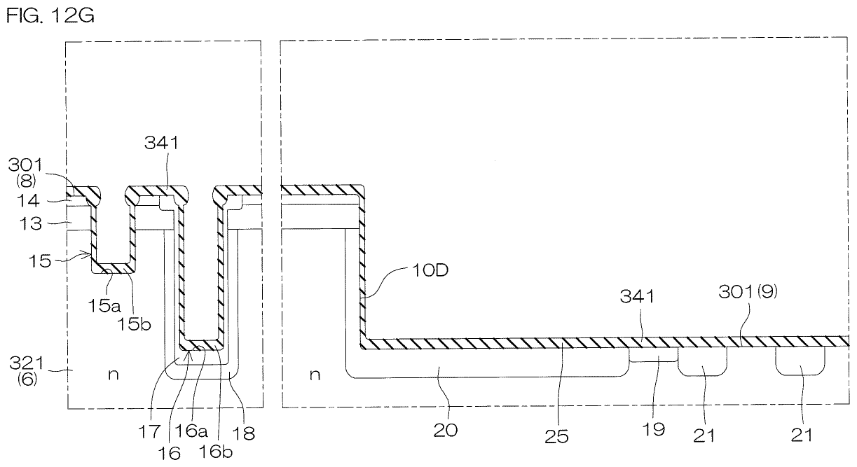

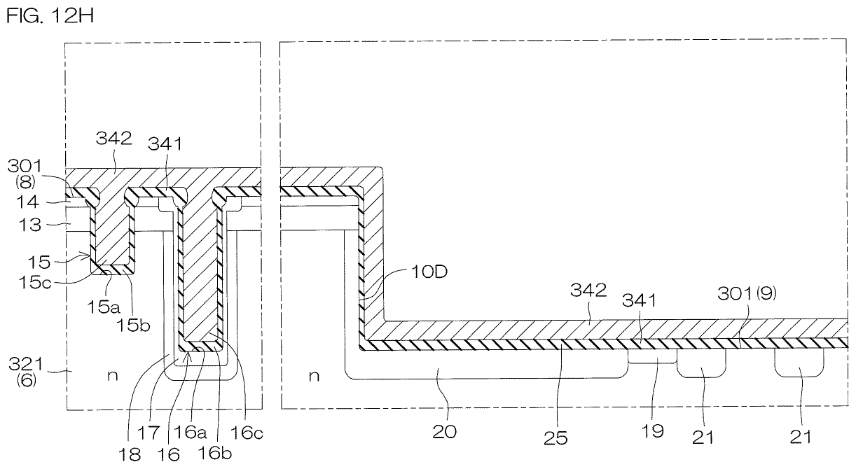

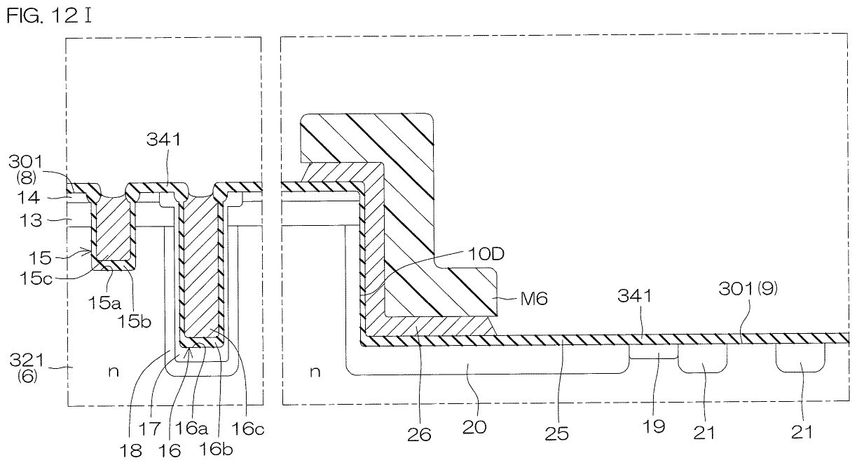

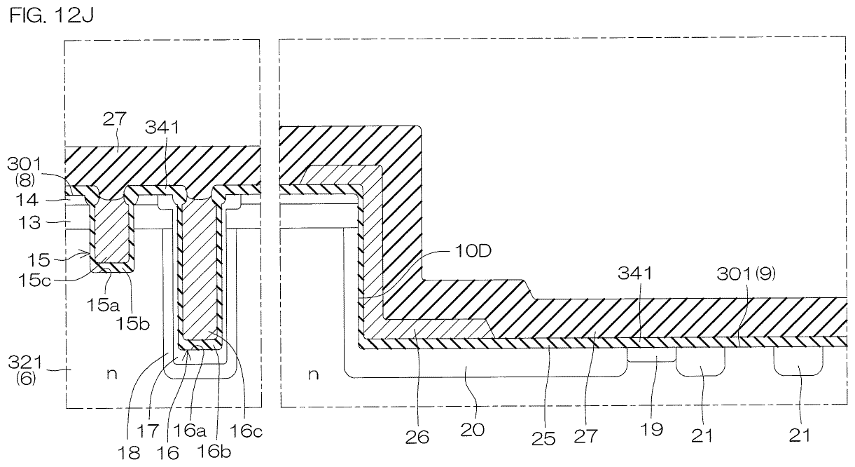

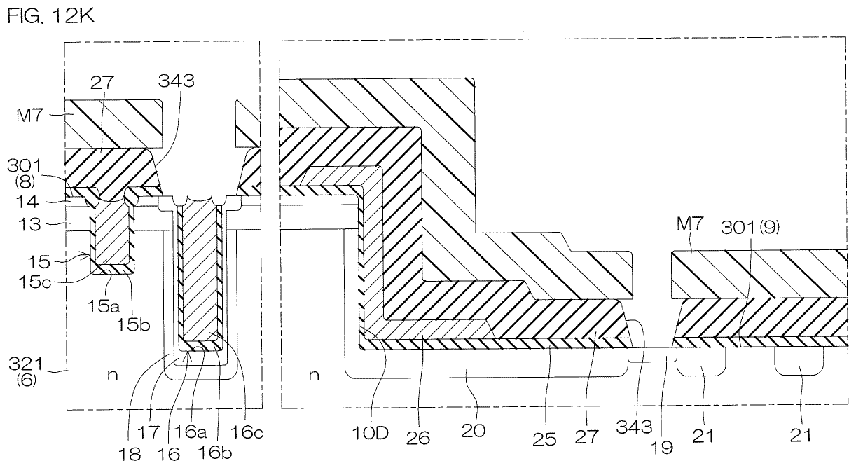

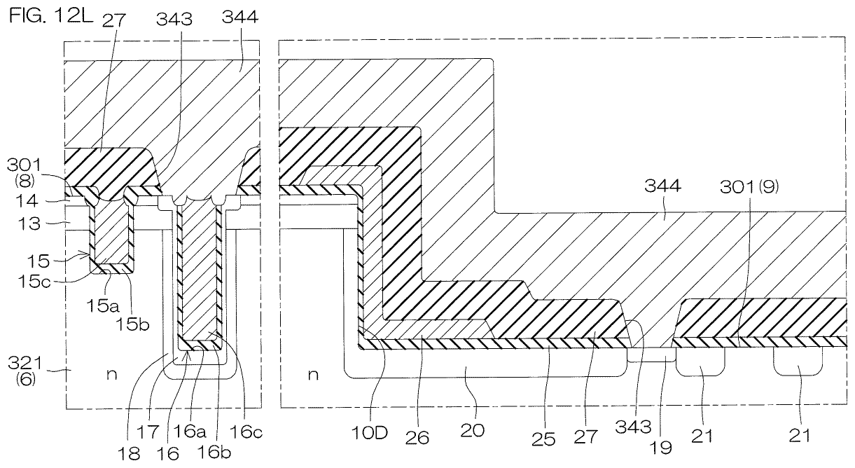

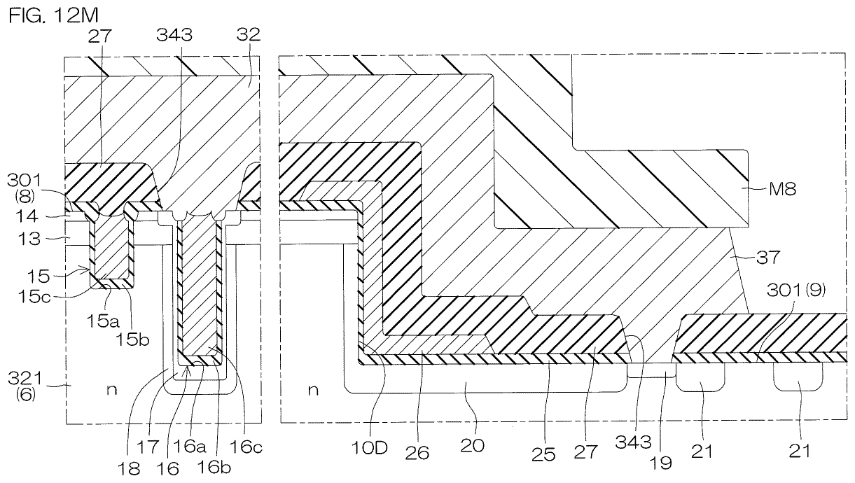

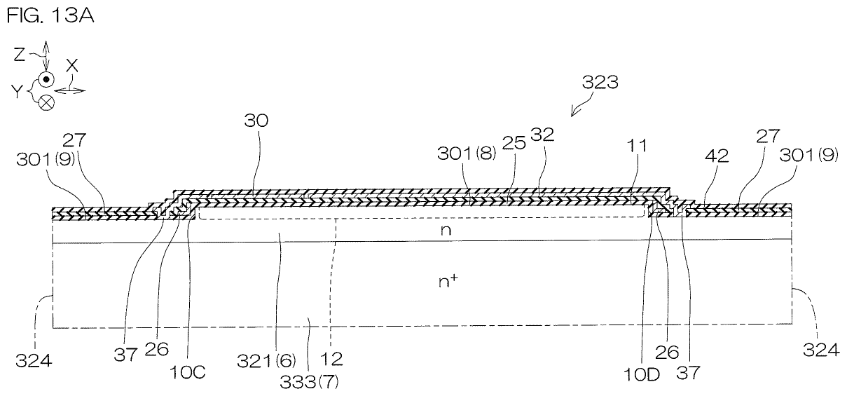

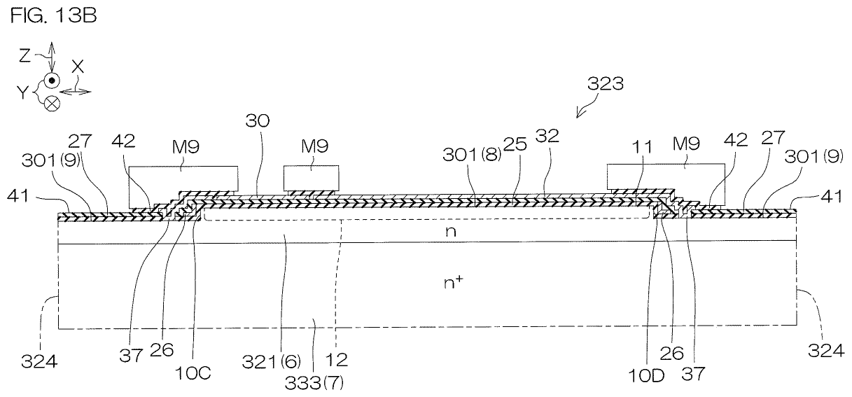

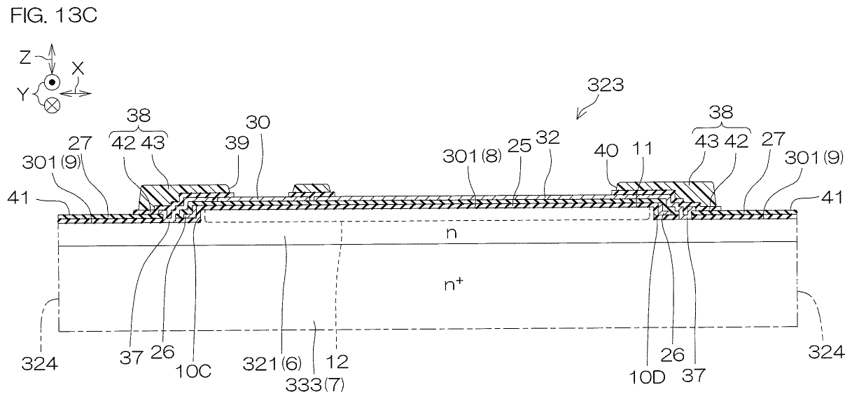

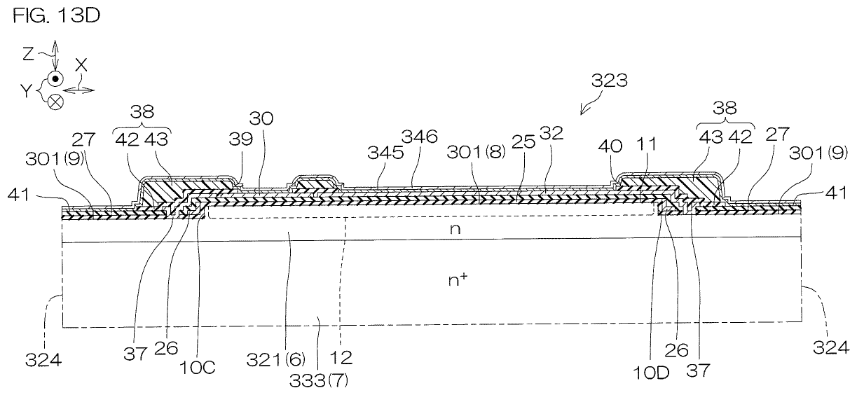

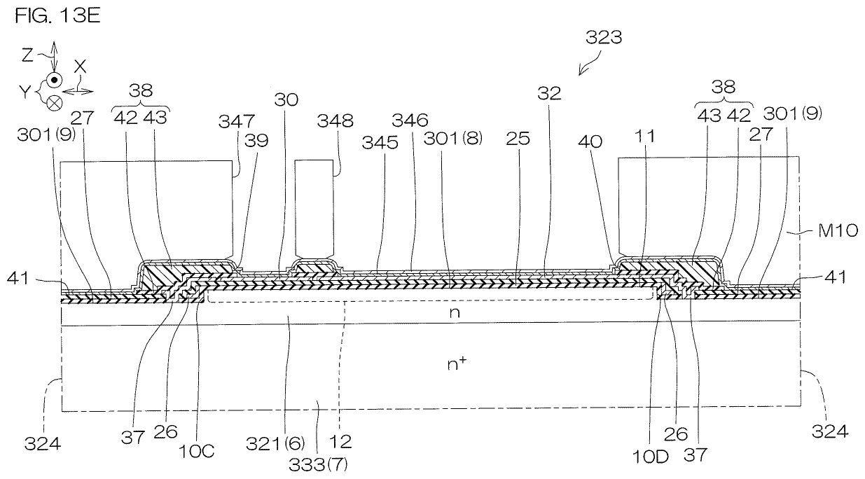

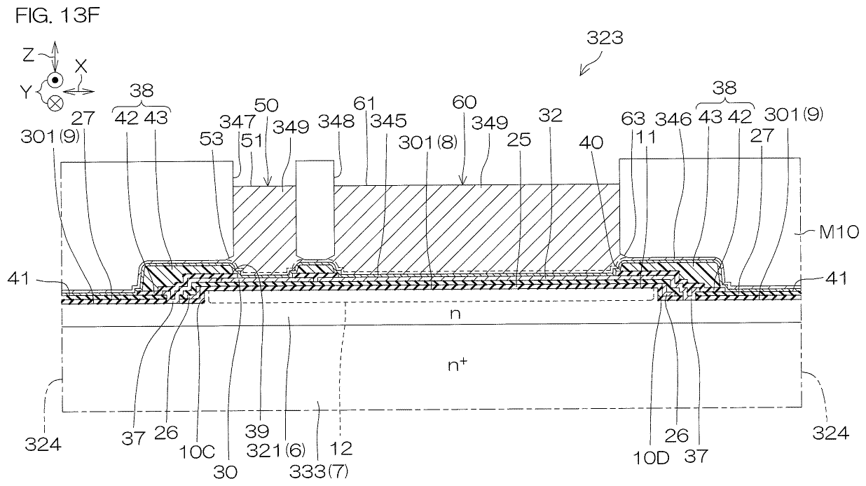

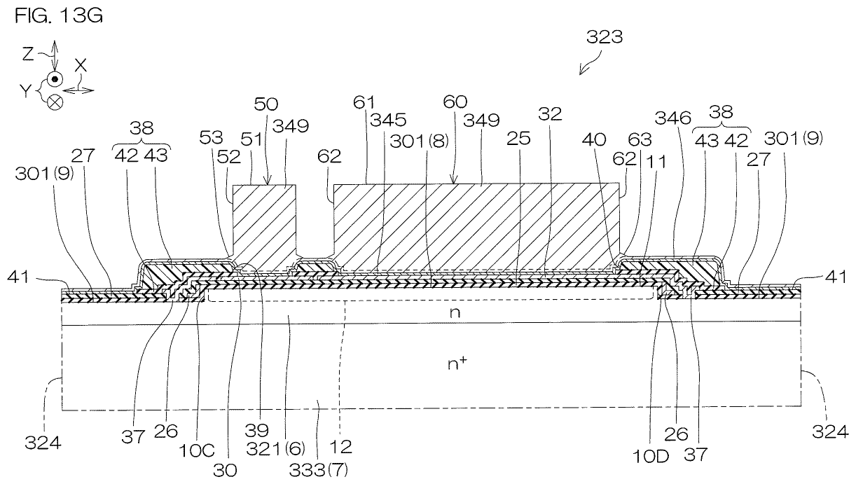

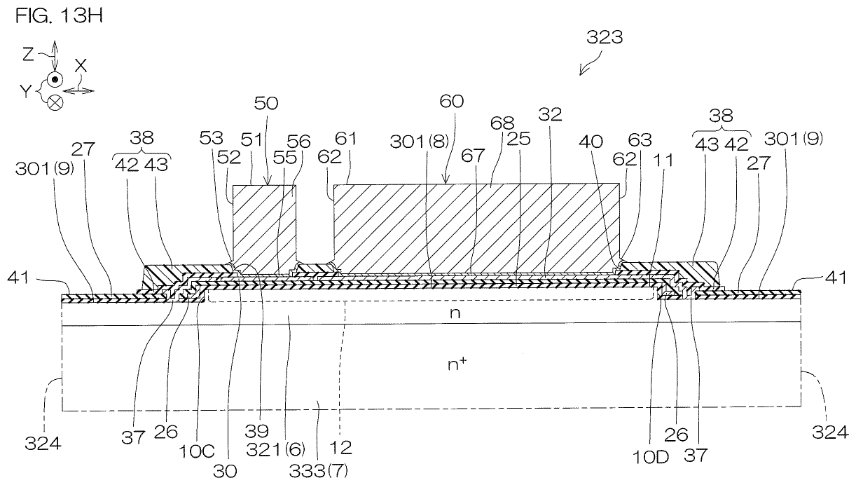

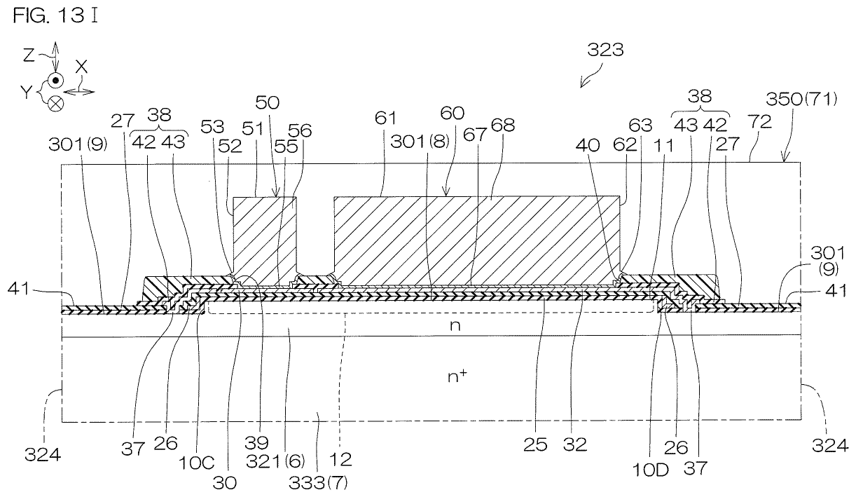

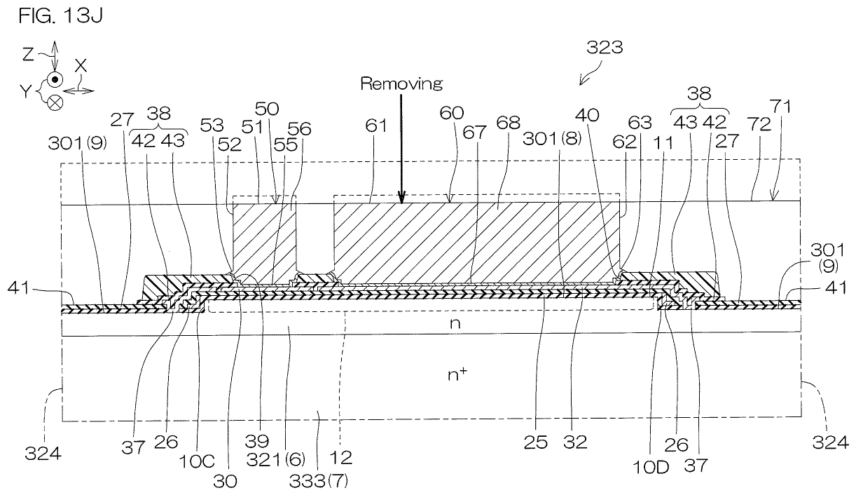

Hereinafter, an example of the forming step of a device structure 325 (step S4 of FIG. 9) shall be illustrated. FIG. 11 is a flowchart showing the example of the forming step of the device structure 325 (step S4 of FIG. 9) shown in FIG. 9. FIG. 12A to FIG. 12M are cross sectional views showing up to a forming step of the gate electrode 30 (source electrode 32) in the example of the forming step of the device structure 325 shown in FIG. 11. FIG. 13A to FIG. 13J are cross sectional views showing steps onward from the forming step of the gate electrode 30 (source electrode 32) in the example of the forming step of the device structure 325 shown in FIG. 11.

In FIG. 12A to FIG. 12M, a principal part of the active surface 8 is shown in a region at a left side of the sheet and a principal part of the outer surface 9 is shown at a right side of the sheet. In FIG. 13A to FIG. 13J, a cross section that includes one device region 323 is shown. Descriptions of specific features of respective structures formed in the respective steps shown in FIG. 12A to FIG. 12M and FIG. 13A to FIG. 13J are as have been described above and shall be omitted or simplified.

With reference to FIG. 12A, after the forming step of the epitaxial layer 321 (step S3 of FIG. 9), the body region 13 of the p-type and the source region 14 of the n-type are formed in the surface layer portion of the first main surface 301 (step S4A of FIG. 11). The body region 13 is formed in a whole region of the surface layer portion of the first main surface 301 by introduction of a p-type impurity into the first main surface 301 in this step. The source region 14 is formed in the whole region of the surface layer portion of the first main surface 301 by introduction of the n-type impurity into the first main surface 301 in this step. The forming step of the source region 14 may be performed after the forming step of the body region 13 or may be performed before the forming step of the body region 13.

Next, with reference to FIG. 12B, a first mask M1 having a predetermined pattern is formed on the first main surface 301 (step S4B of FIG. 11). In this Description, the term “mask” is used as a concept including a single layer structure or a laminated structure of any lamination order that includes at least one among a hard mask including an inorganic insulator and a soft mask (for example, a resist mask) including an organic insulator.

The first mask M1 exposes regions in which a plurality of the gate trenches 15a, a plurality of the source trenches 16a, and the outer surface 9 are to be formed and covers regions other than these. Next, unnecessary portions of the epi-wafer source 322 (specifically, the epitaxial layer 321) are removed by an etching method via the first mask M1. The etching method may be a wet etching method and/or a dry etching method. The plurality of gate trenches 15a, the plurality of source trenches 16a, and the outer surface 9 are thereby formed in the first main surface 301. Also, the mesa portion 11 that includes the active surface 8, the outer surface 9, and the first to fourth connecting surfaces 10A to 10D is formed on the first main surface 301.

Next, with reference to FIG. 12C, a second mask M2 having a predetermined pattern is formed on the first main surface 301. The second mask M2 covers the plurality of gate trenches 15a and exposes the plurality of source trenches 16a and the outer surface 9. Next, unnecessary portions of the epi-wafer source 322 (specifically, the epitaxial layer 321) are removed by an etching method via the second mask M2. The etching method may be a wet etching method and/or a dry etching method. The plurality of source trenches 16a and the outer surface 9 are thereby dug deeper.

Next, with reference to FIG. 12D, a third mask M3 having a predetermined pattern is formed on the first main surface 301 (step S4C of FIG. 11). The third mask M3 exposes regions in which the plurality of well regions 18 and the outer well region 20 are to be formed and covers regions other than these. Next, a p-type impurity is introduced into the surface layer portion of the first main surface 301 via the third mask M3. The plurality of well regions 18 and the outer well region 20 are thereby formed in the surface layer portion of the first main surface 301.

Next, with reference to FIG. 12E, a fourth mask M4 having a predetermined pattern is formed on the first main surface 301 (step S4D of FIG. 11). The fourth mask M4 exposes regions in which the plurality of field regions 21 are to be formed and covers regions other than these. Next, a p-type impurity is introduced into the surface layer portion of the first main surface 301 via the fourth mask M4. The plurality of field regions 21 are thereby formed in the surface layer portion of the first main surface 301.

Next, with reference to FIG. 12F, a fifth mask M5 having a predetermined pattern is formed on the first main surface 301 (step S4E of FIG. 11). The fifth mask M5 exposes regions in which the plurality of contact regions 17 and the outer contact region 19 are to be formed and covers regions other than these. Next, a p-type impurity is introduced into the surface layer portion of the first main surface 301 via the fifth mask M5. The plurality of contact regions 17 and the outer contact region 19 are thereby formed in the surface layer portion of the first main surface 301. The order of steps of steps S4C to S4E of FIG. 11 is arbitrary and may be interchanged as appropriate.

Next, with reference to FIG. 12G, a base insulating film 341 that covers the first main surface 301 is formed (step S4F of FIG. 11). The base insulating film 341 becomes a base of the gate insulating 15b, the source insulating film 16b, and the main surface insulating film 25. The base insulating film 341 may be formed by a CVD (chemical vapor deposition) method and/or a thermal oxidation treatment method.

Next, with reference to FIG. 12H, a base electrode film 342 is formed on the first main surface 301 (step S4G of FIG. 11). The base electrode film 342 becomes a base of a plurality of the gate embedded electrodes 15c, a plurality of the source embedded electrodes 16c, and the side wall structure 26. The base electrode film 342 includes a conductive polysilicon film in this step. The base electrode film 342 may be formed by a CVD method. The base electrode film 342 fills the plurality of gate trenches 15a and the plurality of source trenches 16a and covers the first main surface 301 (the active surface 8, the outer surface 9, and the first to fourth connecting surfaces 10A to 10D).

Next, with reference to FIG. 121, a sixth mask M6 having a predetermined pattern is formed on the base electrode film 342. The sixth mask M6 covers a region in which the side wall structure 26 is to be formed and exposes regions other than this. Next, unnecessary portions of the base electrode film 342 are removed by an etching method via the sixth mask M6. The etching method may be a wet etching method and/or a dry etching method. The plurality of gate embedded electrodes 15c, the plurality of source embedded electrodes 16c, and the side wall structure 26 are thereby formed.

Next, with reference to FIG. 12J, the interlayer insulating film 27 is formed on the first main surface 301 (step S4H of FIG. 11). The interlayer insulating film 27 covers the structures on the first main surface 301 collectively. The interlayer insulating film 27 may be formed by a CVD method.

Next, with reference to FIG. 12K, a seventh mask M7 having a predetermined pattern is formed on the interlayer insulating film 27. The seventh mask M7 selectively exposes portions of the interlayer insulating film 27 covering the plurality of gate structures 15, the plurality of source structures 16, the contact region 17, and the outer contact region 19 and covers regions other than these. Next, unnecessary portions of the interlayer insulating film 27 and unnecessary portions of the base insulating film 341 are removed by an etching method via the seventh mask M7. The etching method may be a wet etching method and/or a dry etching method. A plurality of penetrating holes 343 respectively exposing the plurality of gate structures 15, the plurality of source structures 16, the contact region 17, and the outer contact region 19 are thereby formed in the interlayer insulating film 27.

Next, with reference to FIG. 12L, a base main surface electrode film 344 is formed on the interlayer insulating film 27 such as to fill the plurality of penetrating holes 343 (step S4I of FIG. 11). The base main surface electrode film 344 becomes a base of the gate electrode 30, the source electrode 32, the plurality of gate wirings 36A and 36B, and the source wiring 37. The base main surface electrode film 344 may be formed by at least one method among a sputtering method, a vapor deposition method, and a plating method.

Next, with reference to FIG. 12M, an eighth mask M8 having a predetermined pattern is formed on the base main surface electrode film 344. The eighth mask M8 covers regions of the base main surface electrode film 344 in which the gate electrode 30, the source electrode 32, the plurality of gate wirings 36A and 36B, and the source wiring 37 are to be formed and exposes regions other than these. Next, unnecessary portions of the base main surface electrode film 344 are removed by an etching method via the eighth mask M8. The etching method may be a wet etching method and/or a dry etching method. The gate electrode 30, the source electrode 32, the plurality of gate wirings 36A and 36B, and the source wiring 37 are thereby formed.

Next, with reference to FIG. 13A, the inorganic insulating film 42 is formed on the first main surface 301 (step S4J of FIG. 11). The inorganic insulating film 42 covers the interlayer insulating film 27, the gate electrode 30, the source electrode 32, the plurality of gate wirings 36A and 36B, and the source wiring 37. The inorganic insulating film 42 may be formed by a CVD method.

Next, with reference to FIG. 13B, a ninth mask M9 having a predetermined pattern is formed on the inorganic insulating film 42. The ninth mask M9 exposes regions of the inorganic insulating film 42 in which the gate opening 39, the source opening 40, and the dicing street 41 are to be formed and covers regions other than these.

Next, unnecessary portions of the inorganic insulating film 42 are removed by an etching method via the ninth mask M9. The etching method may be a wet etching method and/or a dry etching method. The inorganic insulating film 42 that demarcates the gate opening 39, the source opening 40, and the dicing street 41 is thereby formed.

Next, with reference to FIG. 13C, the organic insulating film 43 is formed on the inorganic insulating film 42. In this step, first, a photosensitive resin is coated onto the inorganic insulating film 42. Next, the photosensitive resin is exposed and developed in a pattern corresponding to the gate opening 39, the source opening 40, and the dicing street 41. The organic insulating film 43 that forms the upper insulating film 38 together with the inorganic insulating film 42 and demarcates the gate opening 39, the source opening 40, and the dicing street 41 is thereby formed.

The dicing street 41 crosses the scheduled cutting lines 324 such as to expose the scheduled cutting lines 324 and straddles the plurality of device regions 323. The dicing street 41 is formed in a lattice that extends along the plurality of scheduled cutting lines 324. The dicing street 41 exposes the interlayer insulating film 27 in this embodiment. The ninth mask M9 mentioned above may be the organic insulating film 43. That is, the unnecessary portions of the inorganic insulating film 42 mentioned above may be removed by an etching method via the organic insulating film 43.

Next, with reference to FIG. 13D, a first base conductor film 345 that is to be a base of the first gate conductor film 55 and the first source conductor film 67 is formed on the first main surface 301 (step S4K of FIG. 11). The first base conductor film 345 is formed as a film along the interlayer insulating film 27, the gate electrode 30, the source electrode 32, the plurality of gate wirings 36A and 36B, the source wiring 37, and the upper insulating film 38. The first base conductor film 345 includes a Ti-based metal film. The first base conductor film 345 may be formed by a sputtering method and/or a vapor deposition method.

Next, a second base conductor film 346 that is to be a base of the second gate conductor film 56 and the second source conductor film 68 is formed on the first base conductor film 345. The second base conductor film 346 covers the interlayer insulating film 27, the gate electrode 30, the source electrode 32, the plurality of gate wirings 36A and 36B, the source wiring 37, and the upper insulating film 38 as a film with the first base conductor film 345 interposed therebetween. The second base conductor film 346 includes a Cu-based metal film. The second base conductor film 346 may be formed by a sputtering method and/or a vapor deposition method.

Next, with reference to FIG. 13E, a tenth mask M10 having a predetermined pattern is formed on the second base conductor film 346. The tenth mask M10 includes a first opening 347 that exposes the gate electrode 30 and a second opening 348 that exposes the source electrode 32. The first opening 347 exposes, in a region on the gate electrode 30, a region in which the gate terminal electrode 50 is to be formed. The second opening 348 exposes, in a region on the source electrode 32, a region in which the source terminal electrode 60 is to be formed.

This step includes a step of lowering an adhesive property of the tenth mask M10 with respect to the second base conductor film 346. The adhesive property of the tenth mask M10 is adjusted by adjusting exposure conditions and baking conditions (quenching temperature and time, etc.) after exposure for the tenth mask M10. Thereby, a growing starting point of the first protrusion portion 53 is formed at a lower end portion of the first opening 347 and a growing starting point of the second protrusion portion 63 is formed at a lower end portion of the second opening 348.

Next, with reference to FIG. 13F, a third base conductor film 349 that is to be a base of the second gate conductor film 56 and the second source conductor film 68 is formed on the second base conductor film 346. The third base conductor film 349 is formed by depositing a conductor (in this embodiment, a Cu-based metal) inside the first opening 347 and the second opening 348 by a plating method (for example, an electrolytic plating method) in this embodiment. The third base conductor film 349 is made integral with the second base conductor film 346 inside the first opening 347 and the second opening 348. The gate terminal electrode 50 that covers the gate electrode 30 is thereby formed. Also, the source terminal electrode 60 that covers the source electrode 32 is formed.

This step includes a step of making a plating solution enter between the second base conductor film 346 and the tenth mask M10 at the lower end portion of the first opening 347. Also, this step includes a step of making the plating solution enter between the second base conductor film 346 and the tenth mask M10 at the lower end portion of the second opening 348. Thereby, a portion (the gate terminal electrode 50) of the third base conductor film 349 is grown in a protruding shape at the lower end portion of the first opening 347 and the first protrusion portion 53 is formed. Also, a portion (the source terminal electrode 60) of the third base conductor film 349 is grown in a protruding shape at the lower end portion of the second opening 348 and the second protrusion portion 63 is formed.

Next, with reference to FIG. 13G, the tenth mask M10 is removed. The gate terminal electrode 50 and the source terminal electrode 60 are thereby exposed to the exterior.

Next, with reference to FIG. 13H, portions of the second base conductor film 346 that are exposed from the gate terminal electrode 50 and the source terminal electrode 60 are removed. The unnecessary portions of the second base conductor film 346 may be removed by an etching method. The etching method may be a wet etching method and/or a dry etching method. Next, portions of the first base conductor film 345 that are exposed from the gate terminal electrode 50 and the source terminal electrode 60 are removed. The unnecessary portions of the first base conductor film 345 may be removed by an etching method. The etching method may be a wet etching method and/or a dry etching method.

Next, with reference to FIG. 131, a sealant 350 is supplied onto the first main surface 301 such as to cover the gate terminal electrode 50 and the source terminal electrode 60 (step S4L of FIG. 11). The sealant 350 becomes a base of the sealing insulator 71. The sealant 350 is supplied onto the first main surface 301 such as to cover a whole region of the plurality of device regions 323 collectively. Specifically, in each device region 323, the sealant 350 covers a periphery of the gate terminal electrode 50 and a periphery of the source terminal electrode 60 and covers a whole region of the upper insulating film 38, a whole region of the gate terminal electrode 50, and a whole region of the source terminal electrode 60.

The sealant 350 includes the thermosetting resin, the plurality of fillers, and the plurality of flexibility imparting particles (flexibility imparting agents) and is hardened by heating in this embodiment. The sealing insulator 71 is thereby formed. The sealing insulator 71 has the insulating main surface 72 that covers the whole region of the gate terminal electrode 50, and the whole region of the source terminal electrode 60.

Next, with reference to FIG. 13J, the sealing insulator 71 is partially removed (step S4M of FIG. 11). The sealing insulator 71 is ground from the insulating main surface 72 side by a grinding method in this embodiment. The grinding step may be a mechanical polishing method or may be a chemical mechanical polishing method. The insulating main surface 72 is ground until the gate terminal electrode 50 and the source terminal electrode 60 become exposed. This step includes a grinding step of the gate terminal electrode 50 and the source terminal electrode 60.

The insulating main surface 72 that forms a single ground surface with the gate terminal electrode 50 (gate terminal surface 51) and the source terminal electrode 60 (source terminal surface 61) is thereby formed. The device structure 325 is formed in each device region 323 through steps including the above. Thereafter, the forming step of the modified layer 326 (step S5 of FIG. 9) is performed.

As described above, the first manufacturing method example for the semiconductor device 1A includes the preparing step of the wafer source 300 (step S1 of FIG. 9), the forming step of the gate electrode 30 (source electrode 32) (step S4I of FIG. 11), the forming step of the gate terminal electrode 50 (source terminal electrode 60) (step S4K of FIG. 11), the forming step of the sealing insulator 71 (step S4L of FIG. 11), and the separating step of the wafer source 300 (step S6 of FIG. 9).

In the preparing step of the wafer source 300, the wafer source 300 having the first main surface 301 on one side and the second main surface 302 on the other side is prepared. In the forming step of the gate electrode 30 (source electrode 32), the gate electrode 30 (source electrode 32) is formed on the first main surface 301. In the forming step of the gate terminal electrode 50 (source terminal electrode 60), the gate terminal electrode 50 (source terminal electrode 60) is formed on the gate electrode 30 (source electrode 32).

In the forming step of the sealing insulator 71, the sealing insulator 71 that covers the periphery of the gate terminal electrode 50 (source terminal electrode 60) on the first main surface 301 such as to expose a portion of the gate terminal electrode 50 (source terminal electrode 60) is formed. In the separating step of the wafer source 300, the wafer source 300 is cut in the horizontal direction along the first main surface 301 from the intermediate portion of the thickness range of the wafer source 300. By this step, the wafer source 300 is separated into the sealed wafer 331 on the sealing insulator 71 side and the unsealed wafer 332 at the second main surface 302 side.

According to this manufacturing method, the sealed wafer 331 thinner than the wafer source 300 is separated, in the state of being supported by the sealing insulator 71, from the wafer source 300. Therefore, deformation of the sealed wafer 331 can be suppressed by the sealing insulator 71 and, at the same time, the sealed wafer 331 can be handled with the sealing insulator 71 as the supporting member. Shape defects and fluctuations in electrical characteristics of the sealed wafer 331 due to deformation (for example, warping that accompanies thinning) can thereby be suppressed.

Also, according to this structure, the sealed wafer 331 can be protected from an external force and humidity by the sealing insulator 71. That is, the sealed wafer 331 can be protected from damage due to the external force and deterioration due to the humidity. Shape defects and fluctuations in electrical characteristics can thereby be suppressed. As a result, it is possible to provide an efficient manufacturing method for the semiconductor device 1A having high reliability.

Also, according to this manufacturing method, it is also possible to leave room for reuse of the unsealed wafer 332. Thereby, consumption of the wafer source 300 can be suppressed and the number of the semiconductor devices 1A that can be acquired from the single wafer source 300 can be increased. A manufacturing cost can thus be reduced. In a case in which the wafer source 300 includes the monocrystal of the wide bandgap semiconductor (particularly, the SiC monocrystal) that is comparatively expensive, the manufacturing cost due to the wide bandgap semiconductor can be reduced. Such a manufacturing method is thus particularly beneficial in a case in which the wafer source 300 includes the monocrystal of the wide bandgap semiconductor. In the preparing step of the wafer source 300, it is preferable to prepare the wafer source 300 cut out from the ingot.

The separating step of the wafer source 300 preferably includes the step of cutting out the sealed wafer 331 that is thinner than the sealing insulator 71. According to this manufacturing method, the sealed wafer 331 that is comparatively thin can be cut out appropriately because the deformation of the sealed wafer 331 is suppressed by the sealing insulator 71. By the comparatively thin sealed wafer 331, the semiconductor device 1A that can be improved in electrical characteristics by reduction of a resistance value (for example, an on resistance) and has high reliability can be manufactured. Also, according to this manufacturing method, a remaining amount of the unsealed wafer 332 can be increased. Therefore, in a case where the wafer source 300 is reused, the consumption of the wafer source 300 can be suppressed and a manufacturing efficiency can be improved.

As a matter of course, the separating step of the wafer source 300 may include the step of cutting out the sealed wafer 331 that is thicker than the sealing insulator 71. In this case, the manufacturing method for the semiconductor device 1A preferably includes the step, after the separating step of the wafer source 300, of thinning the sealed wafer 331 until the sealed wafer 331 becomes less in thickness than the thickness of the sealing insulator 71 (step S4M of FIG. 11). Even by such the manufacturing method, the comparatively thin sealed wafer 331 can be formed appropriately. Also, the electrical characteristics can be improved by the reduction of the resistance value (for example, the on resistance).

The manufacturing method for the semiconductor device 1A preferably includes the step of reusing the unsealed wafer 332 (step S10 of FIG. 9). In this case, the unsealed wafer 332 may be reused as the wafer source 300 for manufacturing the semiconductor device 1A. As a matter of course, the unsealed wafer 332 may be used as the wafer source 300 for manufacturing another semiconductor device different from the semiconductor device 1A. Also, the unsealed wafer 332 may be used as another member such as the supporting substrate 310, etc.

The reusing step of the unsealed wafer 332 preferably includes the step of thinning the unsealed wafer 332 from the second cut surface 336 side (step S11 of FIG. 9). According to this manufacturing method, shape defects and fluctuations in electrical characteristics of the unsealed wafer 332 can be suppressed. The unsealed wafer 332 can thus be reused appropriately. The thinning step of the unsealed wafer 332 preferably includes the step of smoothening the second cut surface 336. The smoothening step of the second cut surface 336 preferably includes the step of grinding the second cut surface 336.

The separating step of the wafer source 300 preferably includes the step of cutting out the sealed wafer 331 that is thinner than the gate terminal electrode 50 (source terminal electrode 60). As a matter of course, the separating step of the wafer source 300 may include the step of cutting out the sealed wafer 331 that is thicker than the gate terminal electrode 50 (source terminal electrode 60). In this case, the manufacturing method for the semiconductor device 1A preferably includes the step, after the separating step of the wafer source 300, of thinning the sealed wafer 331 until the sealed wafer 331 becomes less in thickness than the thickness of the gate terminal electrode 50 (source terminal electrode 60) (step S4M of FIG. 11). According to these manufacturing methods, the semiconductor device 1A that is excellent in heat dissipation and has high reliability can be manufactured.

The separating step of the wafer source 300 may include the step of cutting out the unsealed wafer 332 that is thicker than the sealed wafer 331. According to this manufacturing method, a reusability of the unsealed wafer 332 can be increased. Such a manufacturing method can be realized, for example, by setting in advance the number of sealed wafers 331 to be acquired from the single wafer source 300 and performing thickness adjustment of the wafer source 300. The separating step of the wafer source 300 may include the step of cutting out the unsealed wafer 332 that is thicker than the sealing insulator 71.

The separating step of the wafer source 300 preferably includes the step of forming, by the laser light irradiating method, the modified layer 326 that extends along the horizontal direction at the intermediate portion of the thickness range of the wafer source 300 and thereafter cleaving the wafer source 300 in the horizontal direction with the modified layer 326 as the starting point. According to this manufacturing method, the wafer source 300 does not have to be separated by cutting. Therefore, the wafer source 300 can be separated efficiently while suppressing the consumption of the wafer source 300.

Such a manufacturing method is particularly beneficial in a case in which the wafer source 300 includes the monocrystal of the wide bandgap semiconductor (particularly, the SiC monocrystal) that has a higher hardness than Si. By the forming step of the modified layer 326, the wide bandgap semiconductor having the comparatively high hardness can be cleaved easily. A manufacturing efficiency pertaining to the wide bandgap semiconductor can thus be improved.

The forming step of the modified layer 326 preferably includes the step of irradiating the laser light into the wafer source 300 from the second main surface 302 side of the wafer source 300. According to this manufacturing method, the laser light is irradiated into the interior of the wafer source 300 from the second main surface 302 at which the sealing insulator 71 is not present. Thus, the modified layer 326 can be formed appropriately inside the wafer source 300 and the wafer source 300 can be cleaved appropriately.

The manufacturing method for the semiconductor device 1A preferably includes the step of attaching the supporting substrate 310 to the second main surface 302 before the forming step of the gate electrode 30 (source electrode 32) (step S2 of FIG. 9). In this case, the separating step of the wafer source 300 preferably includes the step of separating the wafer source 300 in the state of being supported by the supporting substrate 310 and the sealing insulator 71. Further in this case, the forming step of the modified layer 326 preferably includes the step of irradiating the laser light into the wafer source 300 via the supporting substrate 310.

According to these manufacturing methods, the wafer source 300 is separated into the sealed wafer 331 on the sealing insulator 71 side and the unsealed wafer 332 on the supporting substrate 310 side. Thereby, the deformation of the sealed wafer 331 can be suppressed by the sealing insulator 71 and the deformation of the unsealed wafer 332 can be suppressed by the supporting substrate 310. Also, the sealed wafer 331 can be handled (transferred) with the sealing insulator 71 as the supporting member and the unsealed wafer 332 can be handled (transferred) with the supporting substrate 310 as the supporting member. The manufacturing efficiency can thus be improved.

The manufacturing method for the semiconductor device 1A preferably includes the step of thinning the sealed wafer 331 from the first cut surface 334 side in the state of being supported by the sealing insulator 71 (step S7 of FIG. 9). According to this manufacturing method, shape defects and fluctuations in electrical characteristics due to the first cut surface 334 can be suppressed. The semiconductor device 1A having a high reliability can thus be manufactured. In this case, the thinning step of the sealed wafer 331 preferably includes the step of smoothening the first cut surface 334 of the sealed wafer 331. The smoothening step of the first cut surface 334 preferably includes the step of grinding the first cut surface 334.

The manufacturing method for the semiconductor device 1A preferably includes the step of forming the drain electrode 77 (second main surface electrode) that covers the first cut surface 334 of the sealed wafer 331 (step S8 of FIG. 9). The manufacturing method for the semiconductor device 1A preferably includes the step of cutting the sealed wafer 331 together with the sealing insulator 71 (step S9 of FIG. 9).

The forming step of the sealing insulator 71 preferably includes the step of forming the sealing insulator 71 that covers the whole region of the gate terminal electrode 50 (source terminal electrode 60) and the step of removing the sealing insulator 71 until a portion of the gate terminal electrode 50 (source terminal electrode 60) becomes exposed. The forming step of the sealing insulator 71 preferably includes the step of supplying the sealant 350 that includes the thermosetting resin onto the first main surface 301 and thermosetting the sealant 350.

The manufacturing method for the semiconductor device 1A preferably includes the step, before the forming step of the gate terminal electrode 50 (source terminal electrode 60), of forming the upper insulating film 38 that partially covers the gate electrode 30 (source electrode 32) (step S4J of FIG. 11). In this case, the forming step of the sealing insulator 71 preferably includes the step of forming the sealing insulator 71 that covers the gate terminal electrode 50 (source terminal electrode 60) and the upper insulating film 38.

The forming step of the gate terminal electrode 50 (source terminal electrode 60) preferably includes the step of forming the gate terminal electrode 50 (source terminal electrode 60) having the portion that directly covers the upper insulating film 38. The forming step of the upper insulating film 38 preferably includes the step of forming the upper insulating film 38 that includes at least one among the inorganic insulating film 42 and the organic insulating film 43.

The forming step of the gate terminal electrode 50 (source terminal electrode 60) preferably includes the step of forming the second base conductor film 346 (conductor film) that covers the gate electrode 30 (source electrode 32), the step of forming, on the second base conductor film 346, the tenth mask M10 that exposes the portion of the second base conductor film 346 covering the gate electrode 30 (source electrode 32), the step of depositing the third base conductor film 349 (conductor film) on the portion of the second base conductor film 346 exposed from the tenth mask M10, and the step of removing the tenth mask M10 after the depositing step of the third base conductor film 349.

The manufacturing method for the semiconductor device 1A preferably includes the step, before the forming step of the gate electrode 30 (source electrode 32), of forming the epi-wafer source 322 (wafer structure) (step S3 of FIG. 9). In the forming step of the epi-wafer source 322, the epitaxial layer 321 is grown from the first main surface 301. The epi-wafer source 322 that includes the wafer source 300 and the epitaxial layer 321 and has the first main surface 301 formed by the epitaxial layer 321 is thereby formed.

In this case, in the separating step of the wafer source 300, the sealed wafer 331 and the unsealed wafer 332 that have mutually different arrangements are cut out from the epi-wafer source 322. Specifically, the sealed wafer 331 having the laminated structure that includes the first wafer portion 333 consisting of a portion of the wafer source 300 and the epitaxial layer 321 laminated on the first wafer portion 333 is cut out and the unsealed wafer 332 having the single layer structure that includes the second wafer portion 335 consisting of a portion of the wafer source 300 is cut out.

In this case, the sealed wafer 331 preferably includes the first wafer portion 333 that is thinner than the epitaxial layer 321. According to this manufacturing method, a resistance value (for example, an on resistance) due to the first wafer portion 333 can be reduced. As a matter of course, the sealed wafer 331 may include the first wafer portion 333 that is thicker than the epitaxial layer 321.

In this case, the manufacturing method for the semiconductor device 1A preferably includes the step, after the separating step of the wafer source 300, of removing at least a portion of the first wafer portion 333 (step S7 of FIG. 9). Even according to such a manufacturing method, the resistance value (for example, the on resistance) due to the first wafer portion 333 can be reduced. In this case, the first wafer portion 333 is preferably removed until the first wafer portion 333 becomes less in thickness than the thickness of the epitaxial layer 321.

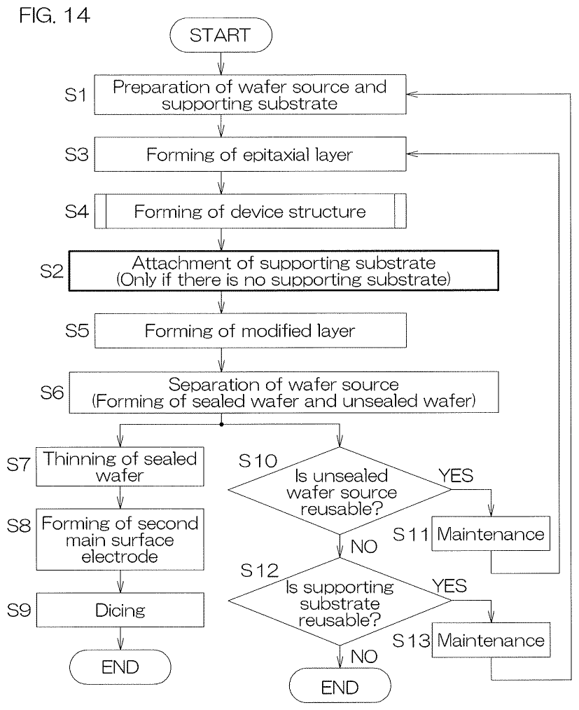

FIG. 14 is a flowchart showing the second manufacturing method example for the semiconductor device 1A shown in FIG. 1. With reference to FIG. 14, the second manufacturing method example is a manufacturing method with which the first manufacturing method example (see FIG. 9) is modified. Specifically, with the second manufacturing method example, the attaching step of the supporting substrate 310 to the wafer source 300 (step S2) is performed after the forming step of the device structure 325 (step S4: steps S4A to S4M) and before the forming step of the modified layer 326 (step S5). In the reusing step of the wafer source 300, the attaching step of the supporting substrate 310 (step S2) is omitted. As described above, the same effects as the effects of the first manufacturing method example are also achieved by the second manufacturing method example.

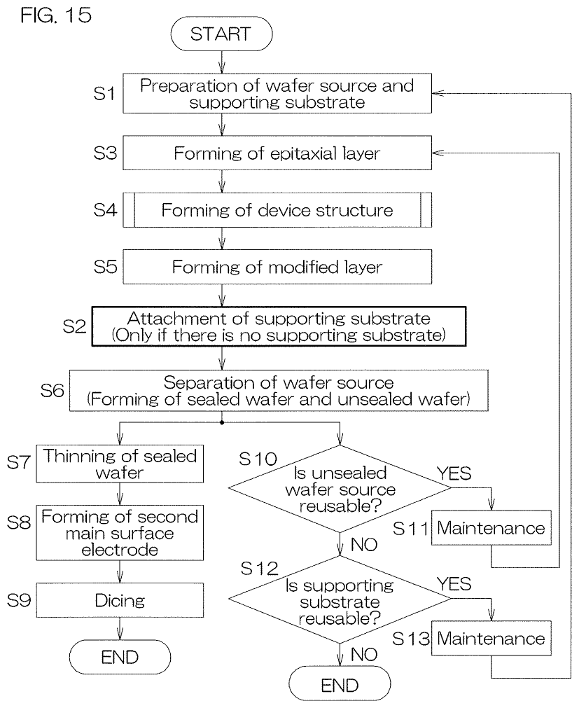

FIG. 15 is a flowchart showing the third manufacturing method example for the semiconductor device 1A shown in FIG. 1. With reference to FIG. 15, the third manufacturing method example is a manufacturing method with which the first manufacturing method example (see FIG. 9) is modified. Specifically, with the third manufacturing method example, the attaching step of the supporting substrate 310 to the wafer source 300 (step S2) is performed after the forming step of the modified layer 326 (see step S5).

In the forming step of the modified layer 326, the laser light is irradiated into the wafer source 300 from the second main surface 302 side in a state in which the supporting substrate 310 is not present and the modified layer 326 is formed. In the reusing step of the wafer source 300, the attaching step of the supporting substrate 310 (step S2) is omitted. As described above, the same effects as the effects of the first manufacturing method example are also achieved by the third manufacturing method example. Also, according to the third manufacturing method example, the modified layer 326 can be formed appropriately inside the wafer source 300.

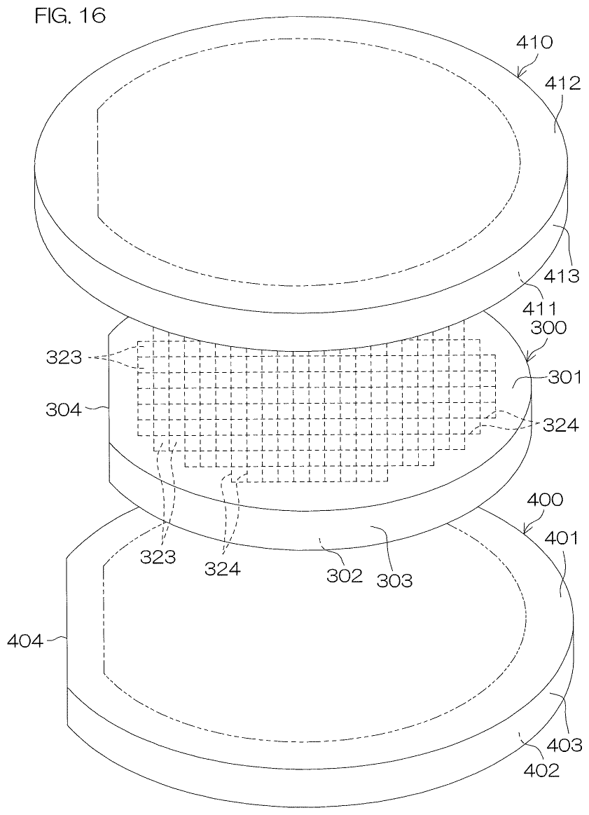

FIG. 16 is a perspective view showing the wafer source 300, a first supporting substrate 400, and a second supporting substrate 410 that are to be used in fourth and fifth manufacturing method examples for the semiconductor device 1A shown in FIG. 1. With reference to FIG. 16, the fourth and fifth manufacturing method examples have in common the point of using the wafer 300 with the first to third manufacturing method examples but differ from the first to third manufacturing method examples in that the first supporting substrate 400 and the second supporting substrate 410 are used in place of the supporting substrate 310. The description concerning the wafer source 300 is as has been stated above and shall thus be omitted.

The first supporting substrate 400 is a plate shaped member that supports the wafer source 300 from the second main surface 302 side. The first supporting substrate 400 may be formed in a disc shape or a circular columnar shape. As long as it can support the wafer source 300 from the second main surface 302 side, a material of the first supporting substrate 400 is arbitrary. The first supporting substrate 400 may consist of an inorganic plate, an organic plate, a metal plate, a crystal plate, or an amorphous plate (glass plate). Preferably, the first supporting substrate 400 consists of a light transmitting plate or a transparent plate and is arranged such as to suppress attenuation of laser light. A melting point of the first supporting substrate 400 is preferably not less than a melting point of the wafer source 300. A ratio of a thermal expansion coefficient of the first supporting substrate 400 with respect to the thermal expansion coefficient of the wafer source 300 is preferably not less than 0.5 and not more than 1.5.

The first supporting substrate 400 particularly preferably consists of the same material as the wafer source 300 (that is, SiC). In this case, the first supporting substrate 400 may consist of an SiC monocrystal or an SiC polycrystal. In this case, the first supporting substrate 400 preferably consists of a hexagonal SiC monocrystal. The first supporting substrate 400 consists of a 4H-SiC monocrystal in this embodiment. As a matter of course, the first supporting substrate 400 may consist of another polytype other than the 4H-SiC monocrystal. The first supporting substrate 400 consists of a crystal plate (that is, a wafer) of disc shape or circular columnar shape cut out from an ingot (SiC monocrystalline mass) by a slicing method in this embodiment.

An impurity concentration of the first supporting substrate 400 is set independently of the wafer source 300. The impurity concentration of the first supporting substrate 400 preferably differs from an impurity concentration of the wafer source 300. The impurity concentration of the first supporting substrate 400 is preferably less than the impurity concentration of the wafer source 300. The first supporting substrate 400 is particularly preferably undoped. In this case, absorption (attenuation) of laser light due to the first supporting substrate 400 is suppressed.

The first supporting substrate 400 may include vanadium as an impurity. If the first supporting substrate 400 includes an n-type impurity or a p-type impurity, the impurity concentration of the first supporting substrate 400 is preferably not more than 1×10¹¹ cm⁻³. It is noted that laser light having a wavelength of not more than 390 μm has a tendency to be absorbed (attenuated) by an SiC monocrystal regardless of whether or not it is doped with an impurity.

The first supporting substrate 400 has a first plate surface 401 on one side (the wafer source 300 side), a second plate surface 402 on the other side, and a plate side surface 403 that connects the first plate surface 401 and the second plate surface 402. The first plate surface 401 may consist of a ground surface, a cleaved surface, a polished surface, or a mirror surface. The second plate surface 402 may consist of a ground surface, a cleaved surface, a polished surface, or a mirror surface. A surface state of the second plate surface 402 does not necessarily have to be the same as a surface state of the first plate surface 401.

The first plate surface 401 and the second plate surface 402 are preferably arranged along c-planes of the SiC monocrystal. In this case, preferably, the first plate surface 401 is arranged along a silicon surface and the second plate surface 402 is arranged along a carbon surface. The first plate surface 401 and the second plate surface 402 may have an off angle inclined at a predetermined angle in a predetermined off direction with respect to the c-planes. The off direction is preferably the a-axis direction of the SiC monocrystal. The off angle may exceed 0° and be not more than 10°. The off angle is preferably not more than 5°. The off angle is particularly preferably not less than 2° and not more than 4.5°. The off direction and an off angle of the first supporting substrate 400 are preferably substantially equal to the off direction and the off angle of the wafer source 300.

A peripheral edge of the first plate surface 401 has a chamfered portion that is inclined obliquely. The chamfered portion of the first plate surface 401 may be a round chamfered portion or a 45 degree chamfered portion. A peripheral edge of the second plate surface 402 has a chamfered portion that is inclined obliquely. The chamfered portion of the second plate surface 402 may be a round chamfered portion or a 45 degree chamfered portion. One or both of the peripheral edge of the first plate surface 401 and the peripheral edge of the second plate surface 402 may lack a chamfered portion and be square. However, from a standpoint of handling, both the peripheral edge of the first plate surface 401 and the peripheral edge of the second plate surface 402 preferably have chamfered portions.

The first supporting substrate 400 has a second mark 404 that indicates the crystal orientation at the plate side surface 403. The second mark 404 is also a mark that indirectly indicates the crystal orientation of the wafer source 300. The second mark 404 includes an orientation flat that is notched rectilinearly in plan view in this embodiment. The orientation flat extends in the second direction Y in this embodiment. The orientation flat does not necessarily have to extend in the second direction Y and may extend in the first direction X.

As a matter of course, the second mark 404 may include an orientation flat extending in the first direction X and an orientation flat extending in the second direction Y. Also, in place of or in addition to the orientation flat, the second mark 404 may have an orientation notch that is notched toward the central portion of the wafer source 300. The orientation notch may be a notched portion that is notched in a polygonal shape such as a triangular shape or a quadrilateral shape, etc., in plan view.

A diameter and a thickness of the first supporting substrate 400 are arbitrary. The diameter of the first supporting substrate 400 is defined by a length of a chord passing through a center of the first supporting substrate 400 outside the second mark 404. In view of the handling of the wafer source 300, the first supporting substrate 400 preferably has a diameter not less than the diameter of the wafer source 300 and a thickness not less than the thickness of the wafer source 300. An interval between the peripheral edge of the wafer source 300 and the peripheral edge of the first supporting substrate 400 when the central portion of the wafer source 300 and a central portion of the first supporting substrate 400 are overlapped is preferably not less than 0 mm and not more than 10 mm.

The second supporting substrate 410 is a plate shaped member that supports the wafer source 300 from the first main surface 301 side. The second supporting substrate 410 may be formed in a disc shape or a circular columnar shape. As long as it can support the wafer source 300 from the first main surface 301 side, a material of the second supporting substrate 410 is arbitrary. The second supporting substrate 410 may consist of an inorganic plate, an organic plate, a metal plate, a crystal plate, or an amorphous plate (glass plate). The second supporting substrate 410 consists of a glass plate (silicon oxide plate) in this embodiment. That is, the second supporting substrate 410 may consist of a different material from the first supporting substrate 400. As a matter of course, the same supporting substrate as the first supporting substrate 400 may be used as the second supporting substrate 410.

The second supporting substrate 410 has a first plate surface 411 on one side (the wafer source 300 side), a second plate surface 412 on the other side, and a plate side surface 413 that connects the first plate surface 411 and the second plate surface 412. The first plate surface 411 may consist of a ground surface, a cleaved surface, a polished surface, or a mirror surface. The second plate surface 412 may consist of a ground surface, a cleaved surface, a polished surface, or a mirror surface. A surface state of the second plate surface 412 does not necessarily have to be the same as a surface state of the first plate surface 411. In a case in which the same supporting substrate as the first supporting substrate 400 described above is used as the second supporting substrate 410, the first plate surface 411 is set to a carbon surface and the second plate surface 412 is set to a silicon surface.

A peripheral edge of the first plate surface 411 has a chamfered portion that is inclined obliquely. The chamfered portion of the first plate surface 411 may be a round chamfered portion or a 45 degree chamfered portion. A peripheral edge of the second plate surface 412 has a chamfered portion. The chamfered portion of the second plate surface 412 may be a round chamfered portion or a 45 degree chamfered portion. One or both of the peripheral edge of the first plate surface 411 and the peripheral edge of the second plate surface 412 may lack a chamfered portion and be square. However, from a standpoint of handling, both the peripheral edge of the first plate surface 411 and the peripheral edge of the second plate surface 412 preferably have chamfered portions.

Unlike the first supporting substrate 400, the second supporting substrate 410 does not have a mark that indicates the crystal orientation at the plate side surface 413 in this embodiment. As a matter of course, the second supporting substrate 410 may have the same mark as the second mark 404 of the first supporting substrate 400 at the plate side surface 413. In this case, the description concerning the second mark 404 of the first supporting substrate 400 applies to a description concerning the mark of the second supporting substrate 410.

A diameter and a thickness of the second supporting substrate 410 are arbitrary. In view of the handling of the wafer source 300, the second supporting substrate 410 preferably has a diameter not less than the diameter of the wafer source 300 and a thickness not less than the thickness of the wafer source 300. An interval between the peripheral edge of the wafer source 300 and the peripheral edge of the second supporting substrate 410 when the central portion of the wafer source 300 and a central portion of the second supporting substrate 410 are overlapped is preferably not less than 0 mm and not more than 10 mm.

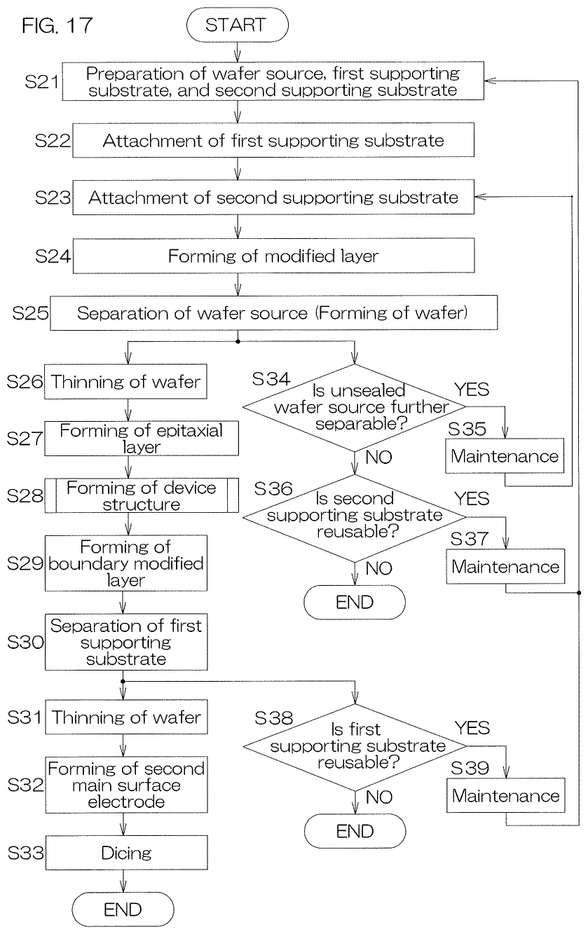

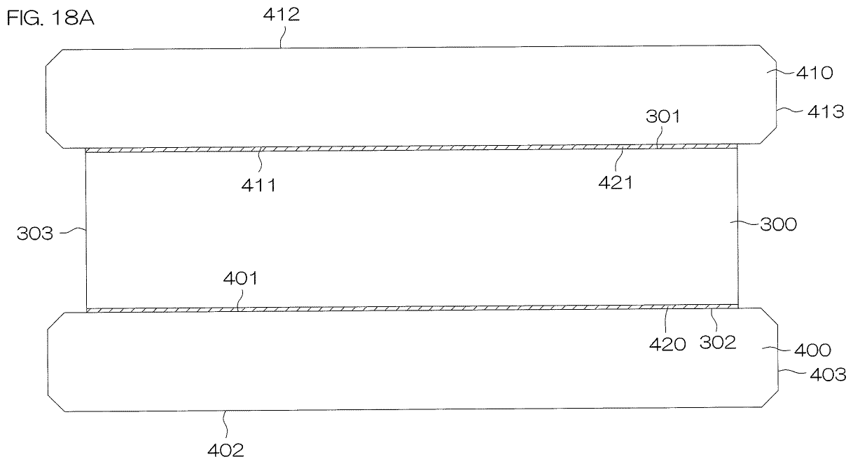

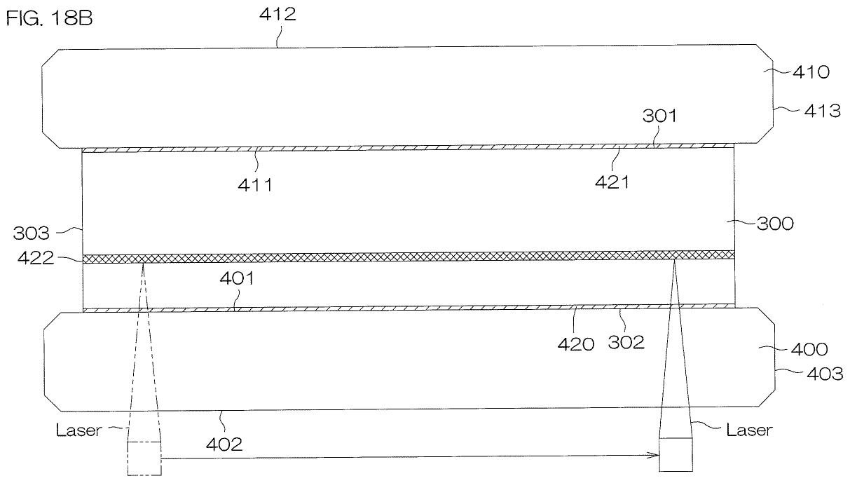

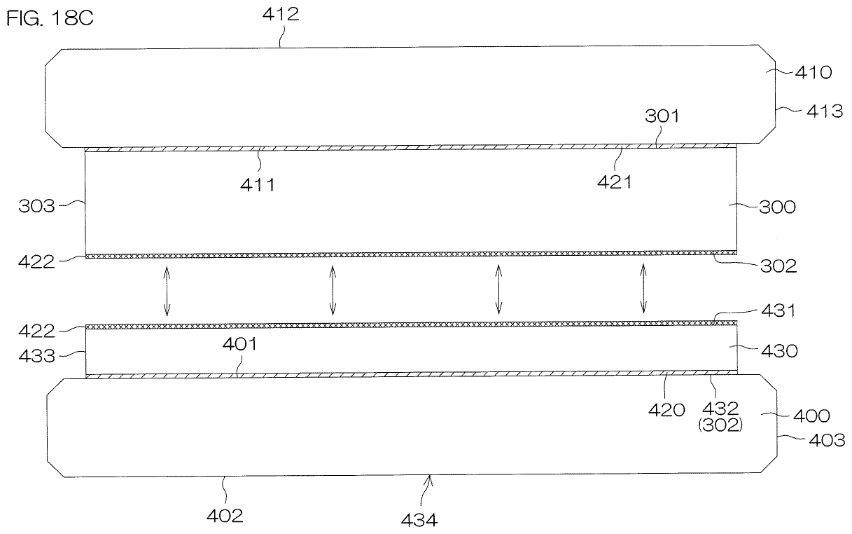

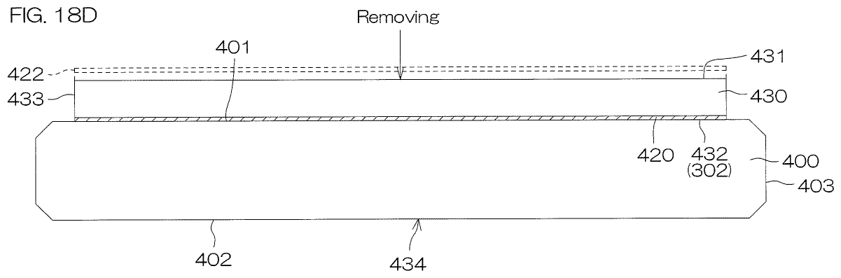

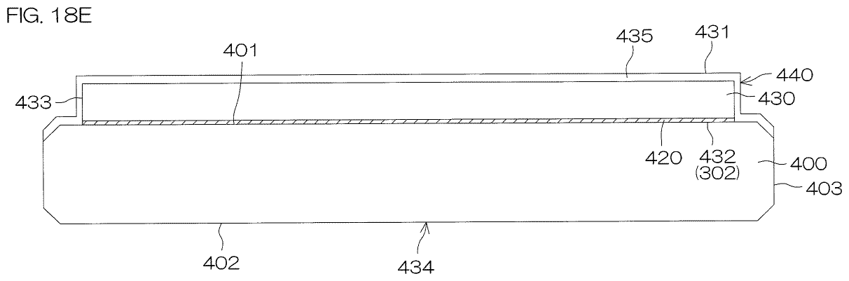

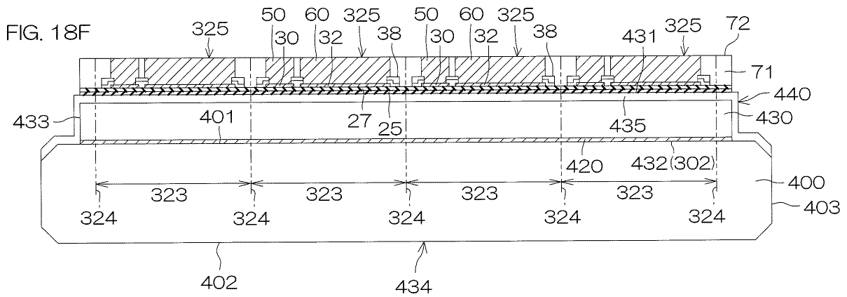

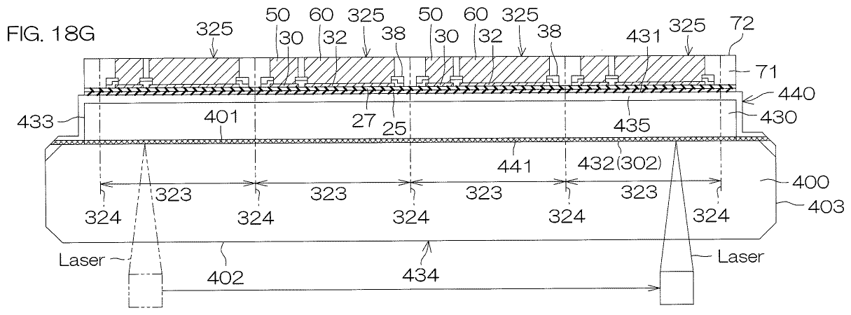

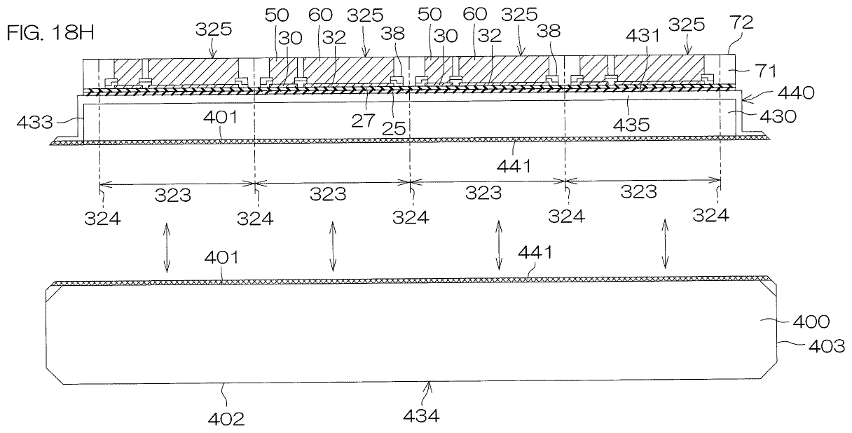

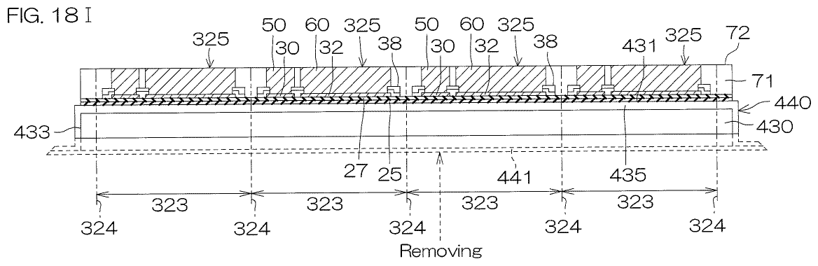

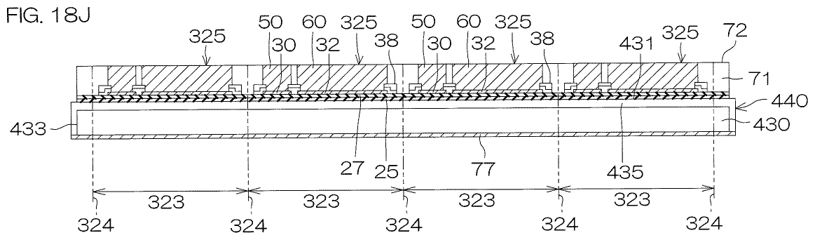

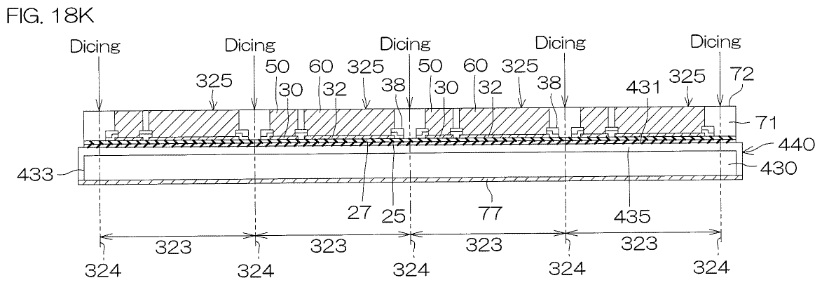

FIG. 17 is a flowchart showing the fourth manufacturing method example for the semiconductor device 1A shown in FIG. 1. FIG. 18A to FIG. 18K are cross sectional views showing the fourth manufacturing method example for the semiconductor device 1A shown in FIG. 17. In FIG. 18A to FIG. 18K, the wafer source 300, the first supporting substrate 400, and the second supporting substrate 410 are shown in simplified manner.

With reference to FIG. 18A, the wafer source 300, the first supporting substrate 400, and the second supporting substrate 410 are prepared (step S21 of FIG. 17). Next, the first supporting substrate 400 is attached to the wafer source 300 (step S22 of FIG. 17) and the second supporting substrate 410 is attached to the wafer source 300 (step S23 of FIG. 17). The order of the attaching step of the first supporting substrate 400 and the attaching step of the second supporting substrate 410 is arbitrary and may be interchanged. In this step, the first plate surface 401 (silicon surface) of the first supporting substrate 400 is attached to the second main surface 302 (carbon surface) of the wafer source 300 and the first plate surface 411 of the second supporting substrate 410 is attached to the first main surface 301 (silicon surface) of the wafer source 300.

The first supporting substrate 400 is attached to the wafer source 300 such that the second mark 404 extends parallel to the first mark 304 at a position adjacent to the first mark 304 (see FIG. 16). In a case in which both the first mark 304 and the second mark 404 include orientation notches, the first supporting substrate 400 is attached to the wafer source 300 such that the notch directions are matched. The crystal orientation of the wafer source 300 is determined by one or both of the first mark 304 and the second mark 404.

The first plate surface 401 (silicon surface) of the first supporting substrate 400 may be directly bonded to the second main surface 302 (carbon surface) of the wafer source 300 by a room temperature bonding method that is an example of a direct bonding method. In the room temperature bonding method, an activating step and a bonding step are performed. In the activating step, for example, atoms or ions are irradiated onto the second main surface 302 of the wafer source 300 and the first plate surface 401 of the first supporting substrate 400 inside a high vacuum and dangling bonds are formed on each of the second main surface 302 and the first plate surface 401.

In the bonding step, the activated second main surface 302 and the activated first plate surface 401 are bonded. A first amorphous bonding layer 420 consisting of a portion of the wafer source 300 and a portion of the first supporting substrate 400 is formed between the second main surface 302 and the first plate surface 401 after bonding. That is, the first supporting substrate 400 is bonded to the wafer source 300 via the first amorphous bonding layer 420. The direct bonding method may include a heat treatment step and a pressurizing step for increasing a bonding strength of the wafer source 300 and the first supporting substrate 400.

The first amorphous bonding layer 420 has a different optical absorption coefficient from the wafer source 300. Specifically, the first amorphous bonding layer 420 has an optical absorption coefficient that is greater than the optical absorption coefficient of the wafer source 300. Further, the optical absorption coefficient of the first amorphous bonding layer 420 is greater than the optical absorption coefficient of the first supporting substrate 400. A thickness of the first amorphous bonding layer 420 may exceed 0 μm and be not more than 5 μm. The thickness of the first amorphous bonding layer 420 is preferably not more than 1 μm.

In this step, the first supporting substrate 400 is bonded to the wafer source 300 by the direct bonding method. However, as long as the wafer source 300 can be supported by the first supporting substrate 400, a bonding method of the first supporting substrate 400 to the wafer source 300 is arbitrary. For example, the first supporting substrate 400 may be bonded to the wafer source 300 by a double-sided tape or an adhesive, etc. In this case, an adhesive layer consisting of the double-sided tape or the adhesive, etc., is formed between the wafer source 300 and the first supporting substrate 400.

The first plate surface 411 of the second supporting substrate 410 may be directly bonded to the first main surface 301 of the wafer source 300 by a room temperature bonding method that is an example of a direct bonding method. In the room temperature bonding method, an activating step and a bonding step are performed. In the activating step, for example, atoms or ions are irradiated onto the first main surface 301 of the wafer source 300 and the first plate surface 411 of the second supporting substrate 410 inside a high vacuum and dangling bonds are formed on each of the first main surface 301 and the first plate surface 411.

In the bonding step, the activated first main surface 301 and the activated first plate surface 411 are bonded. A second amorphous bonding layer 421 consisting of a portion of the wafer source 300 and a portion of the second supporting substrate 410 is formed between the first main surface 301 and the first plate surface 411 after bonding. That is, the second supporting substrate 410 is bonded to the wafer source 300 via the second amorphous bonding layer 421. The direct bonding method may include a heat treatment step and a pressurizing step for increasing a bonding strength of the second supporting substrate 410 with respect to the wafer source 300.

The second amorphous bonding layer 421 has an optical absorption coefficient that is greater than the optical absorption coefficient of the wafer source 300. The optical absorption coefficient of the second amorphous bonding layer 421 is greater than the optical absorption coefficient of the first supporting substrate 400. A thickness of the second amorphous bonding layer 421 may exceed 0 μm and be not more than 5 μm. The thickness of the second amorphous bonding layer 421 is preferably not more than 1 μm.

In this step, the second supporting substrate 410 is bonded to the wafer source 300 by the direct bonding method. However, as long as the wafer source 300 can be supported by the second supporting substrate 410, a bonding method of the second supporting substrate 410 to the wafer source 300 is arbitrary. For example, the second supporting substrate 410 may be bonded to the wafer source 300 by a double-sided tape or an adhesive, etc. In this case, an adhesive layer consisting of the double-sided tape or the adhesive, etc., is formed between the wafer source 300 and the second supporting substrate 410.

Next, with reference to FIG. 18B, a modified layer 422 that is oriented along a horizontal direction parallel to the first main surface 301 is formed at an intermediate portion of a thickness range of the wafer source 300 (step S24 of FIG. 17). In this step, a light converging portion is set at the intermediate portion of the thickness range of the wafer source 300 and a laser light is irradiated from a laser light irradiating apparatus toward the wafer source 300 via the first supporting substrate 400. An irradiation position of the laser light with respect to the wafer source 300 is moved along the horizontal direction. The laser light is preferably irradiated in pulses into the interior of the wafer source 300. The modified layer 422 in which a portion of the crystal structure of the wafer source 300 (SiC monocrystal) is modified to be of a different property is thereby formed.

That is, the modified layer 422 is a laser processing mark formed by the irradiation of the laser light. The modified layer 422 consists of a layer with which density, refractive index, mechanical strength (crystal strength), or other physical characteristic has been modified to differ in property from the wafer source 300 and having a more fragile physical property than the wafer source 300. The modified layer 422 may include at least one layer among an amorphous layer, a melted and rehardened layer, a defect layer, a dielectric breakdown layer, or a refractive index changed layer.

The amorphous layer is a layer in which a portion of the wafer source 300 has been made amorphous. The melted and rehardened layer is a layer in which a portion of the wafer source 300 has been melted and thereafter rehardened. The defect layer is a layer that includes holes, cracks, etc., formed in the wafer source 300. The dielectric breakdown layer is a layer in which a portion of the wafer source 300 has undergone dielectric breakdown. The refractive index changed layer is a layer in which a portion of the wafer source 300 has changed to be of a different refractive index.

In a case in which the second supporting substrate 410 is formed of a material that suppresses attenuation of the laser light, the laser light may be irradiated into the wafer source 300 via the second supporting substrate 410. An irradiation direction of the laser light may be adjusted in accordance with a thickness position of the light converging portion set inside the wafer source 300. For example, in a case in which a distance between the first supporting substrate 400 and the light converging portion is less than a distance between the second supporting substrate 410 and the light converging portion, the laser light may be irradiated into the wafer source 300 via the first supporting substrate 400. Oppositely, in a case in which the distance between the second supporting substrate 410 and the light converging portion is less than the distance between the first supporting substrate 400 and the light converging portion, the laser light may be irradiated into the wafer source 300 via the second supporting substrate 410.

A formation location of the modified layer 422 is set in accordance with a thickness of a wafer to be acquired from the wafer source 300. A distance between the second main surface 302 and the modified layer 422 is preferably set to a value less than a distance between the first main surface 301 and the modified layer 422. As a matter of course, the distance between the second main surface 302 and the modified layer 422 may be set to a value exceeding the distance between the first main surface 301 and the modified layer 422.

The distance between the second main surface 302 and the modified layer 422 is preferably set to a value less than the thickness of the first supporting substrate 400. In this case, a wafer having a thickness less than the thickness of the first supporting substrate 400 is acquired from the wafer source 300. The distance between the second main surface 302 and the modified layer 422 is preferably set to a value less than the thickness of the sealing insulator 71 that is formed in a later step. In this case, a wafer having a thickness less than the thickness of the sealing insulator 71 is acquired from the wafer source 300.

As a matter of course, the distance between the second main surface 302 and the modified layer 422 may be set to a value exceeding the thickness of the sealing insulator 71. In this case, a wafer having a thickness exceeding the thickness of the sealing insulator 71 is acquired from the wafer source 300. The distance between the second main surface 302 and the modified layer 422 may be not less than 10 μm and not more than 300 μm. The distance between the second main surface 302 and the modified layer 422 may be not more than 100 μm. The distance between the second main surface 302 and the modified layer 422 may be not more than 50 μm. The distance between the second main surface 302 and the modified layer 422 may be not more than 40 μm.

Next, with reference to FIG. 18C, the wafer source 300 is cut along the horizontal direction from the intermediate portion of the thickness range with the modified layer 422 as a starting point (step S25 of FIG. 17). In this step, an external force is applied to the wafer source 300 in a state of being supported (sandwiched) by the first supporting substrate 400 and the second supporting substrate 410 and the wafer source 300 is cleaved in the horizontal direction with the modified layer 422 as the starting point. The external force applied to the wafer source 300 may be an ultrasonic wave.

A wafer 430 consisting of a portion of the wafer source 300 is thereby separated from the wafer source 300. The wafer 430 becomes a base of the chip 2 (specifically, the second semiconductor region 7). The wafer 430 has a first wafer main surface 431 consisting of a cut surface, a second wafer main surface 432 consisting of the second main surface 302 of the wafer source 300, and a side surface 433 consisting of a portion of the side surface 303 of the wafer source 300. The first wafer main surface 431 consists of a silicon surface of the SiC monocrystal. The second wafer main surface 432 consists of a carbon surface of the SiC monocrystal. The side surface 433 of the wafer 430 has the first mark 304 inherited from the side surface 303 of the wafer source 300.

The wafer 430 forms a wafer attachment structure 434 together with the first supporting substrate 400 and the first amorphous bonding layer 420 and is separated as the wafer attachment structure 434 from the wafer source 300. The wafer attachment structure 434 is transferred to another location after being separated from the wafer source 300. That is, the wafer 430 is handled integrally with the first supporting substrate 400.

In this step, the wafer 430 is cut out in a state of being supported by the first supporting substrate 400 and therefore, deformation (for example, warping that accompanies thinning) of the wafer 430 is suppressed by the first supporting substrate 400. The wafer 430 that is comparatively thin can thereby be cut out appropriately. It is therefore preferable for the distance between the second main surface 302 and the modified layer 422 to be set to a value less than the thickness of the first supporting substrate 400 (preferably, the sealing insulator 71) and the wafer 430 having a thickness less than the thickness of the first supporting substrate 400 (preferably, the sealing insulator 71) to be cut out.

With reference to FIG. 18D, at the wafer attachment structure 434 side, a thinning step of the wafer 430 from the first wafer main surface 431 side is performed (step S26 of FIG. 17). The thinning step of the wafer 430 may include at least one among a grinding step performed on the first wafer main surface 431 and an etching step performed on the first wafer main surface 431. The grinding step may include at least one among a mechanical polishing method and a chemical mechanical polishing method. The etching step may include at least one among a dry etching step and a wet etching step. This step includes a step of removing a remaining portion of the modified layer 422 adhered to the first wafer main surface 431.

Next, with reference to FIG. 18E, an epitaxial layer 435 is grown from the first wafer main surface 431 by an epitaxial growth method (step S27 of FIG. 17). The epitaxial layer 435 becomes a base of the chip 2 (specifically, the first semiconductor region 6). The epitaxial layer 435 preferably has a thickness exceeding the thickness of the wafer 430. The thickness of the epitaxial layer 435 is preferably not less than 3 μm and not more than 30 μm. The thickness of the epitaxial layer 435 is particularly preferably not less than 5 μm and not more than 25 μm. As a matter of course, the thickness of the epitaxial layer 435 may be less than the thickness of the wafer source 300.

The epitaxial layer 435 is also formed on the side surface 433 of the wafer 430 and the first plate surface 401 of the first supporting substrate 400 in this embodiment. The epitaxial layer 435 may cover the first amorphous bonding layer 420 at a lower end side of the side surface 433 of the wafer 430. Through this step, an epi-wafer 440 (wafer structure) is formed on the first supporting substrate 400. The epi-wafer 440 has a laminated structure that includes the wafer 430 and the epitaxial layer 435 and has the first wafer main surface 431 formed by the epitaxial layer 435.

Next, with reference to FIG. 18F, as in the first manufacturing method example, the plurality of device regions 323 and the plurality of scheduled cutting lines 324 are set on the first wafer main surface 431 of the epi-wafer 440 and the device structures 325 are formed (step S28 of FIG. 17). In the forming step of the device structures 325, the mesa portion 11, the MISFET structure 12, the main surface insulating film 25, the side wall structure 26, the interlayer insulating film 27, the gate electrode 30, the source electrode 32, the plurality of gate wirings 36A and 36B, the source wiring 37, the upper insulating film 38, the gate terminal electrode 50, the source terminal electrode 60, and the sealing insulator 71 are formed in each of the plurality of device regions 323.

The descriptions of the specific features of the respective structures formed in the forming step of the device structures 325 are as have been provided above. Also, the device structures 325 are formed on the first wafer main surface 431 through the forming step of the device structure 325 according to the first manufacturing method example (steps S4A to S4M of FIG. 11). A specific description of the forming step of the device structure 325 according to the fourth manufacturing method example is obtained by replacing the “first main surface 301” in the forming step of the device structure 325 according to the first manufacturing method example by the “first wafer main surface 431.”

In the forming step of the sealing insulator 71 (step S4L of FIG. 11) according to the fourth manufacturing method example, the sealing insulator 71 that is thicker than the epi-wafer 440 is preferably formed. As a matter of course, the sealing insulator 71 that is thinner than the epi-wafer 440 may be formed in the forming step of the sealing insulator 71. In this case, the sealing insulator 71 that is at least thicker than the epitaxial layer 435 is preferably formed. Besides the above, specific descriptions concerning the forming step of the device structure 325 according to the fourth manufacturing method example shall be omitted.

Next, with reference to FIG. 18G, a boundary modified layer 441 that extends along a horizontal direction parallel to the first wafer main surface 431 is formed at a boundary portion of the wafer 430 and the first supporting substrate 400 or in a vicinity of the boundary portion (step S29 of FIG. 17). Specifically, in this step, the boundary modified layer 441 that extends along the first amorphous bonding layer 420 is formed in an interior or a vicinity of the first amorphous bonding layer 420. The vicinity of the first amorphous bonding layer 420 refers to a thickness range of within ±50 μm from a position of the first amorphous bonding layer 420. The vicinity of the first amorphous bonding layer 420 is preferably set in a thickness range of within ±10 μm from the position of the first amorphous bonding layer 420.

In this step, a light converging portion is set in the interior or the vicinity of the first amorphous bonding layer 420 and a laser light is irradiated from a laser light irradiating apparatus toward the first amorphous bonding layer 420 via the first supporting substrate 400. An irradiation position of the laser light with respect to the first amorphous bonding layer 420 is moved along the horizontal direction. The optical absorption coefficient of the first amorphous bonding layer 420 differs from an optical absorption coefficient of the wafer 430 (wafer source 300). Therefore, in this step, an output of the laser light and the light converging portion are adjusted such that the laser light is absorbed by the first amorphous bonding layer 420.

Specifically, the optical absorption coefficient of the first amorphous bonding layer 420 is greater than the optical absorption coefficient of the wafer 430 (wafer source 300) and the optical absorption coefficient of the first supporting substrate 400. Therefore, even if the output of the laser light is increased in the interior or the vicinity of the first amorphous bonding layer 420, a forming position of the boundary modified layer 441 stays within substantially fixed thickness range. That is, fluctuation of the forming position of the boundary modified layer 441 with respect to the output of the laser light is suppressed.

Through such a step, the boundary modified layer 441 in which at least a portion of the first amorphous bonding layer 420 is modified to be of a different property is formed. That is, the boundary modified layer 441 is a laser processing mark formed by the irradiation of the laser light. The boundary modified layer 441 consists of a layer with which density, refractive index, mechanical strength (crystal strength), or other physical characteristic has been modified to differ in property from the first amorphous bonding layer 420 and having a more fragile physical property than the first amorphous bonding layer 420.

The boundary modified layer 441 may include at least one layer among a melted and rehardened layer, a defect layer, a dielectric breakdown layer, or a refractive index changed layer. The melted and rehardened layer is a layer in which a portion of the first amorphous bonding layer 420 has been melted and thereafter rehardened. The defect layer is a layer that includes holes, cracks, etc., formed in the first amorphous bonding layer 420. The dielectric breakdown layer is a layer in which a portion of the first amorphous bonding layer 420 has undergone dielectric breakdown. The refractive index changed layer is a layer in which a portion of the first amorphous bonding layer 420 has changed to be of a different refractive index.

In this step, the boundary modified layer 441 is also formed in a portion of the epitaxial layer 435 formed on the first supporting substrate 400. The portion of the boundary modified layer 441 formed in the epitaxial layer 435 consists of a layer with which density, refractive index, mechanical strength (crystal strength), or other physical characteristic has been modified to differ in property from the epitaxial layer 435 (SiC monocrystal) and having a more fragile physical property than the epitaxial layer 435.

Next, with reference to FIG. 18H, the wafer attachment structure 434 is cut along the horizontal direction with the boundary modified layer 441 (first amorphous bonding layer 420) as a starting point and the first supporting substrate 400 is separated from the epi-wafer 440 (step S30 of FIG. 17). In this step, an external force is applied to the boundary modified layer 441 in a state of being supported (sandwiched) by the sealing insulator 71 and the first supporting substrate 400 and the wafer attachment structure 434 is cleaved in the horizontal direction with the boundary modified layer 441 as the starting point.

The external force applied to the boundary modified layer 441 may be an ultrasonic wave. In this step, the epi-wafer 440 in a state of being supported by the sealing insulator 71 is cut out from the wafer attachment structure 434 and therefore, deformation (for example, warping that accompanies thinning) of the epi-wafer 440 is suppressed by the sealing insulator 71. The epi-wafer 440 that is comparatively thin can thereby be cut out appropriately.

Next, with reference to FIG. 181, in the state of being supported by the sealing insulator 71, a thinning step of the epi-wafer 440 from the second wafer main surface 432 side is performed (step S31 of FIG. 17). The thinning step of the epi-wafer 440 may include at least one among a grinding step performed on the second wafer main surface 432 and an etching step performed on the second wafer main surface 432. The grinding step may include at least one among a mechanical polishing method and a chemical mechanical polishing method. The etching step may include at least one among a dry etching step and a wet etching step. This step includes a step of removing a remaining portion of the boundary modified layer 441 adhered to the second wafer main surface 432.

The epi-wafer 440 is thinned until the epi-wafer 440 is of a desired thickness. In a case in which the epi-wafer 440 that is thinner than the sealing insulator 71 is cut out, the thinning step of the epi-wafer 440 includes a step of thinning the epi-wafer 440 further. On the other hand, in a case in which the epi-wafer 440 that is thicker than the sealing insulator 71 is cut out, the thinning step of the epi-wafer 440 preferably includes a step of thinning the epi-wafer 440 until the epi-wafer 440 becomes less in thickness than the sealing insulator 71. In a case in which the wafer 430 is thinner than the epitaxial layer 435 in these steps, the wafer 430 is thinned further. On the other hand, in a case in which the wafer 430 is thicker than the epitaxial layer 435, the wafer 430 is preferably thinned until the epi-wafer 440 becomes less in thickness than the epitaxial layer 435.

Next, with reference to FIG. 18J, the drain electrode 77 (second main surface electrode) covering the second wafer main surface 432 of the epi-wafer 440 is formed (step S32 of FIG. 17). The drain electrode 77 may be formed by a sputtering method and/or a vapor deposition method.

Thereafter, with reference to FIG. 18K, the epi-wafer 440 and the sealing insulator 71 are cut along the scheduled cutting lines 324 (step S33 of FIG. 17). The epi-wafer 440 and the sealing insulator 71 may be cut by a dicing blade (not shown). A plurality of the semiconductor devices 1A are manufactured from the epi-wafer 440 through steps including the above.

On the other hand, with respect to the wafer source 300 supported by the second supporting substrate 410 after the separating step of the wafer source 300 (step S25 of FIG. 17) (see FIG. 18C), it is determined whether or not the wafer source 300 is further separable (step S34 of FIG. 17). In a case in which the wafer source 300 has a thickness and a state of levels enabling acquisition of a wafer 430 different from the wafer 430 at the wafer attachment structure 434 side, it may be determined that the wafer source 300 is further separable.

In a case in which the wafer source 300 is further separable (step S34 of FIG. 17: YES), a maintenance step of the wafer source 300 is performed (step S35 of FIG. 17). The maintenance step of the wafer source 300 may include at least one among a grinding step performed on the second main surface 302 and an etching step performed on the second main surface 302. The grinding step may include at least one among a mechanical polishing method and a chemical mechanical polishing method. The etching step may include at least one among a dry etching step and a wet etching step. This step includes a step of removing a remaining portion of the modified layer 422 adhered to the second main surface 302 of the wafer source 300.

Through this step, the second main surface 302 of the wafer source 300 is smoothened. Thereafter, steps S23 to S25 of FIG. 17 are executed repeatedly until the wafer source 300 becomes inseparable. That is, in the fourth manufacturing method example, a reusing step of the wafer source 300 is performed. The wafer source 300 that becomes the last one in the repeated steps may be separated as the wafer 430 from the second supporting substrate 410. In this case, the boundary modified layer 441 may be formed in an interior or a vicinity of the second amorphous bonding layer 421 and the last wafer source 300 may be separated from the second supporting substrate 410 by cleaving of the boundary modified layer 441.

On the other hand, in a case in which the wafer source 300 is inseparable (step S34 of FIG. 17: NO), the manufacturing process using a single wafer source 300 ends and it is determined whether or not the second supporting substrate 410 is reusable (step S36 of FIG. 17). In a case in which the second supporting substrate 410 has a thickness and a state of levels enabling supporting of another wafer source 300, it may be determined that the second supporting substrate 410 is reusable. In a case in which the second supporting substrate 410 is unreusable (step S36 of FIG. 17: NO), the manufacturing process using the second supporting substrate 410 ends.

On the other hand, in a case in which the second supporting substrate 410 is reusable (step S36 of FIG. 17: YES), a maintenance step of the second supporting substrate 410 is performed (step S37 of FIG. 17). The maintenance step of the second supporting substrate 410 includes a step of repairing the second supporting substrate 410 to a state enabling use as the new second supporting substrate 410. This step includes a step of removing the wafer source 300 and the second amorphous bonding layer 421 from the second supporting substrate 410.

The removing step of the wafer source 300 (second amorphous bonding layer 421) includes at least one among a grinding step performed on the wafer source 300 and an etching step performed on the wafer source 300. The grinding step may include at least one among a mechanical polishing method and a chemical mechanical polishing method. The etching step may include at least one among a dry etching step and a wet etching step. As a matter of course, the removing step of the wafer source 300 may include at least one among a grinding step performed on the first plate surface 411 and an etching step performed on the first plate surface 411.

Also, the boundary modified layer 441 may be formed in the interior or the vicinity of the second amorphous bonding layer 421 and the wafer source 300 and the second supporting substrate 410 may be separated by cleaving of the boundary modified layer 441. In this case, a remaining portion of the boundary modified layer 441 adhered to the second supporting substrate 410 may be removed by at least one among a grinding step and an etching step. Thereby, the first plate surface 411 of the second supporting substrate 410 is smoothened and the second supporting substrate 410 is reused. Thereafter, steps S21 to S25 of FIG. 17 are performed successively.

On the other hand, with respect to the first supporting substrate 400 after the separating step of the first supporting substrate 400 (step S30 of FIG. 17) (see FIG. 18H), it is determined whether or not the first supporting substrate 400 is reusable (step S38 of FIG. 17). In a case in which the first supporting substrate 400 has a thickness and a state of levels enabling supporting of another wafer source 300, it may be determined that the first supporting substrate 400 is reusable. In a case in which the first supporting substrate 400 is unreusable (step S38 of FIG. 17: NO), the manufacturing process using the first supporting substrate 400 ends.

On the other hand, in a case in which the first supporting substrate 400 is reusable (step S38 of FIG. 17: YES), a maintenance step of the first supporting substrate 400 is performed (step S39 of FIG. 17). The maintenance step of the second supporting substrate 410 includes a step of repairing the first supporting substrate 400 to a state enabling use as the new first supporting substrate 400. This step includes a step of removing a remaining portion of the boundary modified layer 441 (remaining portion of the second amorphous bonding layer 421) from the first supporting substrate 400.

The removing step of the boundary modified layer 441 includes at least one among a grinding step performed on the boundary modified layer 441 and an etching step performed on the boundary modified layer 441. The grinding step may include at least one among a mechanical polishing method and a chemical mechanical polishing method. The etching step may include at least one among a dry etching step and a wet etching step. As a matter of course, the removing step of the boundary modified layer 441 may include at least one among a grinding step performed on the first plate surface 401 and an etching step performed on the first plate surface 401. Thereafter, steps S21 to S25 of FIG. 17 are performed successively.

In FIG. 17, the semiconductor devices 1A are manufactured in the manufacturing process of the first time performed on the wafer source 300 and the reusing step of the wafer source 300. However, arbitrary semiconductor devices (for example, the semiconductor devices 1B to 1H according to other embodiments) differing from the semiconductor devices 1A may be manufactured in the manufacturing process of the first time and the semiconductor devices 1A may be manufactured in the reusing step. As a matter of course, the semiconductor devices 1A may be manufactured in the manufacturing process of the first time and arbitrary semiconductor devices differing from the semiconductor devices 1A may be manufactured in the reusing step. Also, the semiconductor devices 1A may be manufactured using at least one wafer 430 formed in the reusing step and arbitrary semiconductor devices differing from the semiconductor devices 1A may be manufactured using the remaining wafers 430.

As described above, the fourth manufacturing method example for the semiconductor device 1A includes the preparing step of the wafer source 300 (step S21 of FIG. 17), the attaching step of the first supporting substrate 400 (step S22 of FIG. 17), the separating step of the wafer source 300 (step S25 of FIG. 17), the forming step of the gate electrode 30 (source electrode 32) (step S4I of FIG. 11), the forming step of the gate terminal electrode 50 (source terminal electrode 60) (step S4K of FIG. 11), the forming step of the sealing insulator 71 (step S4L of FIG. 11), and the removing step of the first supporting substrate 400 (step S30 of FIG. 17).

In the preparing step of the wafer source 300, the wafer source 300 having the first main surface 301 on one side and the second main surface 302 on the other side is prepared. In the attaching step of the first supporting substrate 400, the first supporting substrate 400 is attached to the second main surface 302 of the wafer source 300. In the separating step of the wafer source 300, the wafer source 300 is cut in the horizontal direction along the first main surface 301 from the intermediate portion of the thickness range of the wafer source 300. Thereby, the wafer 430 having the first wafer main surface 431 consisting of the cut surface and the second wafer main surface 432 consisting of the second main surface 302 is separated together with the first supporting substrate 400 from the wafer source 300.

In the forming step of the gate electrode 30 (source electrode 32), the gate electrode 30 (source electrode 32) is formed on the first wafer main surface 431. In the forming step of the gate terminal electrode 50 (source terminal electrode 60), the gate terminal electrode 50 (source terminal electrode 60) is formed on the gate electrode 30 (source electrode 32). In the forming step of the sealing insulator 71, the sealing insulator 71 that covers the periphery of the gate terminal electrode 50 (source terminal electrode 60) on the first wafer main surface 431 such as to expose a portion of the gate terminal electrode 50 (source terminal electrode 60) is formed. In the removing step of the first supporting substrate 400, the first supporting substrate 400 is removed in the state in which the wafer 430 is supported by the sealing insulator 71.

According to this manufacturing method, the wafer 430 that is thinner than the wafer source 300 is separated, in the state of being supported by the first supporting substrate 400, from the wafer source 300. Therefore, deformation of the wafer 430 can be suppressed by the first supporting substrate 400 and, at the same time, the wafer 430 can be handled together with the first supporting substrate 400. Shape defects and fluctuations in electrical characteristics of the wafer 430 due to deformation (for example, warping that accompanies thinning) can thereby be suppressed.

On the other hand, the first supporting substrate 400 is removed in the state in which the wafer 430 is supported by the sealing insulator 71. Therefore, deformation of the wafer 430 can by suppressed by the sealing insulator 71 and, at the same time, the wafer 430 can be handled with the sealing insulator 71 as the supporting member. Shape defects and fluctuations in electrical characteristics of the wafer 430 due to deformation can thereby be suppressed after the removing step of the first supporting substrate 400.

Also, according to this manufacturing method, the sealed wafer 331 can be protected from an external force and humidity by the sealing insulator 71. That is, the wafer 430 can be protected from damage due to the external force and deterioration due to the humidity. Shape defects and fluctuations in electrical characteristics can thereby be suppressed. As a result, it is possible to provide an efficient manufacturing method for the semiconductor device 1A having high reliability.

Also, according to this manufacturing method, it is also possible to leave room for reuse of the wafer source 300. Thereby, consumption of the wafer source 300 can be suppressed and the number of the semiconductor devices 1A that can be acquired from the single wafer source 300 can be increased. A manufacturing cost can thus be reduced. In a case in which the wafer source 300 includes the monocrystal of the wide bandgap semiconductor (particularly, the SiC monocrystal) that is comparatively expensive, the manufacturing cost due to the wide bandgap semiconductor can be reduced. Such a manufacturing method is thus particularly beneficial in a case in which the wafer source 300 includes the monocrystal of the wide bandgap semiconductor. In the preparing step of the wafer source 300, it is preferable to prepare the wafer source 300 cut out from the ingot.

The separating step of the wafer source 300 preferably includes the step of cutting out the wafer 430 that is thinner than the first supporting substrate 400. According to this manufacturing method, the wafer 430 that is comparatively thin can be cut out appropriately because the deformation of the wafer 430 is suppressed by the first supporting substrate 400. By the comparatively thin wafer 430, the semiconductor device 1A that can be improved in electrical characteristics by reduction of the resistance value (for example, the on resistance) and has high reliability can be manufactured. Also, according to this manufacturing method, a remaining amount of the wafer source 300 can be increased. Therefore, in a case where the wafer source 300 is reused, the consumption of the wafer source 300 can be suppressed and a manufacturing efficiency can be improved.

The manufacturing method for the semiconductor device 1A preferably includes the step of repeating the series of steps including the attaching step of the first supporting substrate 400 and the separating step of the wafer source 300 until the wafer source 300 becomes inseparable (step S34 of FIG. 17). According to this manufacturing method, the consumption of the wafer source 300 can be suppressed. In this case, a portion of the plurality of wafers 430 acquired from the wafer source 300 may be used for manufacturing another semiconductor device different from the semiconductor device 1A.

Also, a portion of the plurality of wafers 430 may be used as other members (including the supporting substrate 310 mentioned above) such as the first supporting substrate 400, the second supporting substrate 410, etc. The manufacturing method for the semiconductor device 1A preferably includes the step, after the separating step of the wafer source 300, of smoothening the second main surface 302 (cut surface) of the wafer source 300 (step S35 of FIG. 17).

The separating step of the wafer source 300 preferably includes the step of forming, by the laser light irradiating method, the modified layer 422 that extends along the horizontal direction at the intermediate portion of the thickness range of the wafer source 300 and thereafter cleaving the wafer source 300 in the horizontal direction with the modified layer 422 as the starting point. According to this manufacturing method, the wafer source 300 does not have to be separated by cutting. Therefore, the wafer source 300 can be separated efficiently while suppressing the consumption of the wafer source 300.

Such a manufacturing method is particularly beneficial in a case in which the wafer source 300 includes the monocrystal of the wide bandgap semiconductor (particularly, the SiC monocrystal) that has a higher hardness than Si. By the forming step of the modified layer 422, the wide bandgap semiconductor having the comparatively high hardness can be cleaved easily. A manufacturing efficiency pertaining to the wide bandgap semiconductor can thus be improved. The forming step of the modified layer 422 preferably includes the step of irradiating the laser light into the wafer source 300 from the second main surface 302 side of the wafer source 300 via the first supporting substrate 400.

The removing step of the first supporting substrate 400 preferably includes the step of separating the first supporting substrate 400 from the wafer 430. According to this manufacturing method, the first supporting substrate 400 does not have to be removed by grinding. The manufacturing efficiency can thus be improved. In this case, the attaching step of the first supporting substrate 400 preferably includes the step of attaching the first supporting substrate 400 to the second main surface 302 by the direct bonding method.

Further in this case, the removing step of the first supporting substrate 400 preferably includes the step of forming, by the laser light irradiating method, the boundary modified layer 441 that extends along the horizontal direction at the boundary portion of the wafer 430 and the first supporting substrate 400 or in the vicinity of the boundary portion and thereafter cleaving the boundary modified layer 441 in the horizontal direction. According to this manufacturing method, the first supporting substrate 400 can be separated easily from the wafer 430. The manufacturing efficiency can thus be improved.

In this case, the attaching step of the first supporting substrate 400 preferably includes the step of forming the first amorphous bonding layer 420 between the wafer source 300 and the first supporting substrate 400 by the direct bonding method. Further in this case, the removing step of the first supporting substrate 400 preferably includes the step of forming the boundary modified layer 441 that extends along the first amorphous bonding layer 420 in the interior or the vicinity of the first amorphous bonding layer 420.

The first amorphous bonding layer 420 has the different optical absorption coefficient from the wafer source 300. Therefore, by making the laser light be absorbed at the first amorphous bonding layer 420 side, the boundary modified layer 441 can be formed appropriately. In this case, it is preferable to form the first amorphous bonding layer 420 having the optical absorption coefficient that is higher than the optical absorption coefficient of the wafer source 300. The first supporting substrate 400 preferably consists of the same material as the wafer source 300.

The manufacturing method for the semiconductor device 1A preferably includes the step, after the removing step of the first supporting substrate 400, of thinning the wafer 430 from the second wafer main surface 432 side in the state of being supported by the sealing insulator 71. By this step, the wafer 430 can be thinned appropriately because the deformation of the wafer 430 is suppressed by the sealing insulator 71. Also, by the comparatively thin wafer 430, the semiconductor device 1A that can be improved in electrical characteristics by reduction of the resistance value (for example, the on resistance) and has high reliability can be manufactured.

The forming step of the sealing insulator 71 preferably includes the step of forming the sealing insulator 71 that is thicker than the wafer 430. The forming step of the sealing insulator 71 may include the step of forming the sealing insulator 71 that is thinner than the wafer 430. In this case, the step of thinning the wafer 430 preferably includes the step of thinning the wafer 430 until the wafer 430 becomes thinner than the sealing insulator 71.

The manufacturing method for the semiconductor device 1A preferably includes the step, after the removing step of the first supporting substrate 400, of forming the drain electrode 77 (second main surface electrode) that covers the second wafer main surface 432 of the wafer 430 (step S32 of FIG. 17). The manufacturing method for the semiconductor device 1A preferably includes the step, after the removing step of the first supporting substrate 400, of cutting the wafer 430 together with the sealing insulator 71 (step S33 of FIG. 17).

The manufacturing method for the semiconductor device 1A preferably includes the step, before the forming step of the gate electrode 30 (source electrode 32), of thinning the wafer 430 from the first wafer main surface 431 side in the state of being supported by the sealing insulator 71 (step S26 of FIG. 17). According to this manufacturing method, shape defects of the first wafer main surface 431 and fluctuations in electrical characteristics due to the first wafer main surface 431 can be suppressed. The thinning step of the wafer 430 preferably includes the step of grinding the first wafer main surface 431.

The manufacturing method for the semiconductor device 1A preferably includes the step, before the forming step of the gate electrode 30 (source electrode 32), of forming the epi-wafer 440 (wafer structure) (step S27 of FIG. 17). In the forming step of the epi-wafer 440, the epitaxial layer 435 is grown from the first wafer main surface 431. The epi-wafer 440 that includes the wafer 430 and the epitaxial layer 435 and has the first wafer main surface 431 formed by the epitaxial layer 435 is thereby formed.

In this case, the manufacturing method for the semiconductor device 1A preferably includes the step, after the removing step of the first supporting substrate 400, of removing at least a portion of the wafer 430 from the epi-wafer 440 in the state of being supported by the sealing insulator 71. According to this manufacturing method, the deformation of the epi-wafer 440 is suppressed by the sealing insulator 71 and therefore, the epi-wafer 440 can be thinned appropriately. Also, according to this manufacturing method, the resistance value (for example, the on resistance) due to the wafer 430 in the epi-wafer 440 can be reduced. The semiconductor device 1A that can be improved in electrical characteristics and has high reliability can thus be manufactured.

The growing step of the epitaxial layer 435 may include the step of forming the epitaxial layer 435 that is thicker than the wafer 430. In this case, the thinning step of the wafer 430 may include the step of further thinning the wafer 430 that is thinner than the epitaxial layer 435. The growing step of the epitaxial layer 435 may include the step of forming the epitaxial layer 435 that is thinner than the wafer 430. In this case, the thinning step of the wafer 430 may include the step of thinning the wafer 430 that is thicker than the epitaxial layer 435 until the wafer 430 becomes thinner than the epitaxial layer 435.

The forming step of the sealing insulator 71 preferably includes the step of forming the sealing insulator 71 that covers the whole region of the gate terminal electrode 50 (source terminal electrode 60) and the step of removing the sealing insulator 71 until a portion of the gate terminal electrode 50 (source terminal electrode 60) becomes exposed. The forming step of the sealing insulator 71 preferably includes the step of supplying the sealant 350 that includes the thermosetting resin onto the first main surface 431 and thermosetting the sealant 350.

The manufacturing method for the semiconductor device 1A preferably includes the step, before the forming step of the gate terminal electrode 50 (source terminal electrode 60), of forming the upper insulating film 38 that partially covers the gate electrode 30 (source electrode 32) (step S4J of FIG. 11). In this case, the forming step of the sealing insulator 71 preferably includes the step of forming the sealing insulator 71 that covers the gate terminal electrode 50 (source terminal electrode 60) and the upper insulating film 38.

The forming step of the gate terminal electrode 50 (source terminal electrode 60) preferably includes the step of forming the gate terminal electrode 50 (source terminal electrode 60) having the portion that directly covers the upper insulating film 38. The forming step of the upper insulating film 38 preferably includes the step of forming the upper insulating film 38 that includes at least one among the inorganic insulating film 42 and the organic insulating film 43.

The forming step of the gate terminal electrode 50 (source terminal electrode 60) preferably includes the step of forming the second base conductor film 346 (conductor film) that covers the gate electrode 30 (source electrode 32), the step of forming, on the second base conductor film 346, the tenth mask M10 that exposes the portion of the second base conductor film 346 covering the gate electrode 30 (source electrode 32), the step of depositing the third base conductor film 349 (conductor film) on the portion of the second base conductor film 346 exposed from the tenth mask M10, and the step of removing the tenth mask M10 after the depositing step of the third base conductor film 349.

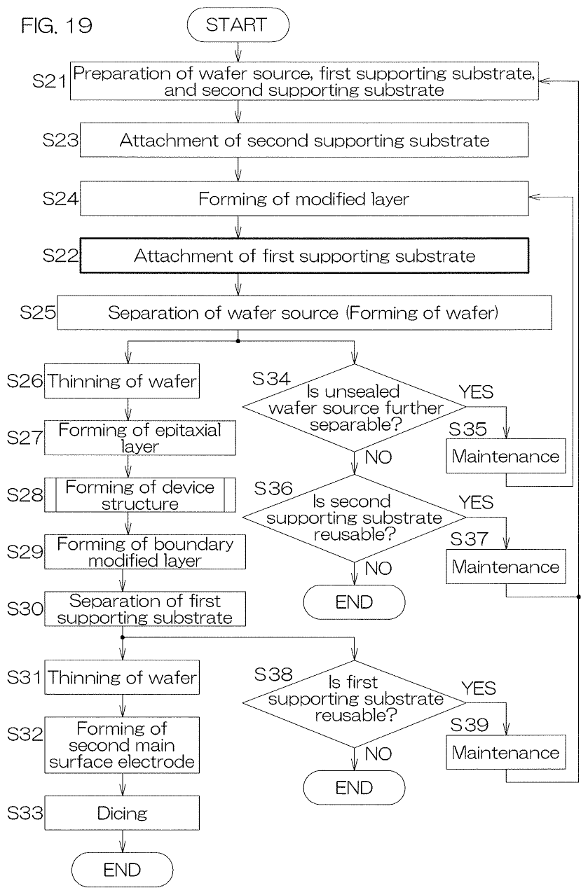

FIG. 19 is a flowchart showing the fifth manufacturing method example for the semiconductor device 1A shown in FIG. 1. With reference to FIG. 19, the fifth manufacturing method example is a manufacturing method with which the fourth manufacturing method example (see FIG. 17) is modified. Specifically, with the fifth manufacturing method example, the attaching step of the first supporting substrate 400 (step S22) is performed after the forming step of the modified layer 422 (step S24). In the forming step of the modified layer 422, the laser light is irradiated into the wafer source 300 from the second main surface 302 side in a state in which the first supporting substrate 400 is not present and the modified layer 422 is formed.

As described above, the same effects as the effects of the fourth manufacturing method example are also achieved by the fifth manufacturing method example. Also, according to the fifth manufacturing method example, the modified layer 422 can be formed appropriately inside the wafer source 300. In the fifth manufacturing method example, the attaching step of the second supporting substrate 410 (step S23 of FIG. 17) is performed before the forming step of the modified layer 422. However, the attaching step of the second supporting substrate 410 may be performed after the forming step of the modified layer 422. In this case, the attaching step of the second supporting substrate 410 may be performed before the attaching step of the first supporting substrate 400 or may be performed after the attaching step of the first supporting substrate 400.

In this case, the laser light may be irradiated into the wafer source 300 from the first main surface 301 side or from the second main surface 302 side in the forming step of the modified layer 422. As a matter of course, in the fifth manufacturing method example, the attaching step of the first supporting substrate 400 and the attaching step of the second supporting substrate 410 may be interchanged. In this case, the laser light may be irradiated into the wafer source 300 from the first main surface 301 side in the forming step of the modified layer 422. During the reusing step, the attaching step of the second supporting substrate 410 may be omitted.

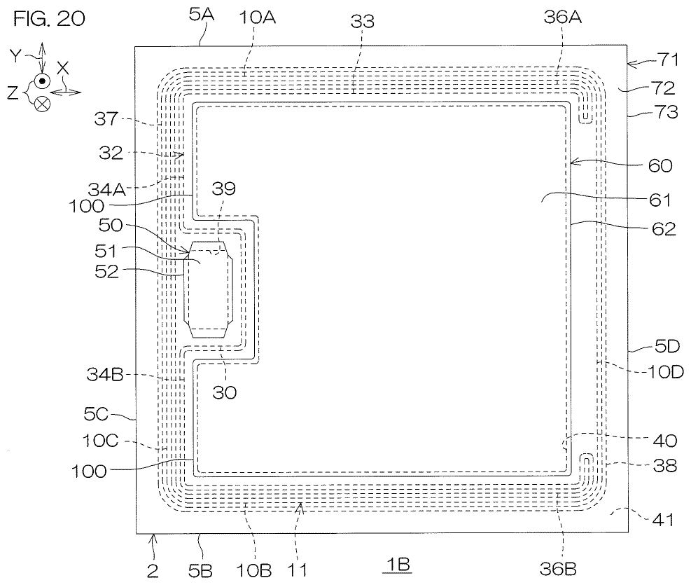

FIG. 20 is a plan view showing a semiconductor device 1B according to a second embodiment. With reference to FIG. 20, the semiconductor device 1B has a modified mode of the semiconductor device 1A. Specifically, the semiconductor device 1B includes the source terminal electrode 60 that has at least one (in this embodiment, a plurality of) drawer terminal portions 100. Specifically, the plurality of drawer terminal portions 100 are each drawn out onto the plurality of drawer electrode portions 34A, 34B of the source electrode 32 such as to oppose the gate terminal electrode 50 in the second direction Y. That is, the plurality of drawer terminal portions 100 sandwich the gate terminal electrode 50 from both sides of the second direction Y in plan view.

As described above, the same effects as those of the semiconductor device 1A are also achieved with the semiconductor device 1B. In the manufacturing method for the semiconductor device 1B, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1B.

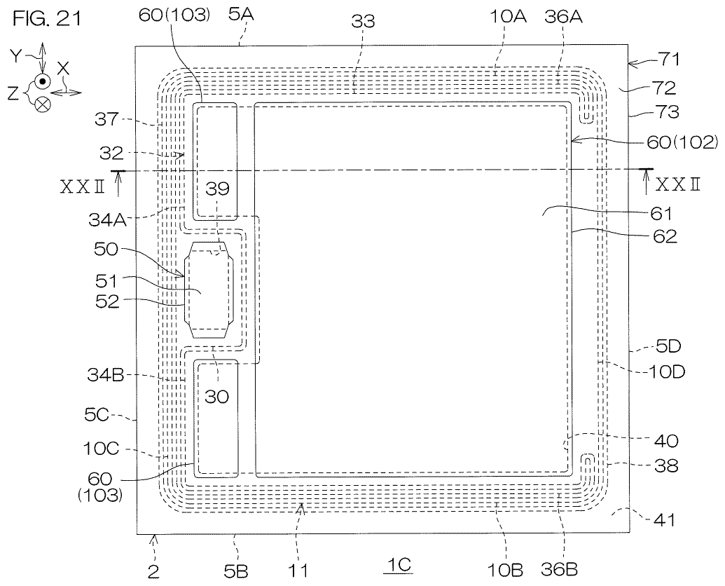

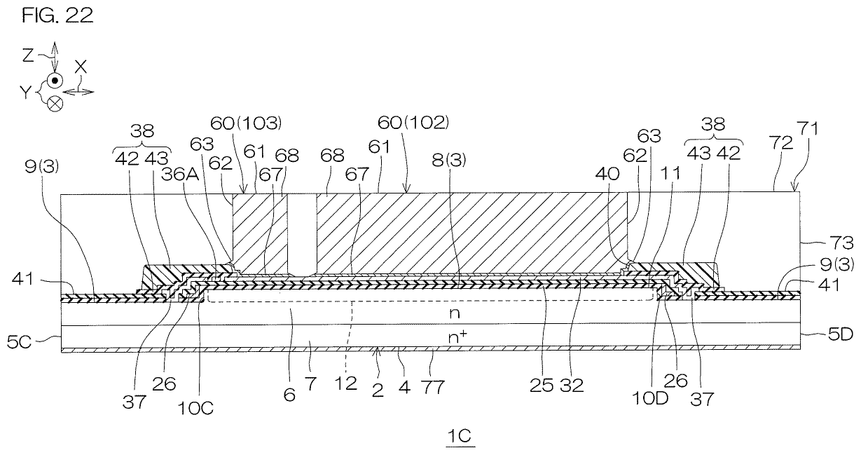

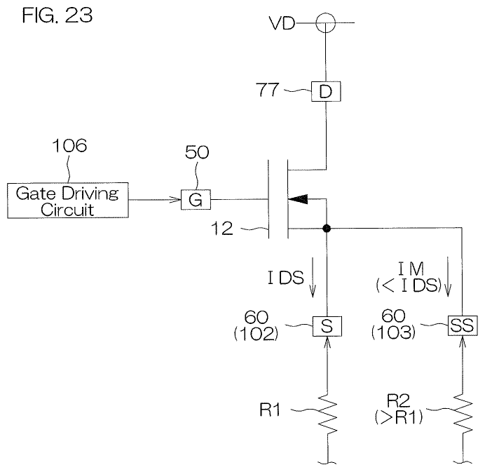

FIG. 21 is a plan view showing a semiconductor device 1C according to a third embodiment. FIG. 22 is a cross sectional view taken along XXII-XXII line shown in FIG. 21. FIG. 23 is a circuit diagram showing an electrical configuration of the semiconductor device 1C shown in FIG. 21. With reference to FIG. 21 to FIG. 23, the semiconductor device 1C has a modified mode of the semiconductor device 1A.

Specifically, the semiconductor device 1C includes the plurality of source terminal electrodes 60 that are arranged on the source electrode 32 at intervals from each other. The semiconductor device 1C includes at least one (in this embodiment, one) source terminal electrode 60 that is arranged on the body electrode portion 33 of the source electrode 32 and at least one (in this embodiment, a plurality of) source terminal electrodes 60 that are arranged on the plurality of drawer electrode portions 34A, 34B of the source electrode 32, in this embodiment.

The source terminal electrode 60 on the body electrode portion 33 side is formed as a main terminal electrode 102 that conducts a drain source current IDS, in this embodiment. The plurality of source terminal electrodes 60 on the plurality of drawer electrode portions 34A, 34B sides are each formed as a sense terminal electrode 103 that conducts a monitor current IM which monitors the drain source current IDS, in this embodiment. Each of the sense terminal electrodes 103 has an area less than an area of the main terminal electrode 102 in plan view.

One sense terminal electrode 103 is arranged on the first drawer electrode portion 34A and faces the gate terminal electrode 50 in the second direction Y in plan view. The other sense terminal electrode 103 is arranged on the second drawer electrode portion 34B and faces the gate terminal electrode 50 in the second direction Y in plan view. The plurality of sense terminal electrodes 103 therefore sandwich the gate terminal electrode 50 from both sides of the second direction Y in plan view.

With reference to FIG. 23, in the semiconductor device 1C, a gate driving circuit 106 is to be electrically connected to the gate terminal electrode 50, at least one first resistance R1 is to be electrically connected to the main terminal electrode 102, and at least one second resistance R2 is to be electrically connected to the plurality of sense terminal electrodes 103. The first resistance R1 is configured such as to conduct the drain source current IDS that is generated in the semiconductor device 1C. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to the main terminal electrode 102.

Also, at least one second bonding wire with the second resistance value more than the first resistance value may be connected to at least one of the sense terminal electrodes 103. The second bonding wire may have a line thickness less than a line thickness of the first bonding wire. In this case, a bonding area of the second bonding wire with respect to the sense terminal electrode 103 may be less than a bonding area of the first bonding wire with respect to the main terminal electrode 102.

As described above, the same effects as those of the semiconductor device 1A are also achieved with the semiconductor device 1C. In the manufacturing method for the semiconductor device 1C, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1C. Therefore, the same effects as those of the manufacturing method for the semiconductor device 1A are also achieved with the manufacturing method for the semiconductor device 1C.

In this embodiment, an example in which the sense terminal electrodes 103 are formed on the drawer electrode portions 34A, 34B, but the arrangement locations of the sense terminal electrodes 103 are arbitrary. Therefore, the sense terminal electrode 103 may be arranged on the body electrode portion 33. In this embodiment, an example in which the sense terminal electrode 103 is applied to the semiconductor device 1A has been shown. As a matter of course, the sense terminal electrode 103 may be applied to the second embodiment.

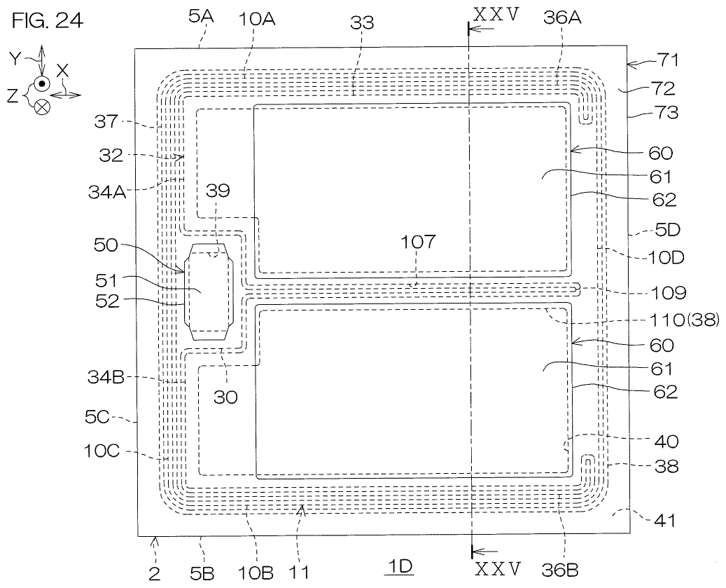

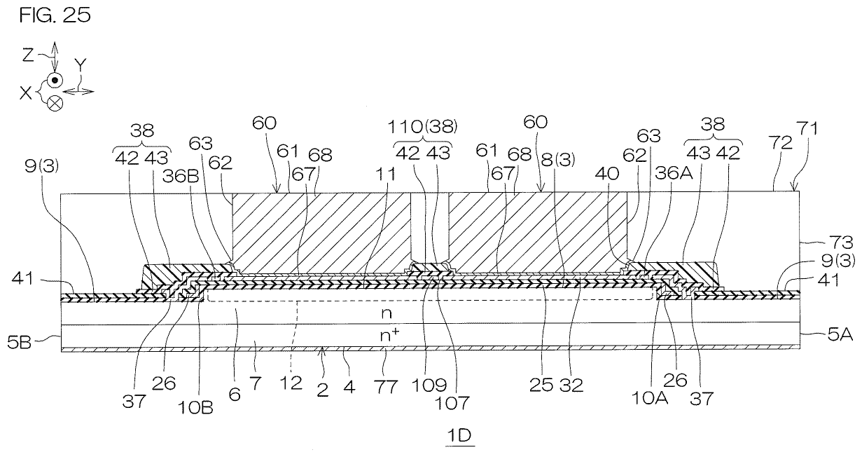

FIG. 24 is a plan view showing a semiconductor device 1D according to a fourth embodiment. FIG. 25 is a cross sectional view taken along XXVIII-XXVIII line shown in FIG. 24. With reference to FIG. 24 and FIG. 25, the semiconductor device 1D has a modified mode of the semiconductor device 1A. Specifically, the semiconductor device 1D includes a gap portion 107 that formed in the source electrode 32.

The gap portion 107 is formed in the body electrode portion 33 of the source electrode 32. The gap portion 107 penetrates the source electrode 32 to expose a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may divide the source electrode 32 into the second direction Y.

The semiconductor device 1D includes a gate intermediate wiring 109 that is drawn out into the gap portion 107 from the gate electrode 30. The gate intermediate wiring 109 has a laminated structure that includes the first gate conductor film 55 and the second gate conductor film 56 as with the gate electrode 30 (the plurality of gate wiring 36A, 36B). The gate intermediate wiring 109 is formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes a gap covering portion 110 that covers the gap portion 107 of the source electrode 32, in this embodiment. The gap covering portion 110 covers a whole region of the gate intermediate wiring 109 inside the gap portion 107. The gap covering portion 110 may be drawn out onto the source electrode 32 from inside the gap portion 107 such as to cover the peripheral edge portion of the source electrode 32.

The semiconductor device 1D includes the plurality of source terminal electrodes 60 that are arranged on the source electrode 32 at an interval from each other, in this embodiment. The plurality of source terminal electrodes 60 are each arranged on the source electrode 32 at an interval from the gap portion 107 and face each other in the second direction Y in plan view. The plurality of source terminal electrodes 60 are arranged such as to expose the gap covering portion 110, in this embodiment.

The plurality of source terminal electrodes 60 are each formed in a quadrangle shape (specifically, rectangular shape extending in the first direction X) in plan view, in this embodiment. The planar shapes of the plurality of source terminal electrodes 60 is arbitrary, and may each be formed in a polygonal shape other than the quadrangle shape, a circular shape, or an elliptical shape in plan view. The plurality of source terminal electrodes 60 may each include the second protrusion portion 63 that is formed on the gap covering portion 110 of the upper insulating film 38.

The sealing insulator 71 aforementioned covers the gap portion 107 at a region between the plurality of source terminal electrodes 60, in this embodiment. The sealing insulator 71 covers the gap covering portion 110 of the upper insulating film 38 at a region between the plurality of source terminal electrodes 60. That is, the sealing insulator 71 covers the gate intermediate wiring 109 with the upper insulating film 38 interposed therebetween.

An example in which the upper insulating film 38 has the gap covering portion 110 has been shown, in this embodiment. However, the presence or the absence of the gap covering portion 110 is arbitrary, and the upper insulating film 38 without the gap covering portion 110 may be formed. In this case, the plurality of source terminal electrodes 60 are formed on the source electrode 32 such as to expose the gate intermediate wiring 109. The sealing insulator 71 directly covers the gate intermediate wiring 109, and electrically isolates the gate intermediate wiring 109 from the source electrode 32. The sealing insulator 71 directly covers a part of the interlayer insulating film 27 that exposes at a region between the source electrode 32 and the gate intermediate wiring 109 inside the gap portion 107.

As described above, the same effects as those of the semiconductor device 1A are also achieved with the semiconductor device 1D. In the manufacturing method for the semiconductor device 1D, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1D.

An example in which the gap portion 107, the gate intermediate wiring 109, the gap covering portion 110, etc., are applied to the semiconductor device 1A has been shown, in this embodiment. As a matter of course, the gap portion 107, the gate intermediate wiring 109, the gap covering portion 110, etc., may be applied to the second and third embodiments.

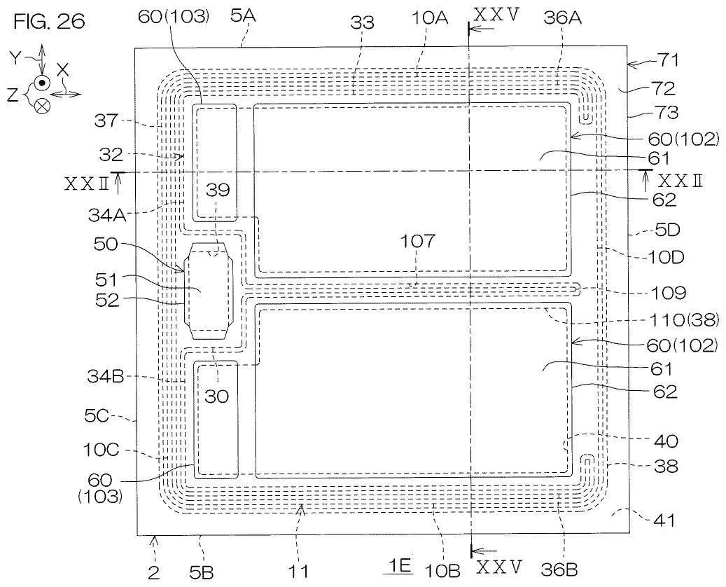

FIG. 26 is a plan view showing a semiconductor device 1E according to a fifth embodiment. With reference to FIG. 26, the semiconductor device 1E has a mode in which the features (structures having the gate intermediate wiring 109) of the semiconductor device 1D according to the forth embodiment are combined to the features (structures having the sense terminal electrode 103) of the semiconductor device 1C according to the third embodiment. The same effects as those of the semiconductor device 1A are also achieved with the semiconductor device 1E having such a mode.

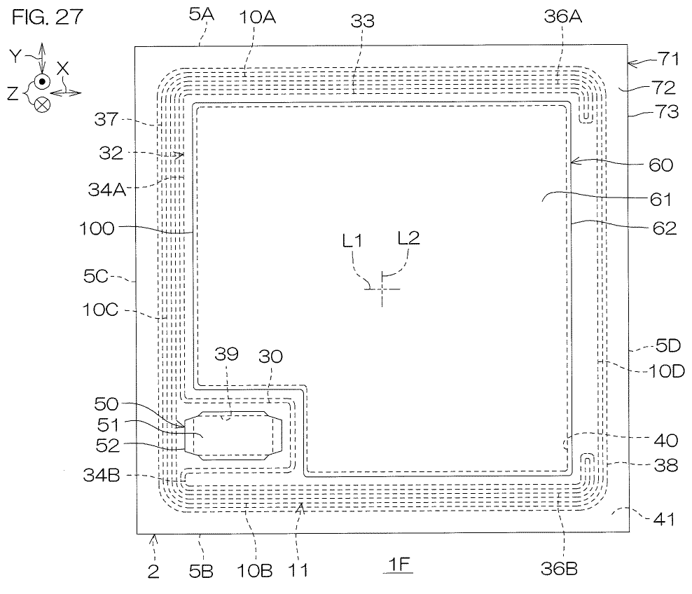

FIG. 27 is a plan view showing a semiconductor device 1F according to an sixth embodiment. With reference to FIG. 27, the semiconductor device 1F has a modified mode of the semiconductor device 1A. Specifically, the semiconductor device 1F has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 50 aforementioned is arranged on the gate electrode 30 as with the case of the first embodiment. The gate terminal electrode 50 is arranged at a region along an arbitrary corner portion of the chip 2, in this embodiment. That is, the gate terminal electrode 50 is arranged at a position offset from both of the first straight line L1 and the second straight line L2 in plan view. The gate terminal electrode 50 is arranged at the region along the corner portion that connects the second side surface 5B and the third side surface 5C in plan view, in this embodiment.

The source terminal electrode 60 aforementioned has the drawer terminal portion 100 that is drawn out onto the first drawer electrode portion 34A, in this embodiment. The source terminal electrode 60 does not have the drawer terminal portion 100 that is drawn out onto the second drawer electrode portion 34B, in this embodiment. The drawer terminal portions 100 thereby faces the gate terminal electrode 50 from one side of the second direction Y. The source terminal electrode 60 has portions that face the gate terminal electrode 50 from two directions including the first direction X and the second direction Y by having the drawer terminal portion 100.

As described above, the same effects as those of the semiconductor device 1A are also achieved with the semiconductor device 1F. In the manufacturing method for the semiconductor device 1F, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1F. The structure in which the gate electrode 30 and the gate terminal electrode 50 are arranged at the corner portion of the chip 2 may be applied to the second to fifth embodiments.

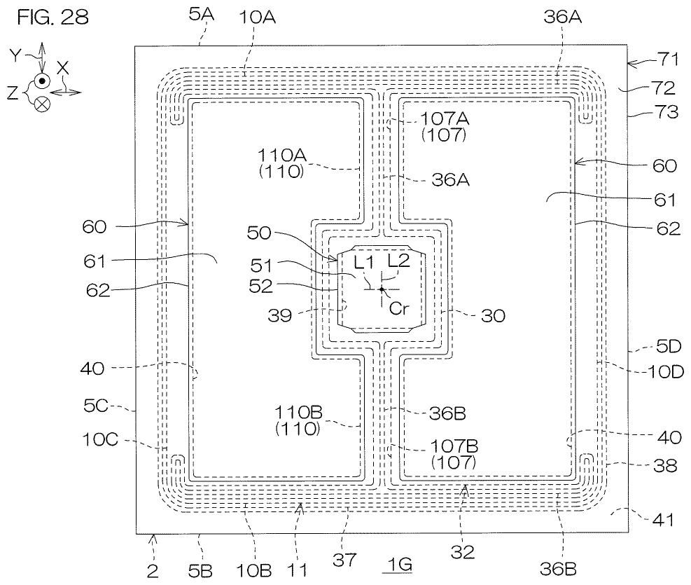

FIG. 28 is a plan view showing a semiconductor device 1G according to a seventh embodiment. With reference to FIG. 28, the semiconductor device 1G has a modified mode of the semiconductor device 1A. Specifically, the semiconductor device 1I has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 aforementioned is formed in an annular shape (specifically, a quadrangle annular shape) surrounding the gate electrode 30 in plan view, in this embodiment.

The semiconductor device 1G includes a plurality of gap portions 107A, 107B that are formed in the source electrode 32. The plurality of gap portions 107A, 107B includes a first gap portions 107A and a second gap portions 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first gap portion 107A. The second gap covering portion 110B covers a whole region of the second gate wiring 36B in the second gap portion 107B. The plurality of gap covering portions 110A, 110B are each drawn out onto the source electrode 32 from inside the plurality of gap portions 107A, 107B such as to cover the peripheral edge portion of the source electrode 32.

The gate terminal electrode 50 aforementioned is arranged on the gate electrode 30 as with the case of the first embodiment. The gate terminal electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 50 is arranged such as to overlap the intersecting portion Cr of the first straight line L1 and the second straight line L2.

The semiconductor device 1G includes a plurality of source terminal electrodes 60 that are arranged on the source electrode 32, in this embodiment. The plurality of source terminal electrodes 60 are each arranged on the source electrode 32 at intervals from the plurality of gap portions 107A, 107B and face each other in the first direction X in plan view. The plurality of source terminal electrodes 60 are arranged such as to expose the plurality of gap portions 107A, 107B, in this embodiment.

The plurality of source terminal electrodes 60 are each formed in a band shape (specifically, C-letter shape curved along the gate terminal electrode 50) in plan view, in this embodiment. The planar shapes of the plurality of source terminal electrodes 60 are arbitrary, and may each be formed in a quadrangle shape, a polygonal shape other than the quadrangle shape, a circular shape or an elliptical shape. The plurality of source terminal electrodes 60 may each include the second protrusion portion 63 that is arranged on the gap covering portion 110A, 110B of the upper insulating film 38.

The sealing insulator 71 aforementioned covers the plurality of gap portions 107A, 107B at a region between the plurality of source terminal electrodes 60, in this embodiment. The sealing insulator 71 covers the plurality of gap covering portion 110A, 110B at a region between the plurality of source terminal electrodes 60, in this embodiment. That is, the sealing insulator 71 covers the plurality of gate wiring 36A, 36B with the plurality of gap covering portion 110A, 110B interposed therebetween.

An example in which the upper insulating film 38 has the gap covering portion 110A, 110B has been shown, in this embodiment. However, the presence or the absence of the plurality of gap covering portion 110A, 110B is arbitrary and the upper insulating film 38 without the plurality of gap covering portion 110A, 110B may be formed. In this case, the plurality of source terminal electrodes 60 are formed on the source electrode 32 such as to expose the gate wirings 36A, 36B.

The sealing insulator 71 directly covers the gate wirings 36A, 36B and electrically isolates the gate wirings 36A, 36B from the source electrode 32. The sealing insulator 71 directly covers a part of the interlayer insulating film 27 exposed from a region between the source electrode 32 and the gate wirings 36A, 36B inside the plurality of gap portions 107A, 107B.

As described above, the same effects as those of the semiconductor device 1A are also achieved with the semiconductor device 1G. In the manufacturing method for the semiconductor device 1G, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1G. The structure in which the gate electrode 30 and the gate terminal electrode 50 are arranged at the central portion of the chip 2 may be applied to the second to sixth embodiments.

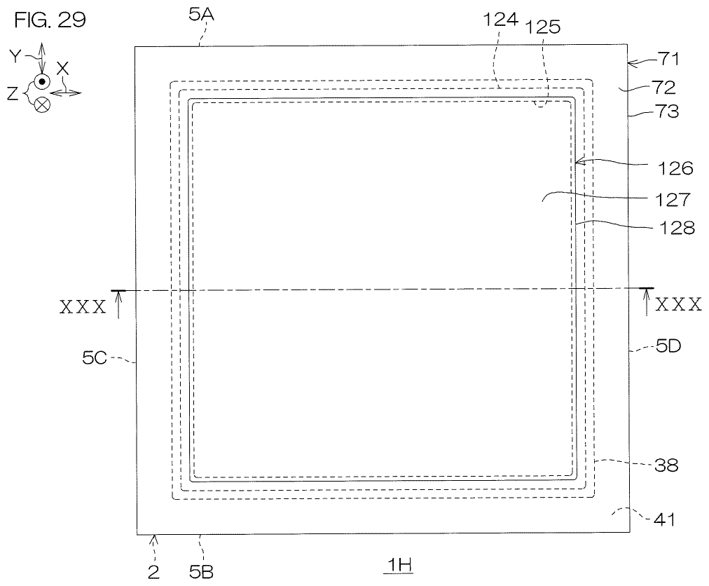

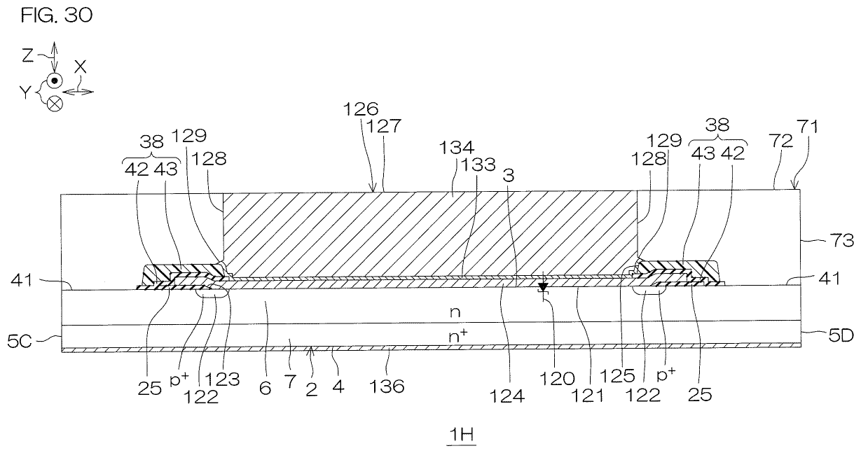

FIG. 29 is a plan view showing a semiconductor device 1H according to a eighth embodiment. FIG. 30 is a cross sectional view taken along XXIII-XXIII line shown in FIG. 24. The semiconductor device 1H includes the chip 2 aforementioned. The chip 2 is free from the mesa portion 11 in this embodiment and has the flat first main surface 3. The semiconductor device 1H has an SBD (Schottky Barrier Diode) structure 120 that is formed in the chip 2 as an example of a diode. Hereinafter the SBD structure 120 shall be specifically described.

The semiconductor device 1H includes a diode region 121 of the n-type that is formed in an inner portion of the first main surface 3. The diode region 121 is formed by using a part of the first semiconductor region 6, in this embodiment. The semiconductor device 1H includes a guard region 122 of the p-type that demarcates the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1H includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1H includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1H includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 has a contact opening 125 exposing an inner portion of the first polar electrode 124 and covers a peripheral edge portion of the first polar electrode 124 over an entire circumference in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1H includes a terminal electrode 126 that is arranged on the first polar electrode 124. The terminal electrode 126 is erected in a columnar shape on a portion of the first polar electrode 124 that is exposed from the contact opening 125. The terminal electrode 126 may have an area less than the area of the first polar electrode 124 in plan view, and may be arranged on an inner portion of the first polar electrode 124 at an interval from the peripheral edge of the first polar electrode 124. The terminal electrode 126 is formed in a polygonal shape (in this embodiment, quadrangle shape) having four sides parallel to the first to fourth side surfaces 5A to 5D in plan view, in this embodiment.

The terminal electrode 126 has a terminal surface 127 and a terminal side wall 128. The terminal surface 127 flatly extends along the first main surface. The terminal surface 127 may consist of a ground surface with grinding marks. The terminal side wall 128 is located on the upper insulating film 38 (specifically, the organic insulating film 43), in this embodiment.

That is, the terminal electrode 126 has a portion in contact with the inorganic insulating film 42 and the organic insulating film 43. The terminal side wall 128 extends substantially vertically to the normal direction Z. Here, “substantially vertically” includes a mode that extends in the laminate direction while being curved (meandering). The terminal side wall 128 includes a portion that faces the first polar electrode 124 with the upper insulating film 38 interposed therebetween. The terminal side wall 128 preferably consists of a smooth surface without a grinding mark.

The terminal electrode 126 has a protrusion portion 129 that outwardly protrudes at a lower end portion of the terminal side wall 128. The protrusion portion 129 is formed at a region on the upper insulating film 38 (the organic insulating film 43) side than an intermediate portion of the terminal side wall 128. The protrusion portion 129 extends along the outer surface of the upper insulating film 38, and is formed in a tapered shape in which a thickness gradually decreases toward the tip portion from the terminal side wall 128 in cross sectional view. The protrusion portion 129 therefore has a sharp-shaped tip portion with an acute angle. As a matter of course, the protrusion portion 129 without the protrusion portion 129 may be formed.

The terminal electrode 126 preferably has a thickness exceeding the thickness of the first polar electrode 124. The thickness of the terminal electrode 126 particularly preferably exceeds the thickness of the upper insulating film 38. The thickness of the terminal electrode 126 exceeds the thickness of the chip 2, in this embodiment. As a matter of course, the thickness of the terminal electrode 126 may be less than the thickness of the chip 2.

The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm. The terminal electrode 126 preferably has a planar area of not less than 50% of the first main surface 3. The terminal electrode 126 particularly preferably has a planar area of not less than 75% of the first main surface 3.

The terminal electrode 126 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125 and is drawn out onto the upper insulating film 38 in a film shape. The first conductor film 133 forms a part of the protrusion portion 129. The first conductor film 133 does not necessarily have to be formed and may be omitted.

The second conductor film 134 forms a body of the terminal electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125, and is drawn out onto the upper insulating film 38 in a film shape with the first conductor film 133 interposed therebetween. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The semiconductor device 1H includes the sealing insulator 71 aforementioned that covers the first main surface 3. The sealing insulator 71 covers a periphery of the terminal electrode 126 such as to expose a part of the terminal electrode 126 on the first main surface 3, in this embodiment. Specifically, the sealing insulator 71 exposes the terminal surface 127 and covers the terminal side wall 128. The sealing insulator 71 covers the protrusion portion 129 and faces the upper insulating film 38 with the protrusion portion 129 interposed therebetween, in this embodiment. The sealing insulator 71 suppresses a dropout of the terminal electrode 126.

The sealing insulator 71 has a portion that directly covers the upper insulating film 38. The sealing insulator 71 covers the first polar electrode 124 with the upper insulating film 38 interposed therebetween. The sealing insulator 71 covers the dicing street 41 that is demarcated by the upper insulating film 38 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

The sealing insulator 71 has the insulating main surface 72 and the insulating side wall 73. The insulating main surface 72 flatly extends along the first main surface 3. The insulating main surface 72 forms a single flat surface with the terminal surface 127. The insulating main surface 72 may consist of a ground surface with grinding marks. In this case, the insulating main surface 72 preferably forms a single ground surface with the terminal surface 127.

The insulating side wall 73 extends toward the chip 2 from the peripheral edge of the insulating main surface 72 and is continuous to the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The semiconductor device 1H includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 and second polar electrode 136. That is, the chip 2 is formed such that the voltage of not less than 500 V and not more than 3000 V is to be applied between the first main surface 3 and the second main surface 4.

As described above, the semiconductor device 1H includes the chip 2, the first polar electrode 124 (main surface electrode), the terminal electrode 126 and the sealing insulator 71. The chip 2 has the first main surface 3. The first polar electrode 124 is arranged on the first main surface 3. The terminal electrode 126 is arranged on the first polar electrode 124. The sealing insulator 71 covers the periphery of the terminal electrode 126 on the first main surface 3 such as to expose a part of the terminal electrode 126.

According to this structure, an object to be sealed can be protected from the external force and the humidity (moisture) by the sealing insulator 71. That is, the object to be sealed can be protected from a damage (including peeling due to the external force and deterioration (including corrosion) due to the humidity. It is therefore possible to suppress shape defects and fluctuations in electrical characteristics. As a result, it is possible to provide the semiconductor device 1H capable of improving reliability.

Thus, the same effects as those of the semiconductor device 1A are also achieved with the semiconductor device 1H. In the manufacturing method for the semiconductor device 1H, the same steps as the manufacturing method for the semiconductor device 1A are performed, except that the layouts of various masks are adjusted. Therefore, the same effects as those of the manufacturing method for the semiconductor device 1A are also achieved with the manufacturing method for the semiconductor device 1H.

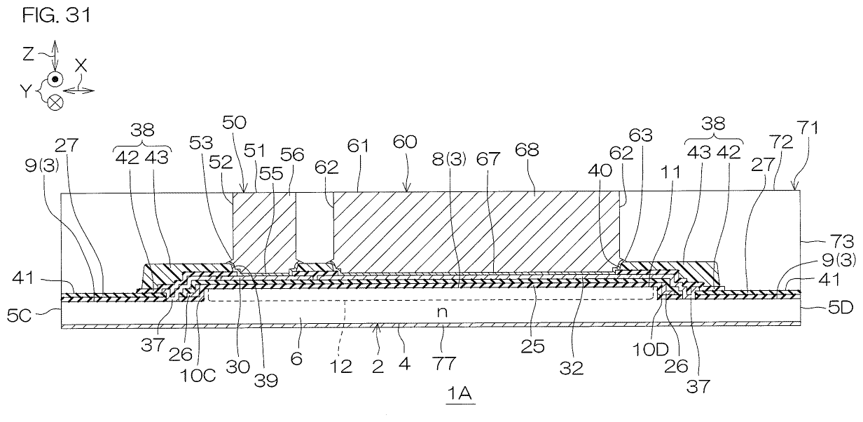

Hereinafter, modified examples to be applied to each embodiment shall be shown. FIG. 31 is a cross sectional view showing a modified example of the chip 2 to be applied to each of the embodiments. In FIG. 31, a mode in which the modified example of the chip 2 is applied to the semiconductor device 1A is shown as an example. However, the modified example of the chip 2 may be applied to any one of the second to eighth embodiments.

With reference to FIG. 31, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment.

Such chip 2 is formed by completely removing a portion (the second semiconductor region 7) of the sealed wafer 331 consisting of the first wafer portion 333 in the thinning step of the sealed wafer 331 (step S7 of FIG. 9) in the first to third manufacturing method examples described above. Also, such chip 2 is formed by completely removing a portion (the second semiconductor region 7) of the epi-wafer 440 consisting of the wafer 430 in the thinning step of the wafer 430 (step S31 of FIG. 17) in the fourth and fifth manufacturing method examples described above.

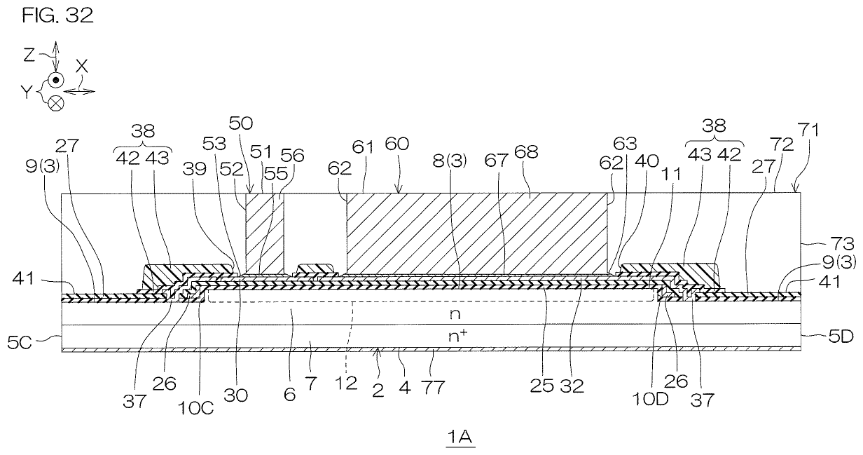

FIG. 32 is a cross sectional view showing a modified example of the sealing insulator 71 to be applied to each of the embodiments. In FIG. 32, a mode in which the modified example of the sealing insulator 71 is applied to the semiconductor device 1A is shown as an example. However, the modified example of the sealing insulator 71 may be applied to any one of the second to tenth embodiments.

With reference to FIG. 32, the semiconductor device 1A may include the sealing insulator 71 that covers a whole region of the upper insulating film 38. In this case, in the first to seventh embodiments, the gate terminal electrode 50 and the source terminal electrode 60 that are not in contact with the upper insulating film 38 are formed. In this case, the sealing insulator 71 may have a portion that directly covers the gate electrode 30 and the source electrode 32. On the other hand, in the eighth embodiment, the terminal electrode 126 that is not in contact with the upper insulating film 38 is formed. In this case, the sealing insulator 71 may have a portion that directly covers the first polar electrode 124.

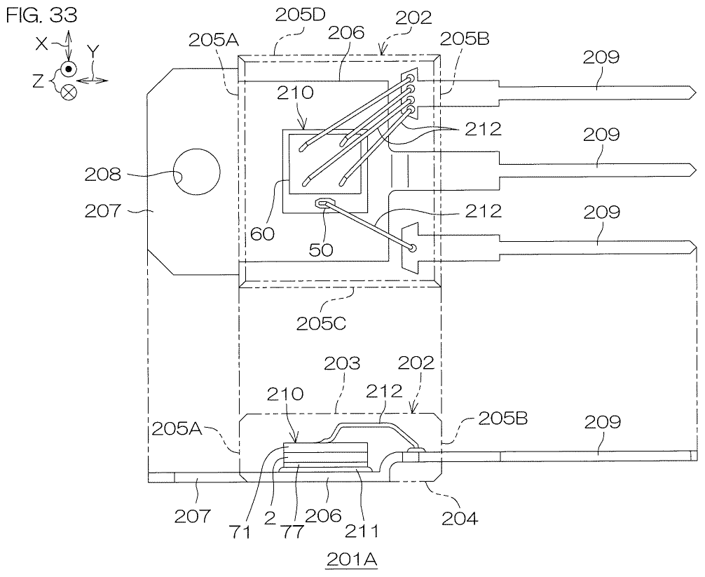

Hereinafter, configuration examples of packages to which any one or plural of the semiconductor devices 1A to 1H according to the first to eighth embodiments are to be incorporated shall be shown. FIG. 33 is a plan view showing a package 201A to which any one of the semiconductor devices 1A to 1G according to the first to seventh embodiments is to be incorporated. The package 201A may be referred to as a “semiconductor package” or a “semiconductor module”.

With reference to FIG. 33, the package 201A includes a package body 202 of a rectangular parallelepiped shape. The package body 202 consists of a mold resin and includes a matrix resin (for example, epoxy resin), a plurality of fillers and a plurality of flexible particles (flexible agent) as with the sealing insulator 71. The package body 202 has a first surface 203 on one side, a second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to an outside of the package body 202. The drawer board part 207 has a through hole 208 of a circular shape. The metal plate 206 may be exposed from the second surface 204.

The package 201A includes a plurality of (in this embodiment, three) lead terminals 209 that are pulled out from an inside of the package body 202 to the outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1G according to the first to seventh embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of a gold wire, a copper wire and an aluminum wire. As a matter of course, the conducting wires 212 may each consist of a metal plate such as a metal clip, instead of the metal wire.

At least one (in this embodiment, one) conducting wire 212 is electrically connected to the gate terminal electrode 50 and the lead terminal 209. At least one (in this embodiment, four) conducting wires 212 are electrically connected to the source terminal electrode 60 and the lead terminal 209. In a case in which the source terminal electrode 60 includes the sense terminal electrode 103 (see FIG. 14), the lead terminal 209 corresponding to the sense terminal electrode 103, and the conducting wire 212 corresponding to the sense terminal electrode 103 and the lead terminals 209 may be provided.

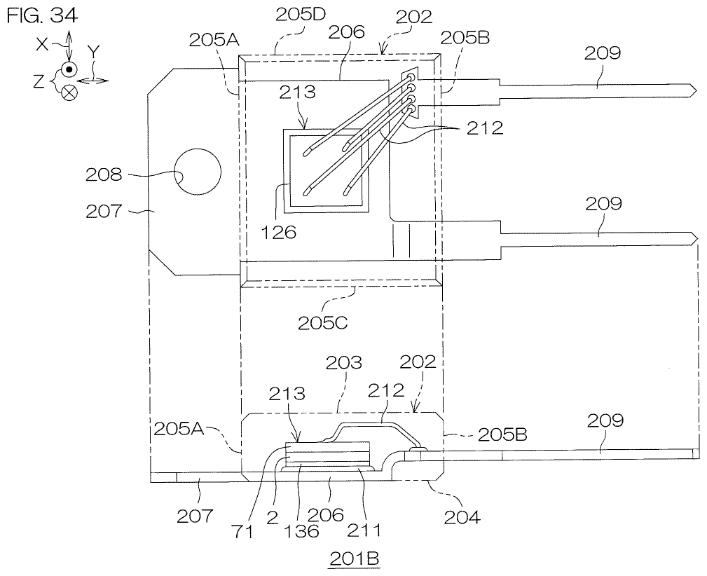

FIG. 34 is a plan view showing a package 201B to which the semiconductor device 1H according to the eighth embodiment is to be incorporated. The package 201B may be referred to as a “semiconductor package” or a “semiconductor module”. With reference to FIG. 34, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of the semiconductor device 1H according to the eighth embodiment. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal electrode 126 and the lead terminal 209.

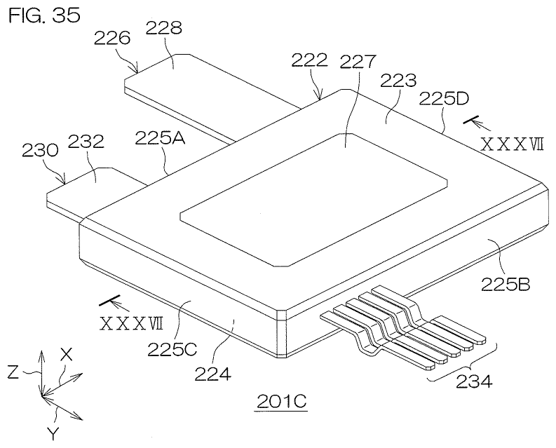

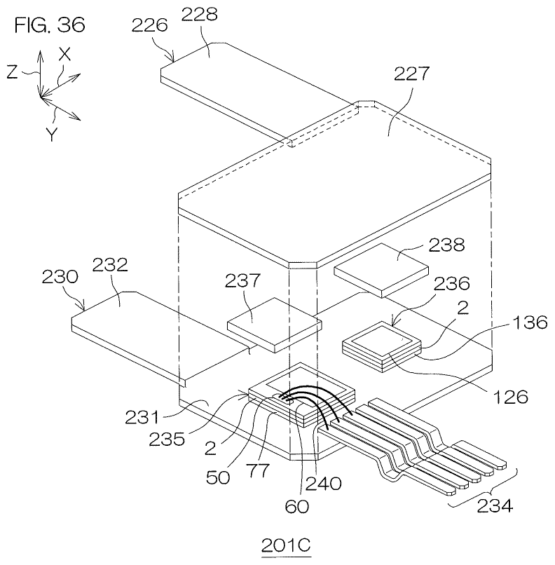

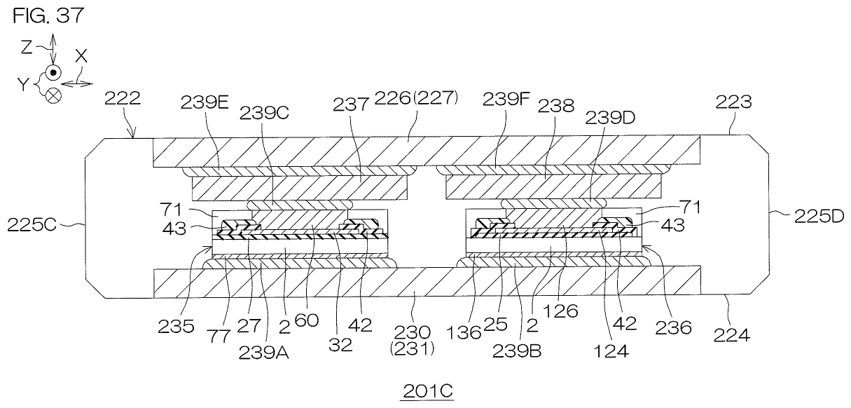

FIG. 35 is a perspective view showing a package 201C to which any one of the semiconductor devices 1A to 1G according to the first to seventh embodiments and the semiconductor device 1H according to the eighth embodiment are to be incorporated. FIG. 36 is an exploded perspective view of the package 201C shown in FIG. 35. FIG. 37 is a cross sectional view taken along XXXVII-XXXVII line shown in FIG. 35. The package 201C may be referred to as a “semiconductor package” or a “semiconductor module”.

With reference to FIG. 35 to FIG. 37, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, the second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes a second pad portion 231 and a second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1G according to the first to seventh embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of the semiconductor device 1H according to the eighth embodiments. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal electrode 60 and the first conductor spacer 237, and connects the first conductor spacer 237 to the source terminal electrode 60. The fourth conductive adhesive 239D is interposed between the terminal electrode 126 and the second conductor spacer 238, and connects the second conductor spacer 238 to the terminal electrode 126.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal electrode 50 of the first semiconductor device 235 and at least one (in this embodiment, a plurality of) third lead terminals 234 inside the package body 222. The conducting wires 240 each consists of a metal wire (that is, bonding wire), in this embodiment.

The conducting wires 240 may include at least one of a gold wire, a copper wire and an aluminum wire. As a matter of course, the conducting wires 240 may each consist of a metal plate such as a metal clip, instead of the metal wire. In a case in which the source terminal electrode 60 includes the sense terminal electrode 103 (see FIG. 15), a conducting wire 240 to be connected to the sense terminal electrode 103 and the third lead terminal 234 may be further provide.

An example in which the source terminal electrode 60 is connected to the first pad portion 227 via the first conductor spacers 237 has been shown, in this embodiment. However, the source terminal electrode 60 may be connected to the first pad portion 227 by the third conductive adhesive 239C without the first conductor spacer 237. Also, an example in which the terminal electrode 126 is connected to the first pad portion 227 via the second conductor spacers 238 has been shown, in this embodiment. However, the terminal electrode 126 may be connected to the first pad portion 227 by the fourth conductive adhesive 239D without the second conductor spacers 238.

Each of the above embodiments can be implemented in yet other embodiments. For example, features disclosed in the first to eighth embodiments aforementioned can be appropriately combined therebetween. That is, a configuration that includes at least two features among the features disclosed in the first to eighth embodiments aforementioned at the same time may be adopted.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.

[A1] A manufacturing method for a semiconductor device (1A to 1H) comprising: a step of preparing a wafer source (300) that has a first main surface (301) on one side and a second main surface (302) on the other side; a step of forming a main surface electrode (30, 32, 124) on the first main surface (301); a step of forming a terminal electrode (50, 60, 126) on the main surface electrode (30, 32, 124); a step of forming a sealing insulator (71) that covers a periphery of the terminal electrode (50, 60, 126) on the first main surface (301) such as to expose a part of the terminal electrode (50, 60, 126); and a step of cutting the wafer source (300) in a horizontal direction along the first main surface (301) from an intermediate portion of a thickness range of the wafer source (300), and separating the wafer source (300) into a sealed wafer (331) on the sealing insulator (71) side and an unsealed wafer (332) on the second surface side (302).

[A2] The manufacturing method for the semiconductor device (1A to 1H) according to A1, wherein the wafer source (300) cut out from an ingot is prepared.

[A3] The manufacturing method for the semiconductor device (1A to 1H) according to A1 or A2, wherein the separating step of the wafer source (300) includes a step of cutting out the sealed wafer (331) that is thinner than the sealing insulator (71).

[A4] The manufacturing method for the semiconductor device (1A to 1H) according to any one of A1 to A3, wherein the separating step of the wafer source (300) includes a step of cutting out the sealed wafer (331) that is thinner than the terminal electrode (50, 60, 126).

[A5] The manufacturing method for the semiconductor device (1A to 1H) according to A1 or A2, wherein the separating step of the wafer source (300) includes a step of cutting out the sealed wafer (331) that is thicker than the sealing insulator (71).

[A6] The manufacturing method for the semiconductor device (1A to 1H) according to A5, further comprising: a step of thinning the sealed wafer (331) until the sealed wafer (331) becomes thinner than the sealing insulator (71), after the separating step of the wafer source (300).

[A7] The manufacturing method for the semiconductor device (1A to 1H) according to any one of A1 to A6, wherein the separating step of the wafer source (300) includes a step of cutting out the unsealed wafer (332) that is thicker than the sealed wafer (331).

[A8] The manufacturing method for the semiconductor device (1A to 1H) according to any one of A1 to A7, wherein the separating step of the wafer source (300) includes a step of cutting out the unsealed wafer (332) that is thicker than the sealing insulator (71).

[A9] The manufacturing method for the semiconductor device (1A to 1H) according to any one of A1 to A8, wherein the separating step of the wafer source (300) includes a step of forming a modified layer (326) that extends along the horizontal direction at the intermediate portion of the thickness range of the wafer source (300) by a laser light irradiating method, and thereafter cleaving the wafer source (300) in the horizontal direction with the modified layer (326) as a starting point.

[A10] The manufacturing method for the semiconductor device (1A to 1H) according to any one of A1 to A9, further comprising: a step of attaching a supporting substrate (310) to the second main surface (302) before the separating step of the wafer source (300); wherein the separating step of the wafer source (300) includes a step of separating the wafer source (300) into the sealed wafer (331) on the sealing insulator (71) side and the unsealed wafer (332) on the supporting substrate (310) side.

[A11] The manufacturing method for the semiconductor device (1A to 1H) according to A10, further comprising: a step of transferring the sealed wafer (331) with the sealing insulator (71) as a supporting member; and a step of transferring the unsealed wafer (332) with the supporting substrate (310) as a supporting member.

[A12] The manufacturing method for the semiconductor device (1A to 1H) according to any one of A1 to A11, further comprising: a step of reusing the unsealed wafer (332).

[A13] The manufacturing method for the semiconductor device (1A to 1H) according to any one of A1 to A12, further comprising: a step of thinning the sealed wafer (331) from a cut surface (334) side of the sealed wafer (331) in a state of being supported by the sealing insulator (71).

[A14] The manufacturing method for the semiconductor device (1A to 1H) according to any one of A1 to A13, further comprising: a step of forming a second main surface electrode (77, 136) that covers a cut surface (334) of the sealed wafer (331).

[A15] The manufacturing method for the semiconductor device (1A to 1H) according to any one of A1 to A14, further comprising: a step of cutting the sealed wafer (331) together with the sealing insulator (71).

[A16] The manufacturing method for the semiconductor device (1A to 1H) according to any one of A1 to A15, further comprising: a step of forming an insulating film (38) that partially covers the main surface electrode (30, 32, 124), before the forming step of the terminal electrode (50, 60, 126); wherein the forming step of the sealing insulator (71) includes a step of forming the sealing insulator (71) that covers the terminal electrode (50, 60, 126) and the insulating film (38).

[A17] The manufacturing method for the semiconductor device (1A to 1H) according to A16, wherein the forming step of the terminal electrode (50, 60, 126) includes a step of forming the terminal electrode (50, 60, 126) having a portion that directly covers the insulating film (38).

[A18] The manufacturing method for the semiconductor device (1A to 1H) according to A16 or A17, wherein the forming step of the insulating film (38) includes a step of forming the insulating film (38) that includes one or both of an inorganic insulating film (42) and an organic insulating film (43).

[A19] The manufacturing method for the semiconductor device (1A to 1H) according to any one of A1 to A18, wherein the forming step of the sealing insulator (71) includes a step of forming the sealing insulator (71) that covers a whole region of the terminal electrode (50, 60, 126) and a step of thinning the sealing insulator (71) until a portion of the terminal electrode (50, 60, 126) becomes exposed.

[A20] The manufacturing method for the semiconductor device (1A to 1H) according to any one of A1 to A19, wherein the forming step of the sealing insulator (71) includes a step of supplying a sealant (350) including a thermosetting resin onto the first main surface (301) and thermosetting the sealant (350).

[A21] The manufacturing method for the semiconductor device (1A to 1H) according to any one of A1 to A20, wherein the forming step of the terminal electrode (50, 60, 126) includes a step of forming a conductor film (346) that covers the main surface electrode (30, 32, 124), a step of forming a mask (M10) that exposes a portion of the conductor film (346) covering the main surface electrode (30, 32, 124), a step of depositing a conductor (349) on the portion of the conductor film (346) exposed from the mask (M10), and a step of removing the mask (M10) after the depositing step of the conductor (349).

[A22] The manufacturing method for the semiconductor device (1A to 1H) according to any one of A1 to A21, further comprising: a step of growing an epitaxial layer (321) from the first main surface (301) to form a wafer structure (322) that includes the wafer source (300) and the epitaxial layer (321) and that has the first main surface (301) formed by the epitaxial layer (321), before the forming step of the main surface electrode (30, 32, 124); wherein the separating step of the wafer source (300) includes a step of separating the wafer structure (322) into the sealed wafer (331) composed of a first wafer portion (333) consisting of a portion of the wafer source (300) and the epitaxial layer (321) laminated on the first wafer portion (333) and the unsealed wafer (332) composed of a second wafer portion (335) consisting of a portion of the wafer source (300).

[A23] The manufacturing method for the semiconductor device (1A to 1H) according to A22, wherein the sealed wafer (331) includes the epitaxial layer (321) that is thicker than the first wafer portion (333).

[A24] The manufacturing method for the semiconductor device (1A to 1H) according to A23, wherein the sealed wafer (331) includes the epitaxial layer (321) that is thinner than the first wafer portion (333).

[A25] The manufacturing method for the semiconductor device (1A to 1H) according to any one of A22 to A24, further comprising: a step of removing at least a portion of the first wafer portion (333) from the wafer structure (322) in a state of being supported by the sealing insulator (71), after the separating step of the wafer source (300).

[A26] The manufacturing method for the semiconductor device (1A to 1H) according to any one of A22 to A25, wherein the unsealed wafer (332) is composed of the second wafer portion (333) that is thicker than the first wafer portion (333).

[A27] The manufacturing method for the semiconductor device (1A to 1H) according to any one of A1 to A26, wherein the wafer source (300) includes a monocrystal of a wide bandgap semiconductor.

[A28] The manufacturing method for the semiconductor device (1A to 1H) according to any one of A1 to A27, wherein the wafer source (300) includes an SiC monocrystal.

[B1] A manufacturing method for a semiconductor device (1A to 1H) comprising: a step of preparing a wafer source (300) that has a first main surface (301) on one side and a second main surface (302) on the other side; a step of attaching a supporting substrate (400) onto the second main surface (302); a step of cutting the wafer source (300) in a horizontal direction along the first main surface (301) from an intermediate portion of a thickness range of the wafer source (300), and separating a wafer (430) having a first wafer main surface (431) consisting of a cut surface and a second wafer main surface (432) consisting of the second main surface (302) from the wafer source (300) with the supporting substrate (400); a step of forming a main surface electrode (30, 32, 124) on the wafer main surface (431); a step of forming a terminal electrode (50, 60, 126) on the main surface electrode (30, 32, 124); a step of forming a sealing insulator (71) that covers a periphery of the terminal electrode (50, 60, 126) on the wafer main surface (431) such as to expose a part of the terminal electrode (50, 60, 126); and a step of removing the supporting substrate (400) in a state in which the wafer (430) is supported by the sealing insulator (71).

[B2] The manufacturing method for the semiconductor device (1A to 1H) according to B1, wherein the wafer source (300) cut out from an ingot is prepared.

[B3] The manufacturing method for the semiconductor device (1A to 1H) according to B1 or B2, wherein the separating step of the wafer source (300) includes a step of separating the wafer (430) that is thinner than the supporting substrate (400) from the wafer source (300).

[B4] The manufacturing method for the semiconductor device (1A to 1H) according to any one of B1 to B3, further comprising: a step of repeating a series of steps including the attaching step of the supporting substrate (400) and the separating step of the wafer source (300) until the wafer source (300) becomes inseparable.

[B5] The manufacturing method for the semiconductor device (1A to 1H) according to any one of B1 to B4, wherein the separating step of the wafer source (300) includes a step of forming a modified layer (422) oriented along the horizontal direction at the intermediate portion of the thickness range of the wafer source (300) by a laser light irradiating method, and thereafter cleaving the wafer source (300) in the horizontal direction with the modified layer (422) as a starting point.

[B6] The manufacturing method for the semiconductor device (1A to 1H) according to any one of B1 to B5, wherein the removing step of the supporting substrate (400) includes a step of separating the supporting substrate (400) from the wafer (430).

[B7] The manufacturing method for the semiconductor device (1A to 1H) according to any one of B1 to B6, wherein the attaching step of the supporting substrate (400) includes a step of attaching the supporting substrate (400) to the second main surface (302) by a direct bonding method, and the removing step of the supporting substrate (400) includes a step of forming a boundary modified layer (441) that extends along the horizontal direction at a boundary portion of the wafer (430) and the supporting substrate (400) or in a vicinity of the boundary portion by a laser light irradiating method, and thereafter cleaving the boundary modified layer (441) in the horizontal direction.

[B8] The manufacturing method for the semiconductor device (1A to 1H) according to B7, wherein the attaching step of the supporting substrate (400) includes a step of forming an amorphous bonding layer (420) between the wafer source (300) and the supporting substrate (400) by the direct bonding method, and the removing step of the supporting substrate (400) includes a step of forming the boundary modified layer (441) that extends along the amorphous bonding layer (420) in an interior or a vicinity of the amorphous bonding layer (420).

[B9] The manufacturing method for the semiconductor device (1A to 1H) according to B8, wherein the amorphous bonding layer (420) has an optical absorption coefficient differing from an optical absorption coefficient of the wafer source (300).

[B10] The manufacturing method for the semiconductor device (1A to 1H) according to any one of B1 to B9, further comprising: a step of thinning the wafer (430) from the second wafer main surface (432) side in a state of being supported by the sealing insulator (71), after the removing step of the supporting substrate (400).

[B11] The manufacturing method for the semiconductor device (1A to 1H) according to B10, wherein the thinning step of the wafer (430) includes a step of further thinning the wafer (430) that is thinner than the sealing insulator (71) or a step of thinning the wafer (430) that is thicker than the sealing insulator (71) until the wafer (430) becomes thinner than the sealing insulator (71).

[B12] The manufacturing method for the semiconductor device (1A to 1H) according to any one of B1 to B11, wherein the forming step of the sealing insulator (71) includes a step of forming the sealing insulator (71) that is thicker than the wafer (430).

[B13] The manufacturing method for the semiconductor device (1A to 1H) according to any one of B1 to B11, wherein the forming step of the sealing insulator (71) includes a step of forming the sealing insulator (71) that is thinner than the wafer (430).

[B14] The manufacturing method for the semiconductor device (1A to 1H) according to any one of B1 to B13, further comprising: a step of forming a second main surface electrode (77, 136) that covers the second wafer main surface (432), after the removing step of the supporting substrate (400).

[B15] The manufacturing method for the semiconductor device (1A to 1H) according to any one of B1 to B14, further comprising: a step of cutting the wafer (430) together with the sealing insulator (71), after the removing step of the supporting substrate (400).

[B16] The manufacturing method for the semiconductor device (1A to 1H) according to any one of B1 to B15, further comprising: a step of forming an insulating film (38) that partially covers the main surface electrode (30, 32, 124), before the forming step of the terminal electrode (50, 60, 126); wherein the forming step of the sealing insulator (71) includes a step of forming the sealing insulator (71) that covers the terminal electrode (50, 60, 126) and the insulating film (38).

[B17] The manufacturing method for the semiconductor device (1A to 1H) according to B16, wherein the forming step of the terminal electrode (50, 60, 126) includes a step of forming the terminal electrode (50, 60, 126) having a portion that directly covers the insulating film (38).

[B18] The manufacturing method for the semiconductor device (1A to 1H) according to B16 or B17, wherein the forming step of the insulating film (38) includes a step of forming the insulating film (38) that includes one or both of an inorganic insulating film (42) and an organic insulating film (43).

[B19] The manufacturing method for the semiconductor device (1A to 1H) according to any one of B1 to B18, wherein the forming step of the sealing insulator (71) includes a step of forming the sealing insulator (71) that covers a whole region of the terminal electrode (50, 60, 126) and a step of thinning the sealing insulator (71) until a portion of the terminal electrode (50, 60, 126) becomes exposed.

[B20] The manufacturing method for the semiconductor device (1A to 1H) according to any one of B1 to B19, wherein the forming step of the sealing insulator (71) includes a step of supplying a sealant (350) including a thermosetting resin onto the first wafer main surface side (431) and thermosetting the sealant (350).

[B21] The manufacturing method for the semiconductor device (1A to 1H) according to any one of B1 to B20, wherein the forming step of the terminal electrode (50, 60, 126) includes a step of forming a conductor film (346) that covers the main surface electrode (30, 32, 124), a step of forming a mask (M10) that exposes a portion of the conductor film (346) covering the main surface electrode (30, 32, 124), a step of depositing a conductor (349) on the portion of the conductor film (346) exposed from the mask (M10), and a step of removing the mask (M10) after the depositing step of the conductor (349).

[B22] The manufacturing method for the semiconductor device (1A to 1H) according to any one of B1 to B21, further comprising: a step of thinning the wafer (430) from the first wafer main surface side (431), before the forming step of the main surface electrode (30, 32, 124).

[B23] The manufacturing method for the semiconductor device (1A to 1H) according to any one of B1 to B22, further comprising: a step of growing an epitaxial layer (435) from the first wafer main surface (431) to form a wafer structure (440) that includes the wafer (430) and the epitaxial layer (435) and that has the first wafer main surface (431) formed by the epitaxial layer (435), before the forming step of the main surface electrode (30, 32, 124).

[B24] The manufacturing method for the semiconductor device (1A to 1H) according to B23, further comprising: a step of removing at least a portion of the wafer (430) from the wafer structure (440) in a state of being supported by the sealing insulator (71), after the removing step of the supporting substrate (400).

[B25] The manufacturing method for the semiconductor device (1A to 1H) according to B24, wherein the removing step of the wafer (430) includes a step of further thinning the wafer (430) that is thinner than the epitaxial layer (435).

[B26] The manufacturing method for the semiconductor device (1A to 1H) according to B23 or B24, wherein the growing step of the epitaxial layer (435) includes a step of forming the epitaxial layer (435) that is thicker than the wafer (430).

[B27] The manufacturing method for the semiconductor device (1A to 1H) according to B26, wherein the removing step of the wafer (430) includes a step of thinning the wafer (430) until the wafer (430) becomes thinner than the epitaxial layer (435).

[B28] The manufacturing method for the semiconductor device (1A to 1H) according to any one of B1 to B27, wherein the wafer (430) includes a monocrystal of a wide bandgap semiconductor.

[B29] The manufacturing method for the semiconductor device (1A to 1H) according to any one of B1 to B28, wherein the wafer (430) includes an SiC monocrystal.

[C1] A wafer attachment structure (320) comprising: a wafer source (300) that has a first main surface (301) on one side and a second main surface (302) on the other side; a supporting substrate (310) that is attached to the second main surface (302); a main surface electrode (30, 32, 124) that is arranged on the first main surface (301); a terminal electrode (50, 60, 126) that is arranged on the main surface electrode (30, 32, 124); and a sealing insulator (71) that covers a periphery of the terminal electrode (50, 60, 126) on the first main surface (301) such as to expose a portion of the terminal electrode (50, 60, 126).

[C2] The wafer attachment structure (320) according to C1, further comprising: a bonding layer (319) that is interposed between the wafer source (300) and the supporting substrate (310) and bonds the wafer source (300) and the supporting substrate (310).

[C3] The wafer attachment structure (320) according to C1 or C2, wherein the bonding layer (319) consists of an amorphous bonding layer (319) that is composed of a portion of the wafer source (300) and a portion of the supporting substrate (310).

[C4] The wafer attachment structure (320) according to any one of C1 to C3, wherein the amorphous bonding layer (319) has an optical absorption coefficient differing from an optical absorption coefficient of the wafer source (300).

[C5] The wafer attachment structure (320) according to C4, wherein the optical absorption coefficient of the amorphous bonding layer (319) exceeds the optical absorption coefficient of the wafer source (300).

[C6] The wafer attachment structure (320) according to any one of C2 to C5, wherein the bonding layer (319) has a thickness of not more than 5 μm.

[C7] The wafer attachment structure (320) according to any one of C1 to C6, wherein the wafer source (300) includes a first mark (304) that indicates a crystal orientation of the wafer source (300) and the supporting substrate (310) includes a second mark (314) that indirectly indicates the crystal orientation of the wafer source (300).

[C8] The wafer attachment structure (320) according to any one of C1 to C7, wherein the sealing insulator (71) is thinner than the wafer source (300).

[C9] The wafer attachment structure (320) according to any one of C1 to C8, further comprising: an insulating film (38) that partially covers the main surface electrode (30, 32, 124); wherein the sealing insulator (71) has a portion that directly covers the insulating film (38).

[C10] The wafer attachment structure (320) according to C9, wherein the terminal electrode (50, 60, 126) is thicker than the insulating film (38) and the sealing insulator (71) is thicker than the insulating film (38).

[C11] The wafer attachment structure (320) according to C9 or C10, wherein the terminal electrode (50, 60, 126) has a portion that directly covers the insulating film (38).

[C12] The wafer attachment structure (320) according to any one of C9 to C11, wherein the sealing insulator (71) includes an insulator different from the insulating film (38).

[C13] The wafer attachment structure (320) according to any one of C9 to C12, wherein the sealing insulator (71) includes a thermosetting resin and the insulating film (38) includes at least one among an inorganic insulating film (42) and a photosensitive resin film (43).

[C14] The wafer attachment structure (320) according to any one of C1 to C13, wherein the wafer source (300) is formed in a disc shape and the supporting substrate (310) is formed in a disc shape.

[C15] The wafer attachment structure (320) according to C14, wherein the wafer source (300) has a first diameter and the supporting substrate (310) has a second diameter different from the first diameter.

[C16] The wafer attachment structure (320) according to C15, wherein the second diameter exceeds the first diameter.

[C17] The wafer attachment structure (320) according to any one of C1 to C17, further comprising: a modified layer (326) that is formed at an intermediate portion of a thickness range of the wafer source (300) such as to extend along a horizontal direction parallel to the first main surface (301).

[C18] The wafer attachment structure (320) according to C17, wherein a distance between the first main surface (301) and the modified layer (326) is less than a distance between the second main surface (302) and the modified layer (326).

[C19] The wafer attachment structure (320) according to C17 or C18, wherein a distance between the first main surface (301) and the modified layer (326) is less than a thickness of the sealing insulator (71).

[C20] The wafer attachment structure (320) according to C17 or C18, wherein a distance between the first main surface (301) and the modified layer (326) exceeds a thickness of the sealing insulator (71).

[C21] The wafer attachment structure (320) according to any one of C1 to C20, further comprising: a wafer structure (331) that includes the wafer source (300) and an epitaxial layer (321) laminated on the wafer source (300) and has the first main surface (301) formed by the epitaxial layer (321) and the second main surface (302) formed by the wafer source (300).

[C22] The wafer attachment structure (320) according to C21, wherein the epitaxial layer (321) covers a side surface (303) of the wafer source (300).

[C23] The wafer attachment structure (320) according to any one of C1 to C22, wherein the wafer source (300) includes a monocrystal of a wide bandgap semiconductor and the supporting substrate (310) includes a monocrystal of a wide bandgap semiconductor.

[C24] The wafer attachment structure (320) according to any one of C1 to C23, wherein the wafer source (300) includes an SiC monocrystal and the supporting substrate (310) includes an SiC monocrystal.

[D1] A wafer attachment structure (434) comprising: a wafer (430) that has a first main surface (431) on one side and a second main surface (432) on the other side; a supporting substrate (400) that is attached to the second main surface (432); a main surface electrode (30, 32, 124) that is arranged on the first main surface (431); a terminal electrode (50, 60, 126) that is arranged on the main surface electrode (30, 32, 124); and a sealing insulator (71) that covers a periphery of the terminal electrode (50, 60, 126) on the first main surface (431) such as to expose a portion of the terminal electrode (50, 60, 126).

[D2] The wafer attachment structure (434) according to D1, further comprising: a bonding layer (420) that is interposed between the wafer (430) and the supporting substrate (400) and bonds the wafer (430) and the supporting substrate (400).

[D3] The wafer attachment structure (434) according to D1 or D2, wherein the bonding layer (420) consists of an amorphous bonding layer (420) that is composed of a portion of the wafer (430) and a portion of the supporting substrate (400).

[D4] The wafer attachment structure (434) according to any one of D1 to D3, wherein the amorphous bonding layer (420) has an optical absorption coefficient differing from an optical absorption coefficient of the wafer (430).

[D5] The wafer attachment structure (434) according to D4, wherein the optical absorption coefficient of the amorphous bonding layer (420) exceeds the optical absorption coefficient of the wafer (430).

[D6] The wafer attachment structure (434) according to any one of D2 to D5, wherein the bonding layer (420) has a thickness of not more than 5 μm.

[D7] The wafer attachment structure (434) according to any one of D1 to D6, wherein the wafer (430) includes a first mark (304) that indicates a crystal orientation of the wafer (430) and the supporting substrate (400) includes a second mark (404) that indirectly indicates the crystal orientation of the wafer (430).

[D8] The wafer attachment structure (434) according to any one of D1 to D7, wherein the supporting substrate (400) is thicker than the wafer.

[D9] The wafer attachment structure (434) according to any one of D1 to D8, wherein the sealing insulator (71) is thicker than the wafer (430).

[D10] The wafer attachment structure (434) according to any one of D1 to D8, wherein the sealing insulator (71) is thinner than the wafer (430).

[D11] The wafer attachment structure (434) according to any one of D1 to D10, further comprising: an insulating film (38) that partially covers the main surface electrode (30, 32, 124); wherein the sealing insulator (71) has a portion that directly covers the insulating film (38).

[D12] The wafer attachment structure (434) according to D11, wherein the terminal electrode (50, 60, 126) is thicker than the insulating film (38) and the sealing insulator (71) is thicker than the insulating film (38).

[D13] The wafer attachment structure (434) according to D11 or D12, wherein the terminal electrode (50, 60, 126) has a portion that directly covers the insulating film (38).

[D14] The wafer attachment structure (434) according to any one of D11 to D13, wherein the sealing insulator (71) includes an insulator different from the insulating film (38).

[D15] The wafer attachment structure (434) according to any one of D11 to D14, wherein the sealing insulator (71) includes a thermosetting resin, and the insulating film (38) includes at least one among an inorganic insulating film (42) and a photosensitive resin film (43).

[D16] The wafer attachment structure (434) according to any one of D1 to D15, wherein the wafer (430) is formed in a disc shape and the supporting substrate (400) is formed in a disc shape.

[D17] The wafer attachment structure (434) according to D16, wherein the wafer (430) has a first diameter and the supporting substrate (400) has a second diameter different from the first diameter.

[D18] The wafer attachment structure (434) according to D17, wherein the second diameter exceeds the first diameter.

[D19] The wafer attachment structure (434) according to any one of D1 to D18, further comprising: a wafer structure (440) that includes the wafer (430) and an epitaxial layer (435) laminated on the wafer (430) and that has the first main surface (431) formed by the epitaxial layer (435) and the second main surface (432) formed by the wafer (430).

[D20] The wafer attachment structure (434) according to D19, wherein the sealing insulator (71) exceeds the epitaxial layer (435) in thickness.

[D21] The wafer attachment structure (434) according to D19 or D20, wherein the sealing insulator (71) is thicker than the wafer (430).

[D22] The wafer attachment structure (434) according to D19 or D20, wherein the sealing insulator (71) is thinner than the wafer (430).

[D23] The wafer attachment structure (434) according to any one of D19 to D22, wherein the epitaxial layer (435) covers a side surface of the wafer (430).

[D24] The wafer attachment structure (434) according to any one of D1 to D23, wherein the wafer (430) includes a monocrystal of a wide bandgap semiconductor and the supporting substrate (400) includes a monocrystal of a wide bandgap semiconductor.

[D25] The wafer attachment structure (434) according to any one of D1 to D24, wherein the wafer (430) includes an SiC monocrystal and the supporting substrate (400) includes an SiC monocrystal.

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A manufacturing method for a semiconductor device comprising:
a step of preparing a wafer source that has a first main surface on one side and a second main surface on the other side;
a step of forming a main surface electrode on the first main surface;
a step of forming a terminal electrode on the main surface electrode;
a step of forming a sealing insulator that covers a periphery of the terminal electrode on the first main surface such as to expose a part of the terminal electrode; and
a step of cutting the wafer source in a horizontal direction along the first main surface from an intermediate portion of a thickness range of the wafer source, and separating the wafer source into a sealed wafer on the sealing insulator side and an unsealed wafer on the second surface side.

2. The manufacturing method for the semiconductor device according to claim 1,
wherein the separating step of the wafer source includes a step of cutting out the sealed wafer that is thinner than the sealing insulator.

3. The manufacturing method for the semiconductor device according to claim 1,
wherein the separating step of the wafer source includes a step of cutting out the unsealed wafer that is thicker than the sealed wafer.

4. The manufacturing method for the semiconductor device according to claim 1,
wherein the separating step of the wafer source includes a step of forming a modified layer that extends along the horizontal direction at the intermediate portion of the thickness range of the wafer source by a laser light irradiating method, and thereafter cleaving the wafer source in the horizontal direction with the modified layer as a starting point.

5. The manufacturing method for the semiconductor device according to claim 1, further comprising:
a step of attaching a supporting substrate to the second main surface, before the separating step of the wafer source;
wherein the separating step of the wafer source includes a step of separating the wafer source into the sealed wafer on the sealing insulator side and the unsealed wafer on the supporting substrate side.

6. The manufacturing method for the semiconductor device according to claim 1, further comprising:
a step of reusing the unsealed wafer.

7. The manufacturing method for the semiconductor device according to claim 1, further comprising:
a step of forming an insulating film that partially covers the main surface electrode before the forming step of the terminal electrode;
wherein the forming step of the sealing insulator includes a step of forming the sealing insulator that covers the terminal electrode and the insulating film.

8. The manufacturing method for the semiconductor device according to claim 1, further comprising:
a step of growing an epitaxial layer from the first main surface to form a wafer structure that includes the wafer source and the epitaxial layer and that has the first main surface formed by the epitaxial layer, before the forming step of the main surface electrode;
wherein the separating step of the wafer source includes a step of cutting out the sealed wafer that includes a wafer portion consisting of a portion of the wafer source and the epitaxial layer laminated on the wafer portion.

9. The manufacturing method for the semiconductor device according to claim 8, further comprising:
a step of removing at least a portion of the wafer portion in a state in which the sealed wafer is supported by the sealing insulator, after the separating step of the wafer source.

10. The manufacturing method for the semiconductor device according to claim 1,
wherein the wafer source includes a monocrystal of a wide bandgap semiconductor.

11. A manufacturing method for a semiconductor device comprising:
a step of preparing a wafer source that has a first main surface on one side and a second main surface on the other side;
a step of attaching a supporting substrate onto the second main surface;
a step of cutting the wafer source in a horizontal direction along the first main surface from an intermediate portion of a thickness range of the wafer source, and separating a wafer having a wafer main surface consisting of a cut surface from the wafer source with the supporting substrate;
a step of forming a main surface electrode on the wafer main surface;
a step of forming a terminal electrode on the main surface electrode;
a step of forming a sealing insulator that covers a periphery of the terminal electrode on the wafer main surface such as to expose a part of the terminal electrode; and
a step of removing the supporting substrate in a state in which the wafer is supported by the sealing insulator.

12. The manufacturing method for the semiconductor device according to claim 11,
wherein the wafer source cut out from an ingot is prepared.

13. The manufacturing method for the semiconductor device according to claim 11,
wherein the separating step of the wafer source includes a step of separating the wafer that is thinner than the supporting substrate from the wafer source.

14. The manufacturing method for the semiconductor device according to claim 11, further comprising:
a step of repeating a series of steps including the attaching step of the supporting substrate and the separating step of the wafer source until the wafer source becomes inseparable.

15. The manufacturing method for the semiconductor device according to claim 11,
wherein the separating step of the wafer source includes a step of forming a modified layer oriented along the horizontal direction at the intermediate portion of the thickness range of the wafer source by a laser light irradiating method, and thereafter cleaving the wafer source in the horizontal direction with the modified layer as a starting point.

16. The manufacturing method for the semiconductor device according to claim 11, further comprising:
a step of thinning the wafer in a state in which the wafer is supported by the sealing insulator, after the removing step of the supporting substrate.

17. The manufacturing method for the semiconductor device according to claim 16,
wherein the thinning step of the wafer includes a step of further thinning the wafer that is thinner than the sealing insulator or a step of thinning the wafer that is thicker than the sealing insulator until the wafer becomes thinner than the sealing insulator.

18. The manufacturing method for the semiconductor device according to claim 11,
wherein the forming step of the sealing insulator includes a step of forming the sealing insulator that is thicker than the wafer.

19. The manufacturing method for the semiconductor device according to claim 11, further comprising:
a step of growing an epitaxial layer from the wafer main surface to form a wafer structure that includes the wafer and the epitaxial layer and that has the wafer main surface formed by the epitaxial layer, before the forming step of the main surface electrode.

20. The manufacturing method for the semiconductor device according to claim 19, further comprising:
a step of removing at least a portion of the wafer from the wafer structure in a state in which the wafer structure is supported by the sealing insulator, after the removing step of the supporting substrate.
